(19) United States
(12) Patent Application Publication
(10) Pub. No.: US 2026/0206436 A1
(43) Pub. Date: Jul. 16, 2026

(54) DISPLAY DEVICE AND ELECTRONIC DEVICE

(71) Applicant: Samsung Display Co., Ltd., Yongin-si (KR)

(72) Inventors: Sun Hwa LEE, Yongin-si (KR); Kwi Hyun KIM, Yongin-si (KR); Ji Sun KIM, Yongin-si (KR); Se Hyun LEE, Yongin-si (KR); Kyung Hoon CHUNG, Yongin-si (KR)

(21) Appl. No.: 19/349,642

(22) Filed: Oct. 3, 2025

(30) Foreign Application Priority Data
Jan. 13, 2025 (KR) 10-2025-0004910

(51) Int. Cl. H10K 59/131; H10K 59/121

(52) U.S. Cl. CPC H10K 59/131; H10K 59/1213

(57) ABSTRACT

A display device includes: pixels in a display area, each of the pixels including a first subpixel, a second subpixel, and a third subpixel; a first driving power line electrically connected to the first subpixels of the pixels; and a second driving power line electrically connected to at least one of the second subpixels or the third subpixels of the pixels. The first driving power line and the second driving power line are to be applied with driving voltages of different levels from each other.

### CROSS-REFERENCE TO RELATED APPLICATION

The present application claims priority to and the benefit of Korean Patent Application No. 10-2025-0004910, filed on January 13, 2025, in the Korean Intellectual Property Office, the entire disclosure of which is incorporated by reference herein.

### BACKGROUND

### Field

Aspects of embodiments of the present disclosure relate to a display device and an electronic device, which may display an image.

### Description of the Related Art

As information society develops, demand for display devices and electronic devices, which may display images, are increasing in various forms. Accordingly, various kinds of display devices and electronic devices, which include pixels for displaying images, are being developed. The display devices may be provided alone, or may be included in the electronic devices and used as display screens of the electronic devices.

The above information disclosed in this Background section is for enhancement of understanding of the background of the present disclosure, and therefore, it may contain information that does not constitute prior art.

### SUMMARY

Embodiments of the present disclosure may be directed to a display device and an electronic device, which may optimize or improve a driving voltage of subpixels, and may improve a power consumption.

However, the aspects and features of the present disclosure are not limited thereto. The above and additional aspects and features will be set forth, in part, in the description that follows, and in part, may be apparent from the description, or may be learned by practicing one or more of the presented embodiments of the present disclosure.

According to one or more embodiments of the present disclosure, a display device includes: pixels in a display area, each of the pixels including a first subpixel, a second subpixel, and a third subpixel; a first driving power line electrically connected to the first subpixels of the pixels; and a second driving power line electrically connected to at least one of the second subpixels or the third subpixels of the pixels. The first driving power line and the second driving power line are configured to be applied with driving voltages of different levels from each other.

In an embodiment, the first driving power line may include first vertical power lines and first horizontal power lines crossing each other and electrically connected to each other in the display area, and the second driving power line may include second vertical power lines and second horizontal power lines crossing each other in the display area.

In an embodiment, the pixels may include pixels of a first pixel row along a first direction of the display area, and pixels of a second pixel row along the first direction of the display area. The pixels of the first pixel row may overlap with one first horizontal power line among the first horizontal power lines, and the pixels of the second pixel row may overlap with one second horizontal power line among the second horizontal power lines.

In an embodiment, the first vertical power lines and the second vertical power lines may be located along the first direction, and each of the first vertical power lines and the second vertical power lines may extend in a second direction.

In an embodiment, the one first horizontal power line may be electrically connected to the first vertical power lines through connection patterns included in the pixels of the first pixel row, and the one second horizontal power line may be electrically connected to the second vertical power lines through connection patterns included in the pixels of the second pixel row.

In an embodiment, each of the first subpixels, the second subpixels, and the third subpixels of the pixels may include: a pixel circuit including a first transistor; and a light emitting element electrically connected to the pixel circuit.

In an embodiment, the first vertical power lines may overlap with the pixel circuits of the first subpixels of the pixels, and may be electrically connected to the pixel circuits of the first subpixels, and the second vertical power lines may overlap with the pixel circuits of the second subpixels and the third subpixels of the pixels, and may be electrically connected to the pixel circuits of the second subpixels and the third subpixels.

In an embodiment, each of the first subpixels of the pixels may include a first light emitting element configured to emit light of a first color, each of the second subpixels of the pixels may include a second light emitting element configured to emit light of a second color, and each of the third subpixels of the pixels may include a third light emitting element configured to emit light of a third color.

In an embodiment, each of the first subpixels, the second subpixels, and the third subpixels of the pixels may include a first transistor electrically connected to the first driving power line or the second driving power line, and configured to control a driving current.

In an embodiment, each of the first subpixels, the second subpixels, and the third subpixels of the pixels may further include a capacitor electrically connected between the first driving power line and a gate electrode of the first transistor, or electrically connected between the second driving power line and the gate electrode of the first transistor.

In an embodiment, the capacitor of the first subpixel may be electrically insulated from the capacitors of the second subpixel and the third subpixel, and the capacitor of the first subpixel may include a capacitor electrode spaced from capacitor electrodes of the capacitors of the second subpixel and the third subpixel.

In an embodiment, the display device may further include bottom conductive patterns located under the first transistors of each of the first subpixels, the second subpixels, and the third subpixels of the pixels.

In an embodiment, each of the bottom conductive patterns may be configured to be applied with a driving voltage of a first level of the first driving power line, or a driving voltage of a second level of the second driving power line.

In an embodiment, the bottom conductive patterns may include: a first bottom conductive pattern located under the first transistor of the first subpixel; and second bottom conductive patterns spaced from the first bottom conductive pattern, and located under the first transistors of the second and third subpixels. The first bottom conductive pattern and the second bottom conductive patterns may be configured to be applied with driving voltages of different levels from each other.

In an embodiment, the bottom conductive patterns may be connected to each other in the display area, and may be configured to be applied with a driving voltage of a first level of the first driving power line, or a driving voltage of a second level of the second driving power line.

According to one or more embodiments of the present disclosure, an electronic device includes: a display module including a display panel; memory configured to store an image data signal or an input control signal; and a processor configured to transmit the image data signal or the input control signal stored in the memory to the display module. The display panel includes: pixels in a display area, each of the pixels including a first subpixel, a second subpixel, and a third subpixel; a first driving power line electrically connected to the first subpixels of the pixels; and a second driving power line electrically connected to at least one of the second subpixels or the third subpixels of the pixels. The first driving power line and the second driving power line are configured to be applied with driving voltages of different levels from each other.

In an embodiment, the first driving power line may include first vertical power lines and first horizontal power lines crossing each other and electrically connected to each other in the display area, and the second driving power line may include second vertical power lines and second horizontal power lines crossing each other and electrically connected to each other in the display area.

In an embodiment, each of the first subpixels, the second subpixels, and the third subpixels of the pixels may include a first transistor electrically connected to the first driving power line or the second driving power line, and configured to control a driving current. The display panel may further include bottom conductive patterns located under the first transistors of the first subpixels, the second subpixels, and the third subpixels of the pixels.

In an embodiment, the bottom conductive patterns may include: a first bottom conductive pattern located under the first transistor of each of the first subpixels of the pixels; and second bottom conductive patterns spaced from the first bottom conductive pattern, and located under the first transistors of the second and third subpixels of the pixels. The first bottom conductive pattern and the second bottom conductive patterns may be configured to be applied with driving voltages of different levels from each other.

In an embodiment, the bottom conductive patterns may be connected to each other in the display area, and may be configured to be applied with a driving voltage of a first level of the first driving power line, or a driving voltage of a second level of the second driving power line.

According to some embodiments, at least two subpixels of a pixel included in a display device and an electronic device may be connected to different driving power lines from each other. Therefore, driving voltages applied to the subpixels, respectively, may be differentiated, optimized, or improved. Accordingly, the subpixels may be efficiently driven, and a power consumption of the display device and the electronic device may be improved.

According to some embodiments, each driving power line may be formed as a mesh-shaped wiring. Accordingly, a drop of the driving voltages may be reduced, and the subpixels may be stably supplied with their respective driving voltages.

According to some embodiments, the display device and the electronic device may further include bottom conductive patterns located under first transistors of the subpixels, and a driving voltage applied to some subpixels may be applied to each of the bottom conductive patterns. Accordingly, operating characteristics of the subpixels may be improved without adding a panel driving voltage, and a reliability of the display device and the electronic device may be increased.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment;

FIG. 2 is a plan view of a display panel according to an embodiment;

FIG. 3 is a block diagram of a display device according to an embodiment;

FIG. 4 is an equivalent circuit diagram of a subpixel according to an embodiment;

FIG. 5 is a waveform diagram illustrating driving signals of a subpixel according to the embodiment;

FIG. 6 is a graph illustrating a difference in characteristics of light emitting elements included in subpixels according to an embodiment;

FIG. 7 is an equivalent circuit diagram of a first subpixel according to an embodiment;

FIG. 8 is an equivalent circuit diagram of a second subpixel and a third subpixel according to an embodiment;

FIG. 9 is an equivalent circuit diagram of a first subpixel according to an embodiment;

FIG. 10 is an equivalent circuit diagram of a first subpixel according to an embodiment;

FIG. 11 is an equivalent circuit diagram of a second subpixel and a third subpixel according to an embodiment;

FIG. 12 is an equivalent circuit diagram of a second subpixel and a third subpixel according to an embodiment;

FIG. 13 is a plan view illustrating pixel circuits, signal lines, and power lines located in a backplane layer of a display panel according to an embodiment;

FIG. 14 is a plan view illustrating pixel circuits, signal lines, and power lines located in a backplane layer of a display panel according to an embodiment;

FIG. 15 is a plan view illustrating pixel circuits, signal lines, and power lines located in a backplane layer of a display panel according to an embodiment;

FIG. 16 is a plan view illustrating a first driving power line and a second driving power line according to an embodiment;

FIG. 17 is a plan view illustrating a first driving power line and a second driving power line according to an embodiment;

FIG. 18 is a plan view illustrating pixel circuits, signal lines, power lines, and bottom conductive patterns located in a backplane layer of a display panel according to an embodiment;

FIG. 19 is a plan view illustrating pixel circuits, signal lines, power lines, and bottom conductive patterns located in a backplane layer of a display panel according to an embodiment;

FIG. 20 is a plan view illustrating bottom conductive patterns according to an embodiment;

FIG. 21 is a plan view illustrating pixel circuits, signal lines, power lines, and bottom conductive patterns located in a backplane layer of a display panel according to an embodiment;

FIG. 22 is a plan view illustrating pixel circuits, signal lines, power lines, and bottom conductive patterns located in a backplane layer of a display panel according to an embodiment;

FIG. 23 is a plan view illustrating bottom conductive patterns according to an embodiment;

FIG. 24 is a plan view illustrating a connection structure of bottom conductive patterns according to an embodiment;

FIG. 25 is a plan view illustrating a connection structure of bottom conductive patterns according to an embodiment;

FIG. 26 is a layout view of a backplane layer of a display panel according to an embodiment;

FIG. 27 is a more detailed layout view of a first pixel circuit of FIG. 26;

FIG. 28 is a more detailed layout view of a second pixel circuit of FIG. 26;

FIG. 29 is a layout view of a light emitting element layer of a display panel according to an embodiment;

FIG. 30 is a cross-sectional view illustrating an example of a cross-section of a display panel corresponding to the line X1-X1’ of FIGS. 27 and 29;

FIG. 31 is a more detailed cross-sectional view corresponding to the area A2 of FIG. 30;

FIG. 32 is a cross-sectional view illustrating an example of a cross-section of a display panel corresponding to the line X2-X2’ of FIGS. 28 and 29;

FIG. 33 is a block diagram of an electronic device according to an embodiment; and

FIG. 34 is a schematic diagram of some electronic devices according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

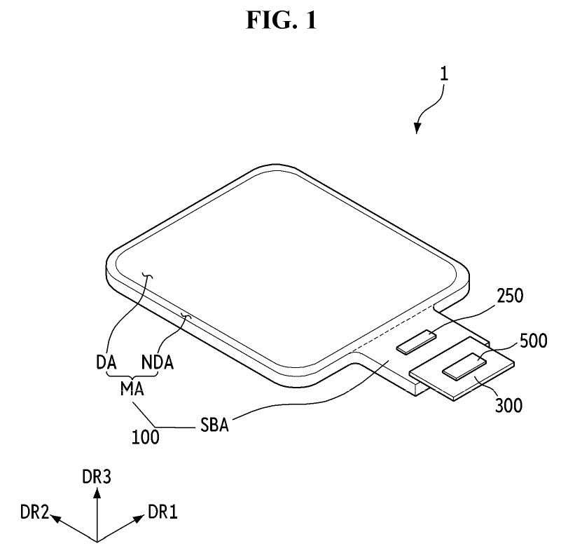

FIG. 1 is a perspective view of a display device 1 according to an embodiment.

Referring to FIG. 1, the display device 1 may be a device that provides an image, such as a moving image or a still image. For example, the display device 1 may be a device that may display an image by including a display module (e.g., a display or a touch-display) that includes a display panel 100. As an example, the display device 1 may refer to any suitable electronic device that provides a display screen on which an image may be displayed, or that includes the display module for displaying an image. The display device 1 may also be included in an electronic device that provides a display screen, and may form the display screen of the electronic device.

For example, the display device 1 may be included in various suitable portable electronic devices, such as mobile phones, smartphones, tablet personal computers (PCs), smart watches, watch phones, mobile communication terminals, electronic notebooks, electronic books, portable multimedia players (PMPs), navigation devices, and ultra-mobile PCs (UMPCs), as well as in various suitable electronic devices, such as televisions, notebook computers, monitors, billboards, and Internet of things (IoT) devices, and may be used as a display screen. In addition, the display device 1 may be included in other suitable electronic devices, such as a virtual reality (VR) device and an augmented reality (AR) device, and may be used to display images in the electronic devices.

In FIG. 1, the display module, which is a main element of the display device 1, is illustrated. In an embodiment, the display device 1 (or an electronic device including the display module) may further include additional elements. For example, the display device 1 may further include a housing or a case for accommodating the display module of FIG. 1.

In an embodiment, the display device 1 may be a light emitting display device, such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode (LED). A micro- or nano-light emitting display device including a micro- or nano-LED will be disclosed in more detail below as a representative example of the display device 1, but the present disclosure is not limited thereto. For example, the kind of light emitting element included in the display device 1 is not limited to a micro- or nano-LED, and the display device 1 may also include other suitable kinds and/or shapes of light emitting elements. In addition, the display device 1 is not limited to a light emitting display device, and the kind and/or shape of the display device 1 may vary as needed or desired.

The display device 1 may include a display panel 100, a display driver 250, a circuit board 300, and a power supply unit (e.g., a power supply) 500. The display panel 100, the display driver 250, the circuit board 300, and the power supply unit 500 may be included in the display module of the display device 1.

In an embodiment, the display panel 100 may have a substantially quadrangular planar shape. For example, the display panel 100 may have a substantially quadrangular shape on a plane defined by a first direction DR1 and a second direction DR2 crossing or intersecting each other. Each corner of the display panel 100 may be rounded or right-angled. The planar shape of the display panel 100 is not limited to a quadrangular shape, but may also be other suitable polygonal shapes, a circular shape, or an elliptical shape. The display panel 100 may be formed to be flat or substantially flat, but the present disclosure is not limited thereto. For example, the display panel 100 may include a curved portion formed at left and right ends and having a constant or varying curvature. In an embodiment, the display panel 100 may be formed to be flexible so that it may be curved, bent, folded, or rolled.

The display panel 100 may include a main area MA including a display area DA. In an embodiment, the display panel 100 may further include a sub-area SBA.

The main area MA may include the display area DA that displays an image, and a non-display area NDA located around the display area DA. The display area DA may include pixels to display an image. Each of the pixels may include a plurality of subpixels. For example, each of the pixels may include a first subpixel that emits light of a first color (e.g., a first light), a second subpixel that emits light of a second color (e.g., a second light), and a third subpixel that emits light of a third color (e.g., a third light), but the present disclosure is not limited thereto.

The sub-area SBA may protrude from a side of the main area MA in the second direction DR2 (e.g., a vertical direction of the display panel 100). Although the sub-area SBA is illustrated as unfolded in FIG. 1, it may be bent. In this case, the sub-area SBA may be placed on a lower surface (e.g., a bottom surface) of the display panel 100. When the sub-area SBA is bent, it may be overlapped by the main area MA in a third direction DR3, which is a thickness direction of the display panel 100. The display driver 250 may be located in the sub-area SBA.

The display driver 250 may generate signals and voltages for driving the display panel 100 (e.g., driving signals and driving voltages of the display panel 100). The display driver 250 may be formed as an integrated circuit, and may be attached onto the display panel 100 using a chip on glass (COG) method, a chip on plastic (COP) method, or an ultrasonic bonding method. However, the present disclosure is not limited thereto. For example, the display driver 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driver 250. The display panel 100 and the display driver 250 may receive digital video data, timing signals, and driving voltages through the circuit board 300. The circuit board 300 may be a flexible printed circuit board, a printed circuit board, or a flexible film such as a chip on film.

The power supply unit 500 may generate panel driving voltages according to a power supply voltage supplied from the outside. The power supply unit 500 may be formed as an integrated circuit, and may be attached onto the circuit board 300 using a COF method.

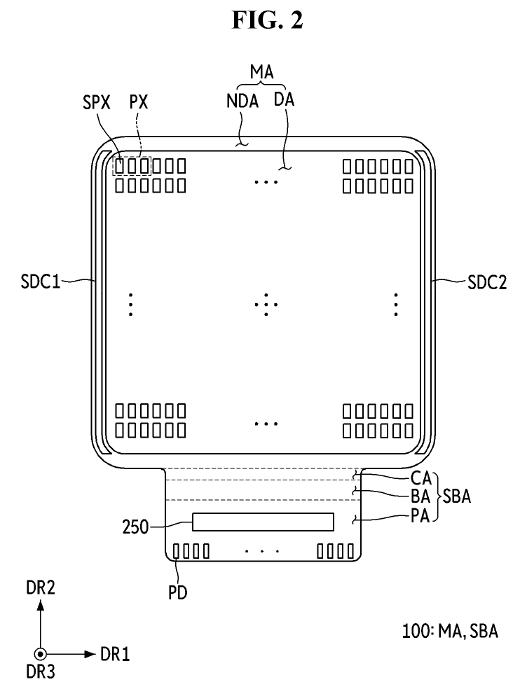

FIG. 2 is a plan view of a display panel 100 according to an embodiment. FIG. 2 shows a state in which a sub-area SBA is unfolded.

Referring to FIGS. 1 and 2, the display panel 100 may include a main area MA and the sub-area SBA.

The main area MA may include a display area DA and a non-display area NDA. The display area DA may occupy most of the main area MA. In an embodiment, the display area DA may be located in the center of the main area MA.

The display area DA may include pixels PX for displaying an image. Each of the pixels PX may include a plurality of subpixels SPX. A pixel PX may be defined as a smallest subpixel group that may express a white gray level (e.g., a white grayscale level or value).

The non-display area NDA may neighbor the display area DA. The non-display area NDA may be an area outside the display area DA. The non-display area NDA may surround (e.g., around a periphery of) the display area DA. The non-display area NDA may be an edge area of the display panel 100.

A first scan driver SDC1 and a second scan driver SDC2 may be located in the non-display area NDA. The first scan driver SDC1 may be located on a side (e.g., a left side) of the display panel 100, and the second scan driver SDC2 may be located on another side (e.g., a right side) of the display panel 100, but the present disclosure is not limited thereto. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, may generate scan signals according to the scan control signal, and may output the scan signals to scan lines. Although FIG. 2 illustrates an embodiment in which the display device 1 (e.g., the display panel 100) includes the first scan driver SDC1 and the second scan driver SDC2 located on different sides of the display area DA from each other, the present disclosure is not limited thereto. For example, the display device 1 may include at least one scan driver, and the number or the positions of scan drivers included in the display device 1 may be variously modified as needed or desired.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be equal to or smaller than a length of the main area MA in the first direction DR1. The sub-area SBA may be bent and placed under the main area MA. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and another side of the connection area CA may contact the bending area BA.

The pad area PA is an area where pads PD and the display driver 250 are located. The display driver 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. A side of the pad area PA may contact the bending area BA.

The bending area BA is a bendable area. When the bending area BA is bent, the pad area PA may be placed under the connection area CA and the main area MA. The bending area BA may be located between the connection area CA and the pad area PA. A side of the bending area BA may contact the connection area CA, and another side of the bending area BA may contact the pad area PA.

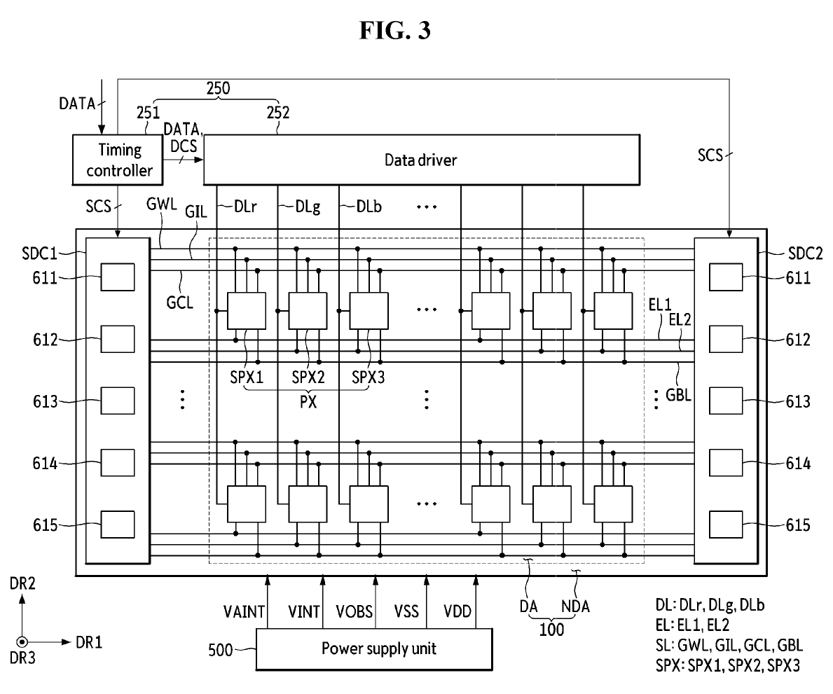

FIG. 3 is a block diagram of the display device 1 according to the embodiment.

Referring to FIG. 3, the display area DA may include pixels PX, scan lines SL, emission control lines EL, and data lines DL.

The pixels PX may be arranged in the first direction DR1 and the second direction DR2. For example, the pixels PX may be arranged in a matrix form in the first direction DR1 and the second direction DR2. The scan lines SL and the emission control lines EL may extend in the first direction DR1, and may be arranged or placed along the second direction DR2. The data lines DL may extend in the second direction DR2, and may be arranged or placed along the first direction DR1. The scan lines SL may include write scan lines GWL, initialization scan lines GIL, control scan lines GCL, and bias scan lines GBL. The configuration or the number of scan lines SL may vary depending on the structure or the driving method of the pixels PX.

Each of the pixels PX may include a plurality of subpixels SPX. For example, each of the pixels PX may include a first subpixel SPX1, a second subpixel SPX2, and a third subpixel SPX3. The first subpixel SPX1, the second subpixel SPX2, and the third subpixel SPX3 may emit light of a first color, light of a second color, and light of a third color, respectively. The light of the first color, the light of the second color, and the light of the third color may be, but are not limited to, red light (e.g., light in a red wavelength band having a main peak wavelength of about 600 to 750 nm), green light (e.g., light in a green wavelength band having a main peak wavelength of about 480 to 560 nm), and blue light (e.g., light in a blue wavelength band having a main peak wavelength of about 370 to 460 nm), respectively. In an embodiment, the first subpixel SPX1, the second subpixel SPX2, and the third subpixel SPX3 of each of the pixels PX may be arranged in the first direction DR1. The number, the kind, the arrangement structure, and/or the emission wavelength of the subpixels SPX included in each of the pixels PX may be variously modified as needed or desired.

Each of the subpixels SPX may be connected to any one of the write scan lines GWL, any one of the initialization scan lines GIL, any one of the control scan lines GCL, any one of the bias scan lines GBL, any one of the emission control lines EL, and any one of the data lines DL. As used herein, the term “connection” may refer to a “physical connection” and/or an “electrical connection.”

Each of the subpixels SPX may receive a data voltage of a data line DL according to a write scan signal of a write scan line GWL, and may emit light from a light emitting element according to the data voltage. The subpixels SPX included in each pixel PX may be connected to different data lines DL from each other. For example, the first subpixel SPX1, the second subpixel SPX2, and the third subpixel SPX3 may be connected to a first data line DLr, a second data line DLg, and a third data line DLb, respectively. Accordingly, the emission luminance of each of the first subpixel SPX1, the second subpixel SPX2, and the third subpixel SPX3 may be individually controlled.

In an embodiment, each of the pixels PX may be connected to two or more emission control lines EL, and emission periods (e.g., on-duty ratios) of at least two of the subpixels SPX included in each pixel PX may be independently and/or individually controlled by different emission control signals supplied to different emission control lines EL. For example, in each horizontal line of the display area DA (e.g., a horizontal line including pixels PX located in each pixel row), a first emission control line EL1 and a second emission control line EL2, which are connected to different subpixels SPX among subpixels SPX included in pixels PX located in the corresponding horizontal line, may be located. For example, the first emission control line EL1 may be connected to first subpixels SPX1 of pixels PX located in a corresponding horizontal line, and the second emission control line EL2 may be connected to second subpixels SPX2 and third subpixels SPX3 included in the pixels PX of the corresponding horizontal line.

The first subpixel SPX1 may emit light during a first emission period in response to a first emission control signal supplied through the first emission control line EL1. The first emission period may be a period during which a driving current may flow through the first subpixel SPX1 in response to the first emission control signal. The second subpixel SPX2 and the third subpixel SPX3 may emit light during a second emission period in response to a second emission control signal supplied through the second emission control line EL2. The second emission period may be a period during which a driving current may flow through the second subpixel SPX2 and the third subpixel SPX3 in response to the second emission control signal. The first emission period and the second emission period may be independently or individually controlled, and may or may not temporally overlap with each other.

In an embodiment, the duration of the first emission period and the duration of the second emission period may be different from each other. For example, the duration of the first emission period may correspond to an on-duty ratio adjusted to allow the first subpixel SPX1 to emit light having a target luminance according to a driving current optimized for a luminous efficiency of the first subpixel SPX1 (e.g., a driving current within a range in which a light emitting element of the first subpixel SPX1 exhibits an optimal consumption efficiency). The duration of the second emission period may correspond to an on-duty ratio adjusted to allow the second subpixel SPX2 and the third subpixel SPX3 to emit light with a target luminance according to a driving current optimized for the luminous efficiency of the second subpixel SPX2 and the third subpixel SPX3 (e.g., a driving current within a range in which light emitting elements of the second subpixel SPX2 and the third subpixel SPX3 exhibit an optimal consumption efficiency). In this case, emission control signal output units (e.g., emission control signal output circuits or stages) 615 included in the first scan driver SDC1 and the second scan driver SDC2 may output emission control signals having different pulse widths from each other to the first emission control line EL1 and the second emission control line EL2.

The first scan driver SDC1, the second scan driver SDC2, and the display driver 250 may be located in the non-display area NDA.

Each of the first scan driver SDC1 and the second scan driver SDC2 may be electrically connected to the corresponding pixels PX through the scan lines SL and the emission control lines EL. For example, each of the first scan driver SDC1 and the second scan driver SDC2 may be electrically connected to pixel circuits of the subpixels SPX included in each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit (e.g., a write scan signal output circuit or stage) 611, an initialization scan signal output unit (e.g., an initialization scan signal output circuit or stage) 612, a control scan signal output unit (a control scan signal output circuit or stage) 613, a bias scan signal output unit (e.g., a bias scan signal output circuit or stage) 614, and an emission control signal output unit (e.g., an emission control signal output circuit or stage) 615. Each of the write scan signal output unit 611, the initialization scan signal output unit 612, the control scan signal output unit 613, the bias scan signal output unit 614, and the emission control signal output unit 615 may receive a scan timing control signal SCS from a timing controller 251.

The write scan signal output unit 611 may generate write scan signals according to the scan timing control signal SCS, and may sequentially output the write scan signals to the write scan lines GWL.

The initialization scan signal output unit 612 may generate initialization scan signals according to the scan timing control signal SCS, and may sequentially output the initialization scan signals to the initialization scan lines GIL.

The control scan signal output unit 613 may generate control scan signals according to the scan timing control signal SCS, and may sequentially output the control scan signals to the control scan lines GCL.

The bias scan signal output unit 614 may generate bias scan signals according to the scan timing control signal SCS, and may sequentially output the bias scan signals to the bias scan lines GBL.

The emission control signal output unit 615 may generate emission control signals according to the scan timing control signal SCS, and may sequentially output the emission control signals to the emission control lines EL. When the subpixels SPX of each horizontal line are divided and connected to a plurality of emission control lines EL (e.g., the first emission control line EL1 and the second emission control line EL2 of each horizontal line), the emission control signal output unit 615 may output the emission control signals to the emission control lines EL, respectively, in each horizontal period.

The display driver 250 may include the timing controller 251 and a data driver 252.

The data driver 252 may be electrically connected to the pixels PX through the data lines DL. For example, the data driver 252 may be electrically connected to the pixel circuits of the subpixels SPX included in each pixel PX through the first data line DLr, the second data line DLg, and the third data line DLb.

The data driver 252 may receive digital video data DATA and a data timing control signal DCS from the timing controller 251. The data driver 252 converts the digital video data DATA into analog data voltages according to the data timing control signal DCS, and outputs the analog data voltages to the data lines DL. In this case, the subpixels SPX may be selected by a write scan signal of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate panel driving voltages according to a power supply voltage supplied from the outside. For example, the power supply unit 500 may generate a first driving voltage VDD, a second driving voltage VSS, a first initialization voltage VINT, a second initialization voltage VAINT, and a bias voltage VOBS, and may supply them to the display panel 100. The first driving voltage VDD, the second driving voltage VSS, the first initialization voltage VINT, the second initialization voltage VAINT, and the bias voltage VOBS may be supplied to the subpixels SPX through respective power lines connected between the power supply unit 500 and the subpixels SPX, and may be used to drive the subpixels SPX. The number and/or the kind of panel driving voltages output from the power supply unit 500 may vary depending on the structure or operation method of the subpixels SPX.

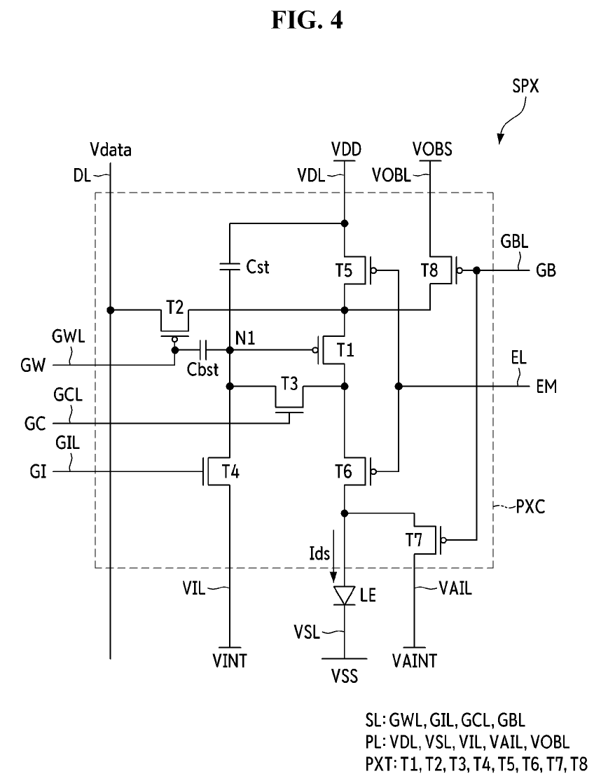

FIG. 4 is an equivalent circuit diagram of a subpixel SPX according to an embodiment. For example, FIG. 4 may be an equivalent circuit diagram of one of the subpixels SPX of FIGS. 2 and 3.

In an embodiment, circuit configurations of a plurality of subpixels SPX that form each pixel PX may be the same or substantially the same as each other. For example, equivalent circuit diagrams of the first subpixel SPX1, the second subpixel SPX2, and the third subpixel SPX3 of FIG. 3 may be the same or substantially the same as each other.

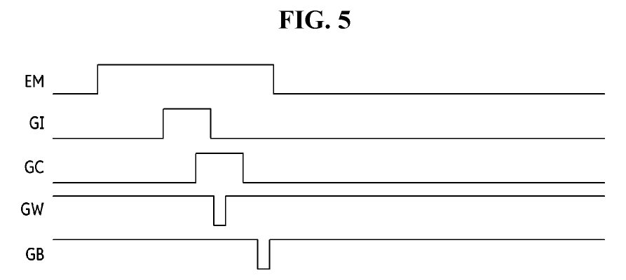

FIG. 5 is a waveform diagram illustrating driving signals of the subpixel SPX according to an embodiment. For example, FIG. 5 shows a write scan signal GW, a control scan signal GC, an initialization scan signal GI, a bias scan signal GB, and an emission control signal EM supplied to scan lines SL and an emission control line EL of FIG. 4.

Referring to FIGS. 4 and 5 in addition to FIGS. 1 through 3, each of the subpixels SPX may include a pixel circuit PXC, and a light emitting element LE electrically connected to the pixel circuit PXC.

The subpixel SPX may be connected to at least one scan driver through the scan lines SL and the emission control line EL (e.g., the first emission control line EL1 or the second emission control line EL2 of FIG. 3). For example, the subpixel SPX may be connected to the first scan driver SDC1 and the second scan driver SDC2 through a write scan line GWL, an initialization scan line GIL, a control scan line GCL, a bias scan line GBL, and the emission control line EL. The first scan driver SDC1 and the second scan driver SDC2 may output a write scan signal GW, an initialization scan signal GI, a control scan signal GC, a bias scan signal GB, and an emission control signal EM (e.g., the first emission control signal or the second emission control signal) to the write scan line GWL, the initialization scan line GIL, the control scan line GCL, the bias scan line GBL, and the emission control line EL, respectively.

The subpixel SPX may be connected to the data driver 252 through a data line DL (e.g., the first data line DLr, the second data line DLg, or the third data line DLb of FIG. 3). The data driver 252 may output a data voltage Vdata, which corresponds to image data of each frame, to the data line DL.

The subpixel SPX may be connected to the power supply unit 500 through power lines PL. For example, the subpixel SPX may be connected to the power supply unit 500 through a driving power line VDL, a common power line VSL, a first initialization power line VIL, a second initialization power line VAIL, and a bias power line VOBL. The driving power line VDL may also be referred to as a pixel power line.

The power supply unit 500 may supply a first driving voltage VDD, a second driving voltage VSS, a first initialization voltage VINT (also referred to as a “third driving voltage”), a second initialization voltage VAINT (also referred to as a “fourth driving voltage”), and a bias voltage VOBS (also referred to as a “fifth driving voltage”) to the driving power line VDL, the common power line VSL, the first initialization power line VIL, the second initialization power line VAIL, and the bias power line VOBL, respectively. In an embodiment, the first driving voltage VDD and the second driving voltage VSS may be voltages applied to both ends (e.g., opposite ends) of the light emitting element LE, and may be an anode voltage and a cathode voltage, respectively.

In an embodiment, the driving power line VDL may include a first driving power line and a second driving power line, which are separated from each other. The first driving power line and the second driving power line may be electrically connected to different subpixels SPX. For example, the first driving power line may be electrically connected to the first subpixel SPX1 among the subpixels SPX of each of the pixels PX, and the second driving power line may be electrically connected to the second subpixel SPX2 and the third subpixel SPX3 among the subpixels SPX of each of the pixels PX.

The power supply unit 500 may transmit first driving voltages VDD of different levels from each other to the first driving power line and the second driving power line. For example, the power supply unit 500 may supply a first driving voltage VDD of a first level and a first driving voltage VDD of a second level to the first driving power line and the second driving power line, respectively. In an embodiment, the first driving voltage VDD of the first level may be a voltage that is adjusted or optimized to suit the characteristics and/or a driving current Ids of the first subpixel SPX1. The first driving voltage VDD of the second level may be a voltage adjusted or optimized to suit the characteristics and/or a driving current Ids of the second subpixel SPX2 and the third subpixel SPX3.

The pixel circuit PXC may control the driving current Ids supplied to the light emitting element LE in response to the driving signals supplied to the subpixel SPX (e.g., the write scan signal GW, the initialization scan signal GI, the control scan signal GC, the bias scan signal GB, the emission control signal EM, and the data voltage Vdata). The emission timing and the luminance of the light emitting element LE may be controlled by the pixel circuit PXC.

The pixel circuit PXC may include pixel transistors PXT and a storage capacitor Cst. In an embodiment, the pixel circuit PXC may further include a boosting capacitor Cbst.

In an embodiment, the pixel transistors PXT may include first through eighth transistors T1 through T8. The first transistor T1 may be a driving transistor of the subpixel SPX. The second through eighth transistors T2 through T8 may be switching transistors of the subpixel SPX.

In an embodiment, the subpixel SPX may include heterogeneous pixel transistors PXT. For example, the first, second, fifth, sixth, seventh, and eighth transistors T1, T2, T5, T6, T7, and T8 may be P-type transistors (e.g., P-type polycrystalline silicon transistors that include respective active layers including polycrystalline silicon), and the third and fourth transistors T3 and T4 may be N-type transistors (e.g., N-type oxide transistors that include respective active layers including oxide semiconductor). In an embodiment, the active layers of the P-type transistors (e.g., the active layers including polycrystalline silicon) and the active layers of the N-type transistors (the active layers including oxide semiconductor) may be located in different layers from each other within the display panel 100 (e.g., within a backplane layer of the display panel 100).

The first transistor T1 may be connected between the fifth transistor T5 and the sixth transistor T6. The first transistor T1 may be connected to the driving power line VDL via the fifth transistor T5, and may be connected to the light emitting element LE via the sixth transistor T6. A gate electrode of the first transistor T1 may be connected to a first node N1. The first transistor T1 may control the driving current Ids, which flows through the subpixel SPX, according to the voltage of the first node N1 (e.g., a voltage corresponding to the data voltage Vdata) that is applied to the gate electrode of the first transistor T1.

The second transistor T2 may be connected between the data line DL and a first electrode of the first transistor T1 (e.g., a source electrode of the first transistor T1 which is connected to the fifth transistor T5). A gate electrode of the second transistor T2 may be connected to the write scan line GWL. The second transistor T2 may be turned on by the write scan signal GW of a gate-on voltage supplied from the write scan line GWL (e.g., a low-level voltage at which the second transistor T2 may be turned on). When the second transistor T2 is turned on, the data voltage Vdata supplied from the data line DL may be transmitted to the first electrode (e.g., the source electrode) of the first transistor T1.

The third transistor T3 may be connected between a second electrode of the first transistor T1 (e.g., a drain electrode of the first transistor T1 which is connected to the sixth transistor T6) and the first node N1. A gate electrode of the third transistor T3 may be connected to the control scan line GCL. The third transistor T3 may be turned on by the control scan signal GC of a gate-on voltage supplied from the control scan line GCL (e.g., a high-level voltage at which the third transistor T3 may be turned on) to connect the gate electrode and the second electrode of the first transistor T1 to each other. When the third transistor T3 is turned on, the first transistor T1 may operate as a diode, and a voltage corresponding to the data voltage Vdata may be applied to the first node N1. In other words, the third transistor T3 may diode connect the first transistor T1.

The fourth transistor T4 may be connected between the first node N1 and the first initialization power line VIL. A gate electrode of the fourth transistor T4 may be connected to the initialization scan line GIL. The fourth transistor T4 may be turned on by the initialization scan signal GI of a gate-on voltage supplied from the initialization scan line GIL (e.g., a high-level voltage at which the fourth transistor T4 may be turned on) to connect the first node N1 to the first initialization power line VIL. When the fourth transistor T4 is turned on, the voltage of the first node N1 may be initialized to the first initialization voltage VINT of the first initialization power line VIL.

The fifth transistor T5 may be connected between the driving power line VDL and the first electrode of the first transistor T1. A gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage supplied from the emission control line EL (e.g., a low-level voltage at which the fifth transistor T5 may be turned on) to connect the first electrode of the first transistor T1 to the driving power line VDL. When the fifth transistor T5 is turned on, the driving power line VDL may be connected to the first electrode of the first transistor T1.

The sixth transistor T6 may be connected between the second electrode of the first transistor T1 and the light emitting element LE. A gate electrode of the sixth transistor T6 may be connected to the emission control line EL. The sixth transistor T6 may be turned on by the emission control signal EM of a gate-on voltage supplied from the emission control line EL (e.g., a low-level voltage at which the sixth transistor T6 may be turned on) to connect the second electrode of the first transistor T1 to the light emitting element LE.

The seventh transistor T7 may be connected between a first electrode of the light emitting element LE (e.g., an anode connected to the sixth transistor T6) and the second initialization power line VAIL. A gate electrode of the seventh transistor T7 may be connected to the bias scan line GBL. The seventh transistor T7 may be turned on by the bias scan signal GB of a gate-on voltage supplied from the bias scan line GBL (e.g., a low-level voltage at which the seventh transistor T7 may be turned on) to connect the first electrode of the light emitting element LE to the second initialization power line VAIL. When the seventh transistor T7 is turned on, the voltage of the first electrode of the light emitting element LE may be initialized to the second initialization voltage VAINT of the second initialization power line VAIL.

The eighth transistor T8 may be connected between the bias power line VOBL and the first electrode of the first transistor T1. A gate electrode of the eighth transistor T8 may be connected to the bias scan line GBL. The eighth transistor T8 may be turned on by the bias scan signal GB of a gate-on voltage supplied from the bias scan line GBL to connect the first electrode of the first transistor T1 to the bias power line VOBL. When the eighth transistor T8 is turned on, the voltage of the first electrode of the first transistor T1 may be initialized to the bias voltage VOBS of the bias power line VOBL. In an embodiment, the bias voltage VOBS may be a bias voltage having a voltage level suitable for compensating for hysteresis characteristics of the first transistor T1.

The storage capacitor Cst may be connected between the first node N1 and the driving power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by a coupling action of the boosting capacitor Cbst, thereby stabilizing the operation of the first transistor T1. The boosting capacitor Cbst may be formed by a parasitic capacitance formed between the first node N1 and the write scan line GWL, or may be designed separately.

In each frame period, the subpixel SPX may emit light during a period corresponding to an on-duty ratio, and may not emit light during the remaining period. An emission period and a non-emission period of the subpixel SPX may be controlled by the emission control signal EM.

A period during which the fifth transistor T5 and the sixth transistor T6 are turned off (e.g., a period during which a high-level emission control signal EM is supplied to the subpixel SPX) may be the non-emission period of the subpixel SPX. The non-emission period of the subpixel SPX may include an initialization period for initializing the voltage of a specific node (e.g., the first node N1) of the subpixel SPX, and a data writing and storage period for charging the storage capacitor Cst with a voltage corresponding to the data voltage Vdata. In an embodiment, the initialization scan signal GI, the control scan signal GC, the write scan signal GW, and the bias scan signal GB of a gate-on voltage may be supplied during the non-emission period of the subpixel SPX. In an embodiment, the initialization scan signal GI, the control scan signal GC, and the bias scan signal GB of a gate-on voltage may be sequentially supplied during the non-emission period of the subpixel SPX. Periods during which the initialization scan signal GI and the control scan signal GC of a gate-on voltage are supplied may overlap with each other, but the present disclosure is not limited thereto. The write scan signal GW of a gate-on voltage may be supplied during a period in which the control scan signal GC of a gate-on voltage is supplied.

A period during which the fifth transistor T5 and the sixth transistor T6 are turned on (e.g., a period during which a low-level emission control signal EM is supplied to the subpixel SPX) may be the emission period of the subpixel SPX. During the emission period of the subpixel SPX, the first transistor T1 may supply the driving current Ids, which corresponds to the voltage of the first node N1, to the light emitting element LE.

The light emitting element LE may be connected between the pixel circuit PXC and the common power line VSL. For example, the first electrode (e.g., an anode or a pixel electrode) of the light emitting element LE may be connected to a node between the sixth transistor T6 and the seventh transistor T7, and a second electrode (e.g., a cathode or a common electrode) of the light emitting element LE may be connected to the common power line VSL. The light emitting element LE may emit light in response to the driving current Ids supplied from the pixel circuit PXC.

In an embodiment, the subpixel SPX may include a single light emitting element LE, but the present disclosure is not limited thereto. For example, the subpixel SPX may include at least two light emitting elements LE. The at least two light emitting elements LE may be connected in a series, parallel, or series-parallel structure between the pixel circuit PXC and the common power line VSL.

In an embodiment, the light emitting element LE may be a micro-LED including an inorganic compound, such as a nitride-based or phosphide-based semiconductor material. The display device 1 including the micro-LED as the light emitting element LE of the subpixel SPX may have a long life and a low power consumption. However, the light emitting element LE is not limited to the micro-LED. For example, the light emitting element LE may be an organic light emitting element, a quantum dot light emitting element, or other suitable kinds of light emitting elements. In addition, the size or the shape of the light emitting element LE may be variously modified as needed or desired.

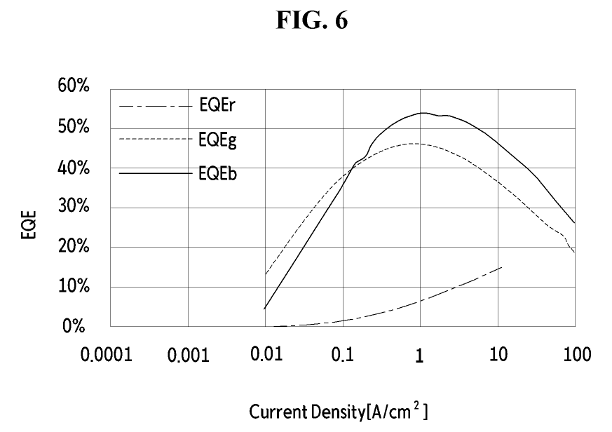

FIG. 6 is a graph illustrating a difference in characteristics of light emitting elements included in subpixels according to an embodiment. For example, FIG. 6 shows an external quantum efficiency EQE with respect to a current density of a red light emitting element, a green light emitting element, and a blue light emitting element, which may be used as light emitting elements LE of the subpixels SPX. The red light emitting element, the green light emitting element, and the blue light emitting element may be a red micro-LED, which emits red light, a green micro-LED, which emits green light, and a blue micro-LED, which emits blue light, respectively.

Referring to FIG. 6, the characteristics of the light emitting elements LE included in the subpixels SPX may be different from each other. For example, the external quantum efficiency EQEr according to the current density of the red micro-LED may be significantly different from the external quantum efficiency EQEg according to the current density of the green micro-LED and the external quantum efficiency EQEb according to the current density of the blue micro-LED, and may be relatively lower. On the other hand, the external quantum efficiency EQEg according to the current density of the green micro-LED and the external quantum efficiency EQEb according to the current density of the blue micro-LED may show relatively similar tendencies as each other, and may be relatively similar to each other.

In addition, optimal current density ranges (e.g., current density ranges including optimal driving currents) of the red micro-LED, the green micro-LED, and the blue micro-LED may be different from each other. For example, the optimal current density range of the red micro-LED may be greater than the optimal current density range of the green micro-LED and the optimal current density range of the blue micro-LED. Accordingly, an efficient operating range of the red micro-LED and efficient operating ranges of the green and blue micro-LEDs may be different from each other.

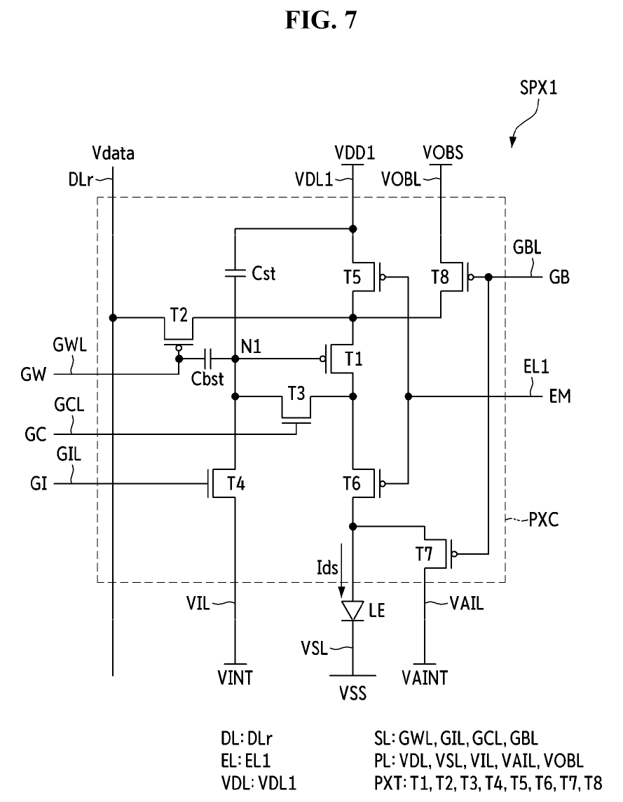

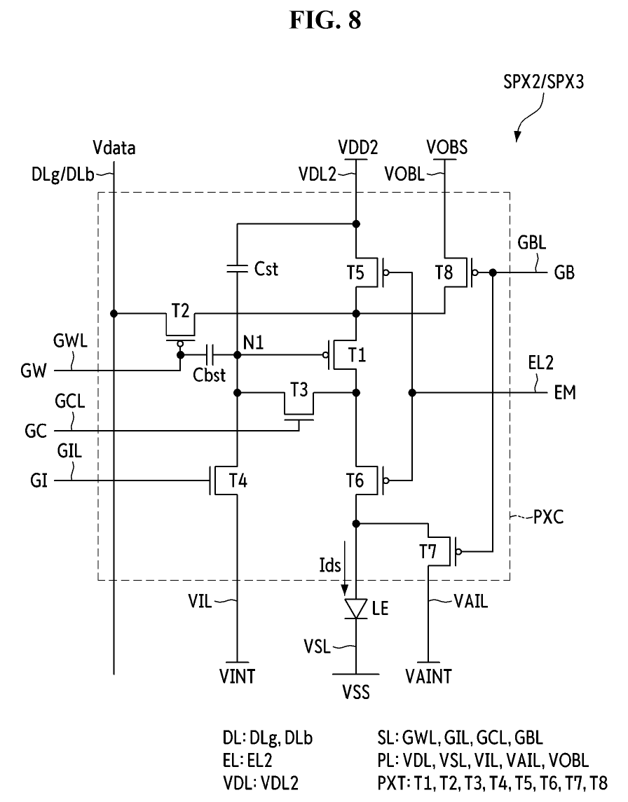

FIG. 7 is an equivalent circuit diagram of a first subpixel SPX1 according to an embodiment. FIG. 8 is an equivalent circuit diagram of a second subpixel SPX2 and a third subpixel SPX3 according to an embodiment.

Referring to FIGS. 7 and 8 in addition to FIGS. 1 through 6, subpixels SPX of each pixel PX may be electrically connected to different data lines DL from each other. In addition, at least two of the subpixels SPX of each pixel PX may be connected to different emission control lines EL and/or different driving power lines VDL from each other.

The first subpixel SPX1 may be connected to a first data line DLr and a first emission control line EL1. The first subpixel SPX1 may emit light for a period corresponding to a first emission control signal, which is transmitted to the first emission control line EL1, in response to a data voltage Vdata applied to the first data line DLr.

In an embodiment, the first subpixel SPX1 may be driven by a driving current Ids, which is adjusted and/or set to suit the characteristics of a light emitting element LE (e.g., the optimal current density of a red micro-LED) included in the first subpixel SPX1, and the first emission control signal. Accordingly, the consumption efficiency of the light emitting element LE included in the first subpixel SPX1 may be improved or optimized.

In an embodiment, the first subpixel SPX1 may be connected to a first driving power line VDL1, and may be driven by a first driving voltage VDD1 of a first level, which is applied to the first driving power line VDL1. The first driving voltage VDD1 of the first level may be adjusted and/or set to be suitable for the driving current Ids of the first subpixel SPX1. For example, the first driving voltage VDD1 of the first level may have a voltage value that is optimized to appropriately and/or efficiently drive the light emitting element LE of the first subpixel SPX1 using the driving current Ids of the first subpixel SPX1, while reducing or improving the power consumption of the display device 1. In an embodiment, when the driving current Ids of the first subpixel SPX1 is relatively higher than driving currents Ids of the second and third subpixels SPX2 and SPX3, the first driving voltage VDD1 of the first level may be higher than a first driving voltage VDD2 of a second level, which is applied to the second and third subpixels SPX2 and SPX3.

The second subpixel SPX2 may be connected to a second data line DLg and a second emission control line EL2. The second subpixel SPX2 may emit light for a period corresponding to a second emission control signal, which is transmitted to the second emission control line EL2, in response to a data voltage Vdata applied to the second data line DLg.

The third subpixel SPX3 may be connected to a third data line DLb and the second emission control line EL2. The third subpixel SPX3 may emit light for a period corresponding to the second emission control signal, which is transmitted to the second emission control line EL2, in response to a data voltage Vdata applied to the third data line DLb.

In an embodiment, the second subpixel SPX2 and the third subpixel SPX3 may be driven by their respective driving currents Ids, which are adjusted and/or set to suit the characteristics (e.g., the optimal current density ranges of green and blue micro-LEDs) of light emitting elements LE included in the second subpixel SPX2 and the third subpixel SPX3, and the second emission control signal. Accordingly, the consumption efficiency of the light emitting elements LE included in the second subpixel SPX2 and the third subpixel SPX3 may be improved or optimized.

In an embodiment, the second subpixel SPX2 and the third subpixel SPX3 may be connected to a second driving power line VDL2, and may be driven by the first driving voltage VDD2 of the second level, which is applied to the second driving power line VDL2. The first driving voltage VDD2 of the second level may be adjusted and/or set to be suitable for the driving currents Ids of the second subpixel SPX2 and the third subpixel SPX3. For example, the first driving voltage VDD2 of the second level may have a voltage value that is optimized to appropriately and/or efficiently drive the respective light emitting elements LE of the second subpixel SPX2 and the third subpixel SPX3 using the driving currents Ids of the second subpixel SPX2 and the third subpixel SPX3, while reducing or improving the power consumption of the display device 1. Accordingly, the consumption efficiency of the light emitting elements LE included in the second subpixel SPX2 and the third subpixel SPX3 may be improved or optimized, and the power consumption of the display device 1 may be improved.

When the first subpixel SPX1 and the second and third subpixels SPX2 and SPX3 are respectively connected to the first driving power line VDL1 and the second driving power line VDL2 and are driven by different first driving voltages VDD from each other, a storage capacitor Cst of the first subpixel SPX1 may be electrically insulated from storage capacitors Cst of the second and third subpixels SPX2 and SPX3. For example, one electrode of the storage capacitor Cst of the first subpixel SPX1 (e.g., an electrode opposite to an electrode connected to a first node N1 of the first subpixel SPX1) may be electrically connected to the first driving power line VDL1. On the other hand, one electrode of the storage capacitor Cst of each of the second and third subpixels SPX2 and SPX3 (e.g., an electrode opposite to an electrode connected to a first node N1 of each of the second subpixel SPX2 and the third subpixel SPX3) may be electrically connected to the second driving power line VDL2, which is separated from the first driving power line VDL1.

According to the above, the emission periods, the driving currents Ids, and/or the first driving voltages VDD of the subpixels SPX may be differentiated and/or optimized according to the characteristics of the light emitting elements LE included in the subpixels SPX. Accordingly, the consumption efficiency of the light emitting elements LE may be improved or optimized, and the power consumption of the display device 1 may be improved.

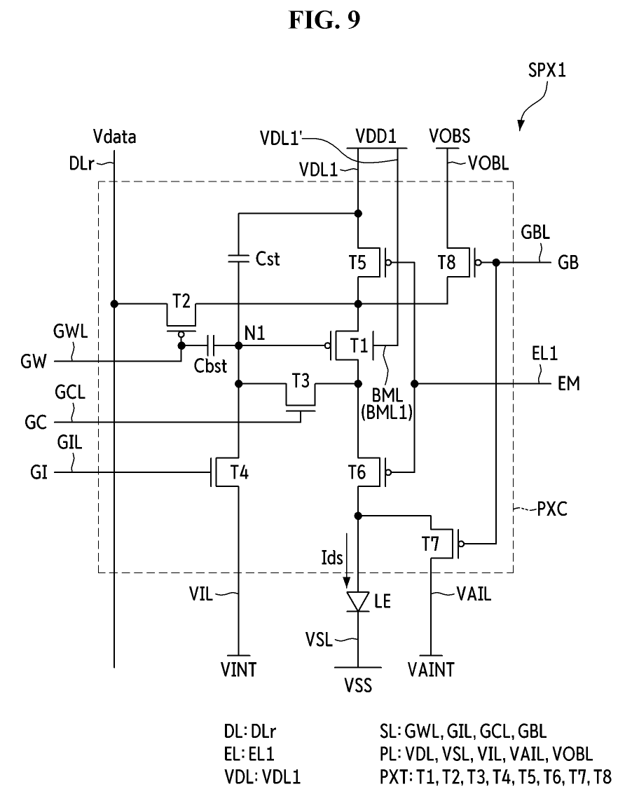

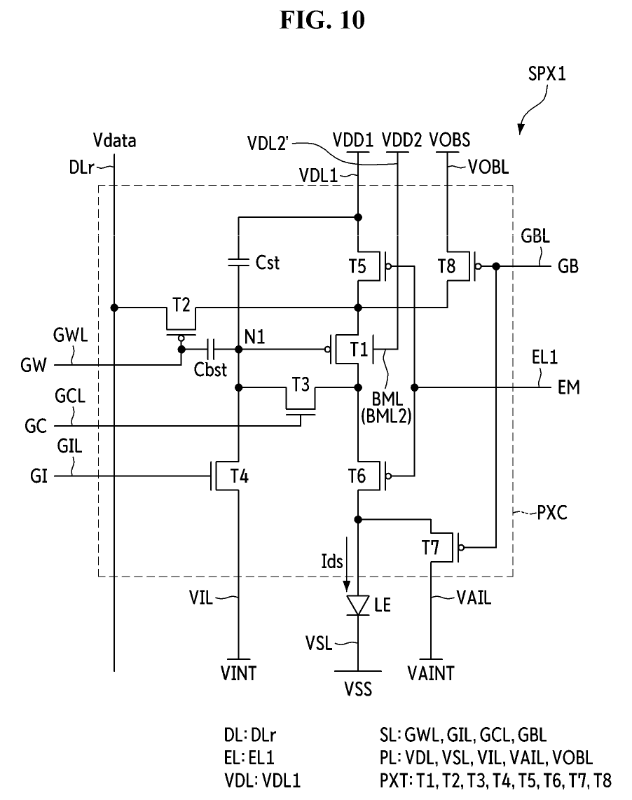

FIG. 9 is an equivalent circuit diagram of a first subpixel SPX1 according to an embodiment. FIG. 10 is an equivalent circuit diagram of a first subpixel SPX1 according to an embodiment. Compared with the embodiment described above with reference to FIG. 7, FIGS. 9 and 10 show embodiments in which the first subpixel SPX1 further includes a bottom conductive pattern BML. FIGS. 9 and 10 show different embodiments in relation to the bottom conductive pattern BML of the first subpixel SPX1.

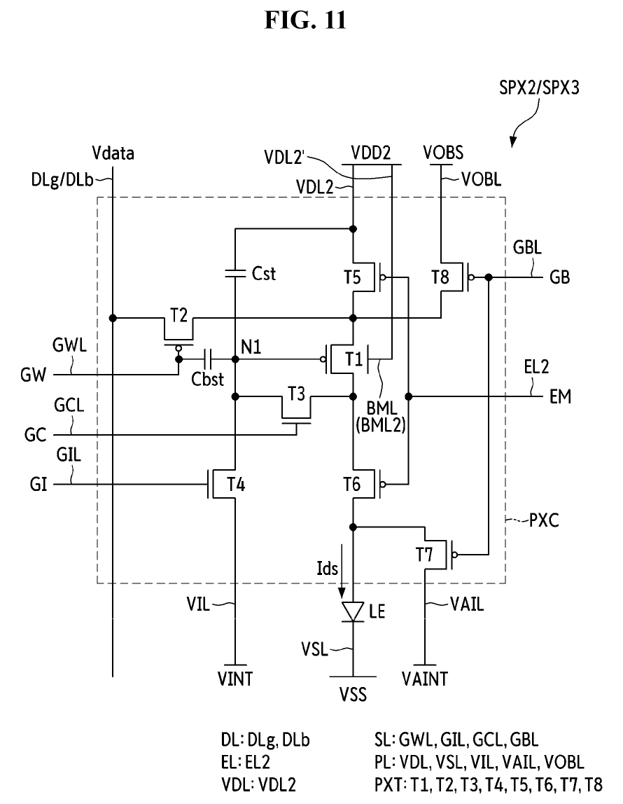

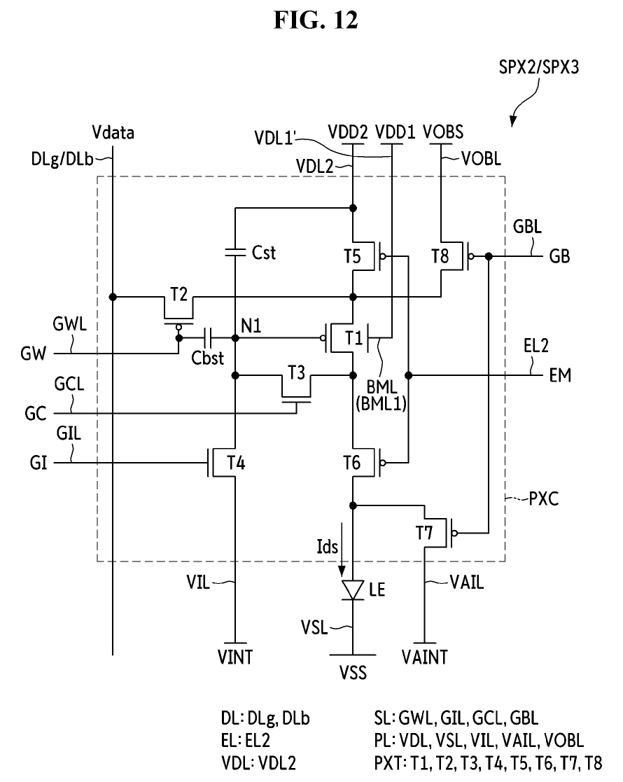

FIG. 11 is an equivalent circuit diagram of a second subpixel SPX2 and a third subpixel SPX3 according to an embodiment. FIG. 12 is an equivalent circuit diagram of a second subpixel SPX2 and a third subpixel SPX3 according to an embodiment. Compared with the embodiment described above with reference to FIG. 8, FIGS. 11 and 12 show embodiments in which each of the second subpixel SPX2 and the third subpixel SPX3 further includes a bottom conductive pattern BML. FIGS. 11 and 12 show different embodiments in relation to the bottom conductive pattern BML of each of the second subpixel SPX2 and the third subpixel SPX3.

Referring to FIGS. 9 through 12 in addition to FIGS. 7 and 8, each of the subpixels SPX may further include the bottom conductive pattern BML (e.g., a lower electrode or a bottom electrode) opposite to a gate electrode of a first transistor T1. The bottom conductive pattern BML of each of the subpixels SPX may be located under the first transistor T1 included in each of the subpixels SPX. For example, the bottom conductive pattern BML of each of the subpixels SPX may be located under an active layer and the gate electrode of the first transistor T1 included in each of the subpixels SPX. The bottom conductive pattern BML and the gate electrode of the first transistor T1 may face each other with the active layer of the first transistor T1 therebetween. The active layer of the first transistor T1 may be located between the bottom conductive pattern BML and the gate electrode of the first transistor T1.

In some embodiments, a constant voltage may be applied to the bottom conductive pattern BML of each of the subpixels SPX. In an embodiment, the constant voltage may be applied to the bottom conductive pattern BML of each of the subpixels SPX by utilizing some of the panel driving voltages supplied to the display panel 100 to drive the subpixels SPX. For example, a first driving voltage VDD1 of a first level or a first driving voltage VDD2 of a second level may be applied to the bottom conductive pattern BML of each of the subpixels SPX. The bottom conductive pattern BML to which the first driving voltage VDD1 of the first level is applied may be referred to as a “first bottom conductive pattern BML1”, and the bottom conductive pattern BML to which the first driving voltage VDD2 of the second level is applied may be referred to as a “second bottom conductive pattern BML2”.

In an embodiment, the bottom conductive pattern BML located under the first transistor T1 of the first subpixel SPX1 may be electrically connected to a power line VDL1’ to which the first driving voltage VDD1 of the first level is applied, as illustrated in FIG. 9. In an embodiment, the power line VDL1’ connected to the bottom conductive pattern BML (e.g., the first bottom conductive pattern BML1) of the first subpixel SPX1 may be a first driving power line VDL1, or a first power bus line electrically connected to the first driving power line VDL1. For example, the bottom conductive pattern BML of the first subpixel SPX1 may be electrically connected to the first driving power line VDL1 within the display area DA, or may be electrically connected to the first driving power line VDL1 and/or the first power bus line (e.g., a power bus line to which the first driving voltage VDD1 of the first level is applied) in the non-display area NDA around the display area DA. Accordingly, the first driving voltage VDD1 of the first level may be applied to the bottom conductive pattern BML of the first subpixel SPX1. In an embodiment, when the bottom conductive pattern BML of the first subpixel SPX1 is electrically connected to the first driving power line VDL1, the bottom conductive pattern BML of the first subpixel SPX1 may be considered as a wiring that branches from the first driving power line VDL1, or as a part of the first driving power line VDL1.

In an embodiment, the bottom conductive pattern BML located under the first transistor T1 of the first subpixel SPX1 may be electrically connected to a power line VDL2’ to which the first driving voltage VDD2 of the second level is applied, as illustrated in FIG. 10. In an embodiment, the power line VDL2’ connected to the bottom conductive pattern BML (e.g., the second bottom conductive pattern BML2) of the first subpixel SPX1 may be a second driving power line VDL2, or a second power bus line electrically connected to the second driving power line VDL2. For example, the bottom conductive pattern BML of the first subpixel SPX1 may be electrically connected to the second driving power line VDL2 within the display area DA, or may be electrically connected to the second driving power line VDL2 and/or the second power bus line (e.g., a power bus line to which the first driving voltage VDD2 of the second level is applied) in the non-display area NDA around the display area DA. Accordingly, the first driving voltage VDD2 of the second level may be applied to the bottom conductive pattern BML of the first subpixel SPX1. In an embodiment, when the bottom conductive pattern BML of the first subpixel SPX1 is electrically connected to the second driving power line VDL2, the bottom conductive pattern BML of the first subpixel SPX1 may be considered as a wiring that branches from the second driving power line VDL2, or as a part of the second driving power line VDL2.

In an embodiment, the bottom conductive pattern BML located under the first transistor T1 of each of the second subpixel SPX2 and the third subpixel SPX3 may be electrically connected to a power line VDL2’ to which the first driving voltage VDD2 of the second level is applied, as illustrated in FIG. 11. In an embodiment, the power line VDL2’ connected to the bottom conductive pattern BML (e.g., the second bottom conductive pattern BML2) of each of the second subpixel SPX2 and the third subpixel SPX3 may be a second driving power line VDL2, or a second power bus line electrically connected to the second driving power line VDL2. For example, the bottom conductive pattern BML of each of the second subpixel SPX2 and the third subpixel SPX3 may be electrically connected to the second driving power line VDL2 within the display area DA, or may be electrically connected to the second driving power line VDL2 and/or the second power bus line (e.g., a power bus line to which the first driving voltage VDD2 of the second level is applied) in the non-display area NDA around the display area DA. Accordingly, the first driving voltage VDD2 of the second level may be applied to the bottom conductive pattern BML of each of the second subpixel SPX2 and the third subpixel SPX3. In an embodiment, when the bottom conductive pattern BML of each of the second subpixel SPX2 and the third subpixel SPX3 is electrically connected to the second driving power line VDL2, the bottom conductive pattern BML of each of the second subpixel SPX2 and the third subpixel SPX3 may be considered as a wiring that branches from the second driving power line VDL2, or as a part of the second driving power line VDL2.

In an embodiment, the bottom conductive pattern BML located under the first transistor T1 of each of the second subpixel SPX2 and the third subpixel SPX3 may be electrically connected to a power line VDL1’ to which the first driving voltage VDD1 of the first level is applied, as illustrated in FIG. 12. In an embodiment, the power line VDL1’ connected to the bottom conductive pattern BML (e.g., the first bottom conductive pattern BML1) of each of the second subpixel SPX2 and the third subpixel SPX3 may be a first driving power line VDL1, or a first power bus line electrically connected to the first driving power line VDL1. For example, the bottom conductive pattern BML of each of the second subpixel SPX2 and the third subpixel SPX3 may be electrically connected to the first driving power line VDL1 within the display area DA, or may be electrically connected to the first driving power line VDL1 and/or the first power bus line (e.g., a power bus line to which the first driving voltage VDD1 of the first level is applied) in the non-display area NDA around the display area DA. Accordingly, the first driving voltage VDD1 of the first level may be applied to the bottom conductive pattern BML of each of the second subpixel SPX2 and the third subpixel SPX3. In an embodiment, when the bottom conductive pattern BML of each of the second subpixel SPX2 and the third subpixel SPX3 is electrically connected to the first driving power line VDL1, the bottom conductive pattern BML of each of the second subpixel SPX2 and the third subpixel SPX3 may be considered as a wiring that branches from the first driving power line VDL1, or as a part of the first driving power line VDL1.

In an embodiment, different voltages may be applied to the bottom conductive pattern BML of the first subpixel SPX1 and the bottom conductive patterns BML of the second and third subpixels SPX2 and SPX3. For example, as illustrated in FIGS. 9 and 11, the first driving voltage VDD1 of the first level may be applied to the bottom conductive pattern BML of the first subpixel SPX1, and the first driving voltage VDD2 of the second level may be applied to the bottom conductive patterns BML of the second and third subpixels SPX2 and SPX3.

In this case, the bottom conductive pattern BML of the first subpixel SPX1 and the bottom conductive patterns BML of the second and third subpixels SPX2 and SPX3 may be separated from each other. For example, the bottom conductive pattern BML of the first subpixel SPX1 may extend in the second direction DR2 in the display area DA, and may be located under the first transistors T1 included in the first subpixels SPX1 of the pixels PX arranged in the same pixel column of the display area DA as each other. The bottom conductive pattern BML of the second subpixel SPX2 may extend in the second direction DR2 in the display area DA, and may be located under the first transistors T1 included in the second subpixels SPX2 of the pixels PX arranged in the same pixel column of the display area DA as each other. The bottom conductive pattern BML of the third subpixel SPX3 may extend in the second direction DR2 in the display area DA, and may be located under the first transistors T1 included in the third subpixels SPX3 of the pixels PX arranged in the same pixel column of the display area DA as each other. In an embodiment, the second subpixels SPX2 and the third subpixels SPX3 of the pixels PX arranged in the same pixel column as each other may be integrally formed with each other, and may be connected to each other to form one pattern within the display area DA, but the present disclosure is not limited thereto. The bottom conductive pattern BML of the first subpixel SPX1 and the bottom conductive patterns BML of the second and third subpixels SPX2 and SPX3 may be spaced apart from each other in the first direction DR1, and may be arranged alternately along the first direction DR1.

In an embodiment, the same voltage may be applied to the bottom conductive pattern BML of the first subpixel SPX1 and the bottom conductive patterns BML of the second and third subpixels SPX2 and SPX3. For example, as illustrated in FIGS. 9 and 12, the bottom conductive pattern BML of the first subpixel SPX1 and the bottom conductive patterns BML of the second and third subpixels SPX2 and SPX3 may be the first bottom conductive patterns BML1 to which the first driving voltage VDD1 of the first level is applied. As another example, as illustrated in FIGS. 10 and 11, the bottom conductive pattern BML of the first subpixel SPX1 and the bottom conductive patterns BML of the second and third subpixels SPX2 and SPX3 may be the second bottom conductive patterns BML2 to which the first driving voltage VDD2 of the second level is applied.

In an embodiment, the bottom conductive pattern BML of the first subpixel SPX1 and the bottom conductive patterns BML of the second and third subpixels SPX2 and SPX3 may be electrically connected to a driving power line VDL, which is connected to a greater number of subpixels SPX among the first driving power line VDL1 and the second driving power line VDL2, and/or a power bus line connected to the driving power line VDL. As another example, the bottom conductive pattern BML of the first subpixel SPX1 and the bottom conductive patterns BML of the second and third subpixels SPX2 and SPX3 may be electrically connected to a driving power line VDL, to which a lower first driving voltage VDD (e.g., a first driving voltage VDD having a lower voltage value among the first driving voltage VDD1 of the first level and the first driving voltage VDD2 of the second level) is applied among the first driving power line VDL1 and the second driving power line VDL2, and/or a power bus line connected to the driving power line VDL. For example, any one panel driving voltage may be applied to each bottom conductive pattern BML in consideration of various aspects, such as ease of design, electrical stability, and/or power consumption.

In an embodiment, when the same voltage is applied to the bottom conductive pattern BML of the first subpixel SPX1 and the bottom conductive patterns BML of the second and third subpixels SPX2 and SPX3, the bottom conductive pattern BML of the first subpixel SPX1 and the bottom conductive patterns BML of the second and third subpixels SPX2 and SPX3 may be connected to each other. For example, the bottom conductive patterns BML of the display area DA may be formed as a single mesh pattern in the display area DA and the non-display area NDA around the display area DA, but the present disclosure is not limited thereto.

According to the above, the operation of the subpixels SPX may be stabilized by placing the bottom conductive patterns BML under the first transistors T1 of the subpixels SPX, and applying a constant voltage to the bottom conductive patterns BML. For example, when the bottom conductive patterns BML are placed under the first transistors T1, charges that may gather around the first transistors T1 may be dispersed by a voltage difference between scan signals adjacent to the respective gate electrodes of the first transistors T1. Accordingly, the operating characteristics of the first transistors T1 and the subpixels SPX including the first transistors T1 may be improved.

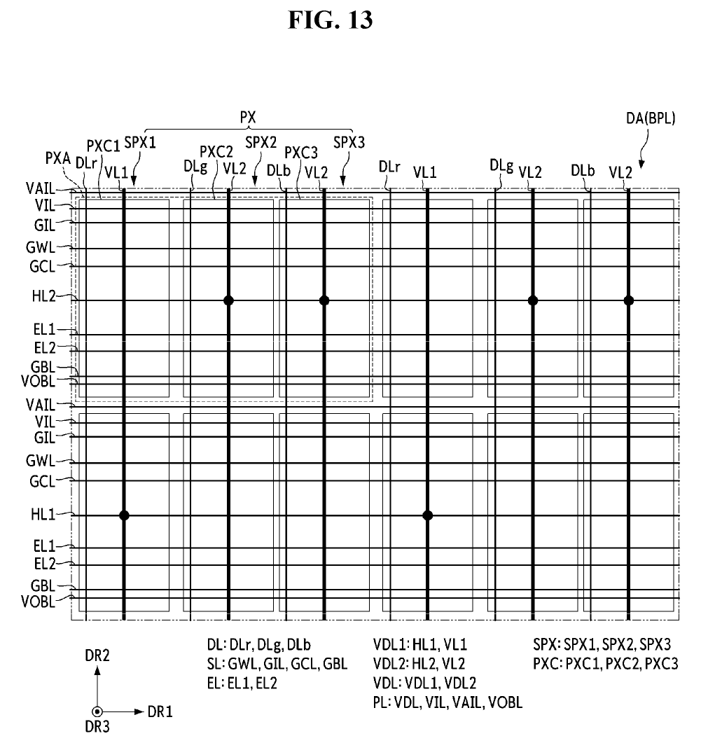

FIG. 13 is a plan view illustrating pixel circuits, signal lines, and power lines located in a backplane layer of a display panel according to an embodiment.

For example, FIG. 13 shows a rough arrangement of the pixel circuits PXC, the signal lines, and the power lines PL in the backplane layer BPL of a display panel 100 in a portion of a display area DA, which includes four pixel areas PXA in which two pixels PX are arranged along each of the first direction DR1 and the second direction DR2 in a 2x2 arrangement. FIG. 13 shows a portion of the display area DA, and each of the pixel circuits PXC, the signal lines, and the power lines PL illustrated in FIG. 13 may be repeatedly arranged in the display area DA along the first direction DR1 and/or the second direction DR2. For convenience of illustration, in FIG. 13, only the subpixels SPX located in one pixel area PXA and a pixel PX including the subpixels SPX are indicated by reference numerals.

Referring to FIG. 13 in addition to FIGS. 1 through 12, in each pixel area PXA of the display area DA, a plurality of pixel circuits PXC included in a pixel PX in the corresponding pixel area PXA may be located. For example, in each pixel area PXA, a pixel circuit PXC (hereinafter, referred to as a “first pixel circuit PXC1”) of a first subpixel SPX1, a pixel circuit PXC (hereinafter, referred to as a “second pixel circuit PXC2”) of a second subpixel SPX2, and a pixel circuit PXC (hereinafter, referred to as a “third pixel circuit PXC3”) of a third subpixel SPX3 may be located.

The first pixel circuit PXC1, the second pixel circuit PXC2, and the third pixel circuit PXC3 may be arranged in the first direction DR1 in the display area DA. For example, the first pixel circuit PXC1, the second pixel circuit PXC2, and the third pixel circuit PXC3 may be sequentially arranged along the first direction DR1 in each pixel area PXA. However, the arrangement structure and/or the order of the first pixel circuit PXC1, the second pixel circuit PXC2, and the third pixel circuit PXC3 may be variously modified as needed or desired.

In each pixel area PXA of the display area DA and/or its surroundings, signal lines and power lines PL, which are electrically connected to the subpixels SPX in the corresponding pixel area PXA, may be located. The signal lines of the display area DA may include scan lines SL, emission control lines EL, and data lines DL. The power lines PL of the display area DA may include a driving power line VDL, a first initialization power line VIL, a second initialization power line VAIL, and a bias power line VOBL. A common power line VSL connected in common to light emitting elements LE of the subpixels SPX as illustrated in FIG. 4 may or may not be located in the display area DA. For example, the common power line VSL may be located in the display area DA and may be electrically connected to the light emitting elements LE of the subpixels SPX, or may be located only in a non-display area NDA and electrically connected to the light emitting elements LE of the subpixels SPX through a common electrode extending to the non-display area NDA.

Although each of the signal lines and the power lines PL are illustrated in FIG. 13 as extending straight along the first direction DR1 and/or the second direction DR2, the present disclosure is not limited thereto. For example, FIG. 13 illustrates the overall shape, position, extension direction, and arrangement direction of each of the signal lines and the power lines PL. However, the shape, the position, the arrangement direction, and/or the size of each of the signal lines and the power lines PL may be adjusted or variously modified in consideration of a circuit density, a minimization or reduction of an interference between circuits, a defect avoidance, and/or an arrangement shape of the subpixels SPX. For example, each of the signal lines and the power lines PL may extend entirely or substantially along the first direction DR1 or the second direction DR2 (e.g., along the first direction DR1 and the second direction DR2 in the case of a mesh-shaped wiring), but at least some of the signal lines and the power lines PL may also be partially bent or curved.

The scan lines SL and the emission control lines EL may be arranged in the second direction DR2, and may each extend in the first direction DR1. In an embodiment, in each pixel row (e.g., in each horizontal line including a pixel row) in which a row of pixels PX is located, a write scan line GWL, an initialization scan line GIL, a control scan line GCL, a bias scan line GBL, a first emission control line EL1, and a second emission control line EL2, which are electrically connected to the subpixels SPX of the corresponding pixel row, may be located.

The positions and/or the arrangement order of the write scan line GWL, the initialization scan line GIL, the control scan line GCL, the bias scan line GBL, the first emission control line EL1, and the second emission control line EL2 may be variously modified depending on the design structure of each of the pixel circuits PXC. For example, the write scan line GWL may be located at a position corresponding to a second transistor T2 of each of the pixel circuits PXC. In an example, the write scan line GWL may overlap with the second transistor T2 of each of the pixel circuits PXC, or may be located around the second transistor T2. The initialization scan line GIL may be located at a position corresponding to a fourth transistor T4 of each of the pixel circuits PXC. The control scan line GCL may be located at a position corresponding to a third transistor T3 of each of the pixel circuits PXC. The bias scan line GBL may be located at a position corresponding to seventh and eighth transistors T7 and T8 of each of the pixel circuits PXC. The first emission control line EL1 and the second emission control line EL2 may be located at a position corresponding to fifth and sixth transistors T5 and T6 of each of the pixel circuits PXC. The first emission control line EL1 and the second emission control line EL2 connected to the pixels PX of each pixel row may be adjacent to each other in the second direction DR2.

The data lines DL may be arranged in the first direction DR1, and may each extend in the second direction DR2. In an embodiment, in each pixel column (e.g., in each vertical line) in which a column of pixels PX is located, a first data line DLr, a second data line DLg, and a third data line DLb, which are connected to the subpixels SPX of the corresponding pixel column, may be located.

The first data line DLr may be located at a position corresponding to the second transistor T2 of each of the first pixel circuits PXC1. For example, the first data line DLr may overlap with the second transistor T2 of each of the first pixel circuits PXC1, or may be located around the second transistor T2. The second data line DLg may be located at a position corresponding to the second transistor T2 of each of the second pixel circuits PXC2. The third data line DLb may be located at a position corresponding to the second transistor T2 of each of the third pixel circuits PXC3.

The driving power line VDL may include a first driving power line VDL1 and a second driving power line VDL2 to which a first driving voltage VDD1 of a first level and a first driving voltage VDD2 of a second level are applied, respectively. The first driving power line VDL1 may be electrically connected to the first subpixels SPX1 of the pixels PX, and the second driving power line VDL2 may be electrically connected to the second and third subpixels SPX2 and SPX3 of the pixels PX. In an embodiment, when first driving voltages VDD of different levels from each other are to be applied to the second subpixels SPX3 and the third subpixels SPX3, the driving power line VDL may include three driving power lines electrically connected to the first subpixels SPX1, the second subpixels SPX2, and the third subpixels SPX3, respectively, and separated from each other.

In an embodiment, each of the first driving power line VDL1 and the second driving power line VDL2 may be a mesh-shaped wiring located in the display area DA. For example, the first driving power line VDL1 may be formed as a mesh-shaped wiring including first vertical power lines VL1 and first horizontal power lines HL1, which cross or intersect each other in the display area DA, and electrically connected to each other. In an embodiment, the first vertical power lines VL1 and the first horizontal power lines HL1 may be electrically connected to each other within the display area DA. The second driving power line VDL2 may be formed as a mesh-shaped wiring including second vertical power lines VL2 and second horizontal power lines HL2, which cross or intersect each other in the display area DA, and electrically connected to each other. In an embodiment, the second vertical power lines VL2 and the second horizontal power lines HL2 may be electrically connected to each other within the display area DA.

The first vertical power lines VL1 and the second vertical power lines VL2 may be arranged in the first direction DR1 in the display area DA, and may be spaced apart from each other in the first direction DR1. Each of the first vertical power lines VL1 and the second vertical power lines VL2 may extend in the second direction DR2.

The first vertical power lines VL1 may overlap with the first pixel circuits PXC1, and may be electrically connected to the first pixel circuits PXC1. The second vertical power lines VL2 may overlap with the second pixel circuits PXC2 and the third pixel circuits PXC3, and may be electrically connected to the second pixel circuits PXC2 and the third pixel circuits PXC3. In an embodiment, in each pixel column in which a plurality of pixels PX are arranged along the second direction DR2, one first vertical power line VL1, which overlaps with the first pixel circuits PXC1, and two second vertical power lines VL2, which respectively overlap with the second pixel circuits PXC2 and the third pixel circuits PXC3, may be located. However, the present disclosure is not limited thereto. For example, a pair of a second pixel circuit PXC2 and a third pixel circuit PXC3 in the first direction DR1 may also share one second vertical power line VL2.

The first horizontal power lines HL1 and the second horizontal power lines HL2 may be arranged in the second direction DR2 in the display area DA, and may be spaced apart from each other in the second direction DR2. Each of the first horizontal power lines HL1 and the second horizontal power lines HL2 may extend in the first direction DR1. In FIG. 13, a pair of a first horizontal power line HL1 and a second horizontal power line HL2 arranged in a pair of pixel rows neighboring each other in the second direction DR2 is illustrated. However, a plurality of first horizontal power lines HL1 and a plurality of second horizontal power lines HL2 may be arranged (e.g., alternately arranged) along the second direction DR2 in the display area DA in the same or substantially the same manner as that illustrated in FIG. 13.

In an embodiment, one first horizontal power line HL1 or one second horizontal power line HL2 may be located in each pixel row in which a plurality of pixels PX are arranged along the first direction DR1. In an embodiment, the first horizontal power lines HL1 and the second horizontal power lines HL2 may be alternately arranged in every at least one pixel row, or in every at least one horizontal line. For example, the first horizontal power lines HL1 may be located in odd pixel rows of the display area DA, and the second horizontal power lines HL2 may be located in even pixel rows. As another example, the first horizontal power lines HL1 may be located in even pixel rows of the display area DA, and the second horizontal power lines HL2 may be located in odd pixel rows. For example, among a first pixel row and a second pixel row arranged in the second direction DR2 in the display area DA (e.g., a pair of pixel rows adjacent to each other in the second direction DR2), one of the first horizontal power lines HL1 may be located in the first pixel row, and one of the second horizontal power lines HL2 may be located in the second pixel row. However, the present disclosure is not limited thereto. For example, the number, the ratio, the spacing, the period, and/or the order of the first horizontal power lines HL1 and the second horizontal power lines HL2 may be variously modified as needed or desired.

The first initialization power line VIL may be located in each pixel row (e.g., in each horizontal line), and may extend in the first direction DR1. The first initialization power line VIL may be located at a position corresponding to the fourth transistor T4 of each of the pixel circuits PXC.

The second initialization power line VAIL may be located in each pixel row (e.g., in each horizontal line), and may extend in the first direction DR1. The second initialization power line VAIL may be located at a position corresponding to the seventh transistor T7 of each of the pixel circuits PXC. The bias power line VOBL may be located in each pixel row (e.g., in each horizontal line), and may extend in the first direction DR1. The bias power line VOBL may be located at a position corresponding to the eighth transistor T8 of each of the pixel circuits PXC.

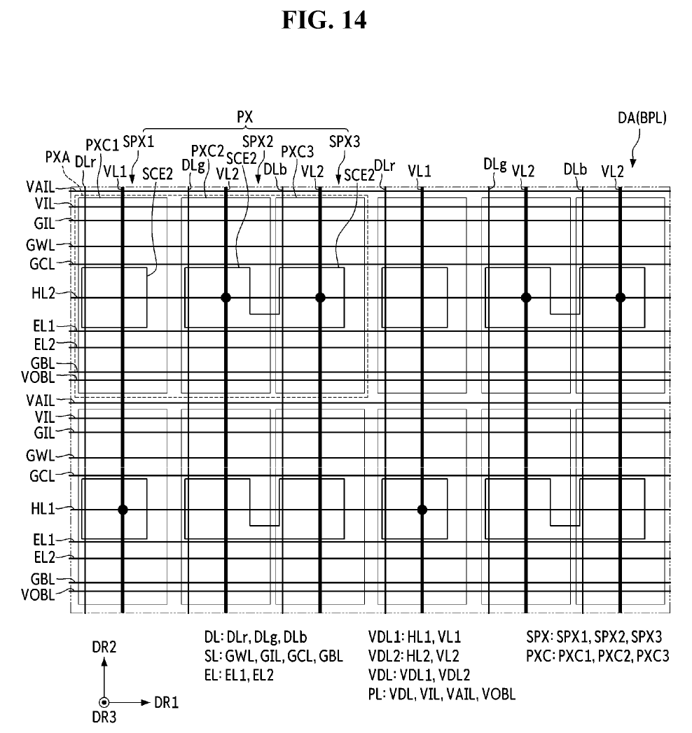

FIG. 14 is a plan view illustrating pixel circuits, signal lines, and power lines located in a backplane layer of a display panel according to an embodiment. Compared with the embodiment illustrated in FIG. 13, FIG. 14 further shows one electrode (e.g., one capacitor electrode) SCE2 of a storage capacitor Cst included in each of the pixel circuits PXC of the subpixels SPX.

Referring to FIG. 14 in addition to FIGS. 7 through 13, a storage capacitor Cst of each of the first subpixels SPX1 may be electrically connected between a first node N1, to which a gate electrode of a first transistor T1 is connected, and a first driving power line VDL1. In an embodiment, the storage capacitor Cst of each of the first subpixels SPX1 may include a first capacitor electrode integrated with the gate electrode of the first transistor T1, and the second capacitor electrode SCE2 overlapping with the first capacitor electrode.

In an embodiment, the second capacitor electrode SCE2 of each of the first subpixels SPX1 may be an island-shaped pattern that is individually formed in each of the first subpixels SPX1. The second capacitor electrode SCE2 of each of the first subpixels SPX1 may be electrically connected to the first driving power line VDL1 through at least one contact hole and/or connection pattern.

A storage capacitor Cst of each of the second subpixels SPX2 and the third subpixels SPX3 may be electrically connected between a first node N1, to which a gate electrode of a first transistor T1 is connected, and a second driving power line VDL2. In an embodiment, the storage capacitor Cst of each of the second subpixels SPX2 and the third subpixels SPX3 may include a first capacitor electrode integrated with the gate electrode of the first transistor T1, and the second capacitor electrode SCE2 overlapping with the first capacitor electrode.

In an embodiment, the second capacitor electrode SCE2 of each of the second subpixels SPX2 and the third subpixels SPX3 may be an island-shaped pattern that is individually formed in at least one subpixel area. For example, the second capacitor electrode SCE2 of each of the second subpixels SPX2 and the third subpixels SPX3 may be formed in a pixel circuit area of each of the second subpixels SPX2 and the third subpixels SPX3.

In an embodiment, the second capacitor electrodes SCE2 included in the second subpixel SPX2 and the third subpixel SPX3 of each pixel PX may be integrally formed with each other. For example, the second capacitor electrodes SCE2 included in the second subpixel SPX2 and the third subpixel SPX3 of each pixel PX may be connected to each other to form one pattern. In an embodiment, the respective second capacitor electrodes SCE2 of the second subpixel SPX2 and the third subpixel SPX3 may be formed separately from each other in their respective subpixel areas in the same shape as that of the second capacitor electrode SCE2 of the first subpixel SPX1.

The second capacitor electrode SCE2 of each of the second subpixels SPX2 and the third subpixels SPX3 may be electrically connected to the second driving power line VDL2 through at least one contact hole and/or connection pattern.

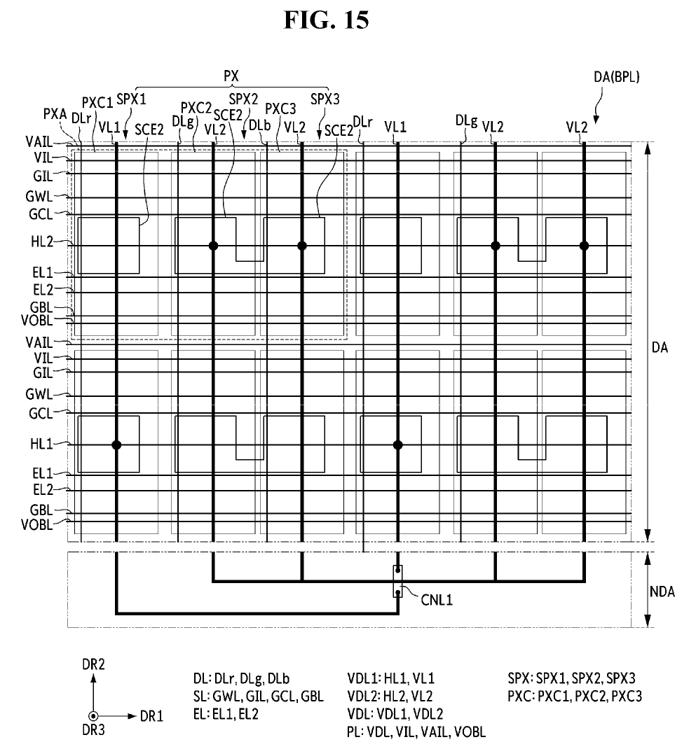

FIG. 15 is a plan view illustrating pixel circuits, signal lines, and power lines located in a backplane layer of a display panel according to an embodiment. Compared with the embodiment illustrated in FIG. 14, FIG. 15 further shows a connection structure of the first vertical power lines VL1 and a connection structure of the second vertical power lines VL2 according to an embodiment.

Referring to FIG. 15 in addition to FIGS. 7 through 14, the first vertical power lines VL1 may be connected to each other in a non-display area NDA, and the second vertical power lines VL2 may be connected to each other in the non-display area NDA. The first vertical power lines VL1 may be integrally formed with each other, or may be electrically connected to each other through at least one connection wiring. The second vertical power lines VL2 may be integrally formed with each other, or may be electrically connected to each other through at least one connection wiring.

In an embodiment, the first vertical power lines VL1 may be connected to each other through at least one first connection wiring CNL1 located in the non-display area NDA, and the second vertical power lines VL2 may be integrally connected to each other in the non-display area NDA. In an embodiment, the second vertical power lines VL2 may be connected to each other through at least one connection wiring located in the non-display area NDA, and the first vertical power lines VL1 may be integrally connected to each other in the non-display area NDA.

For example, the first vertical power lines VL1 and the second vertical power lines VL2 may be arranged, such that lines to which the same first driving voltage VDD (e.g., a first driving voltage VDD1 of a first level or a first driving voltage VDD2 of a second level) is applied are integrally formed with each other, or are non-integrally formed and connected to each other through at least one connection wiring. In an embodiment, when the first vertical power lines VL1 and the second vertical power lines VL2 (or power bus lines respectively connected to the first vertical power lines VL1 and the second vertical power lines VL2) cross or intersect each other in the non-display area NDA, the first vertical power lines VL1 or the second vertical power lines VL2 may be connected to each other using a connection wiring (e.g., the first connection wiring CNL1) located in a different conductive layer from those of the first vertical power lines VL1 and the second vertical power lines VL2. Therefore, electrical stability (e.g., insulation) between the first vertical power lines VL1 and the second vertical power lines VL2 may be secured. However, the connection structure of the first vertical power lines VL1 and/or the connection structure of the second vertical power lines VL2 may be variously modified as needed or desired.

The first vertical power lines VL1 may be electrically connected to the power supply unit 500 (e.g., see FIG. 3) through at least one wiring and/or pad located in the non-display area NDA. The second vertical power lines VL2 may be electrically connected to the power supply unit 500 through at least one wiring and/or pad located in the non-display area NDA. Accordingly, the first driving voltages VDD (e.g., the first driving voltage VDD1 of the first level and the first driving voltage VDD2 of the second level) output form the power supply unit 500 may be applied to the first vertical power lines VL1 and the second vertical power lines VL2.

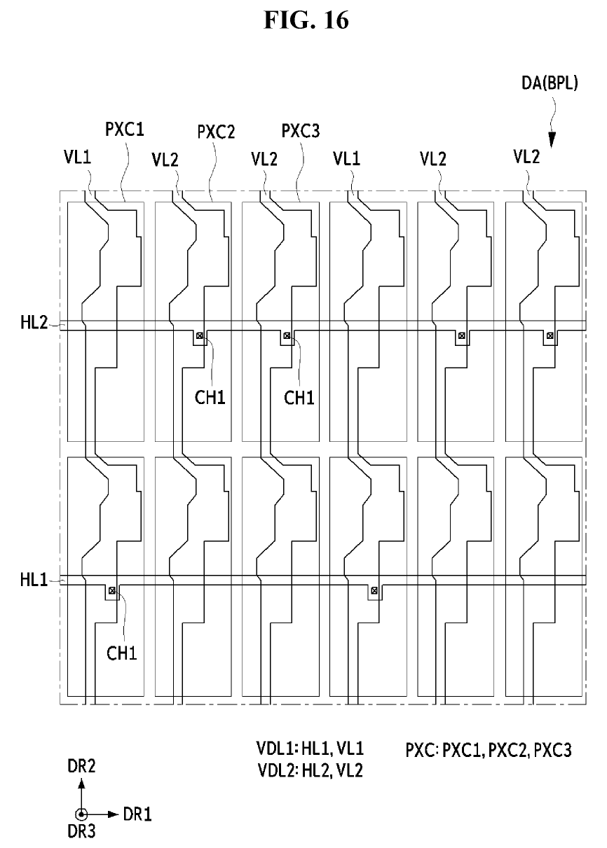

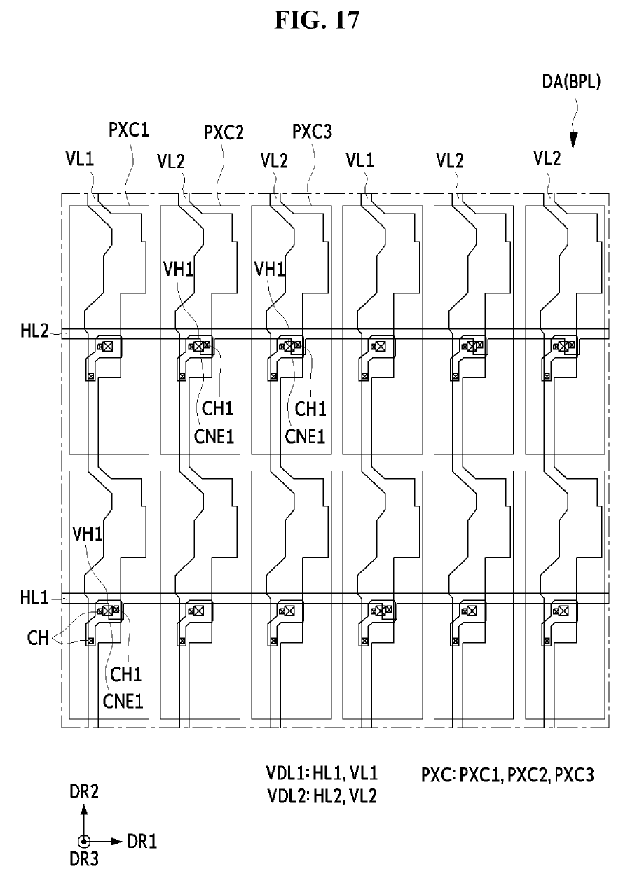

FIG. 16 is a plan view illustrating a first driving power line and a second driving power line according to an embodiment. FIG. 17 is a plan view illustrating a first driving power line and a second driving power line according to an embodiment. Compared with the embodiment illustrated in FIG. 16, FIG. 17 further shows first connection patterns CNE1 located in the pixel circuits PXC.

Referring to FIGS. 16 and 17 in addition to FIGS. 7 through 15, first vertical power lines VL1 and first horizontal power lines HL1 may be formed as patterns included in different conductive layers from each other, and may be electrically connected to each other at points where they cross or intersect each other, or may be electrically connected to each other at points where they are adjacent to each other. For example, in pixel rows in which the first horizontal power lines HL1 are located, the first vertical power lines VL1 and the first horizontal power lines HL1 may be electrically connected to each other through at least one contact hole (e.g., a first contact hole CH1 formed in each of the first pixel circuits PXC1) and/or at least one connection pattern (e.g., a first connection pattern CNE1 formed in each of the first pixel circuits PXC1).

Second vertical power lines VL2 and second horizontal power lines HL2 may be formed as patterns included in different conductive layers from each other, and may be electrically connected to each other at points where they cross or intersect each other, or may be electrically connected to each other at points where they are adjacent to each other. For example, in pixel rows in which the second horizontal power lines HL2 are located, the second vertical power lines VL2 and the second horizontal power lines HL2 may be electrically connected to each other through at least one contact hole (e.g., a first contact hole CH1 formed in each of the second pixel circuits PXC2 and third pixel circuits PXC3) and/or at least one connection pattern (e.g., a first connection pattern CNE1 formed in each of the second pixel circuits PXC2 and the third pixel circuits PXC3).

In an embodiment, the first vertical power lines VL1 and the second vertical power lines VL2 may be patterns formed separately from each other among patterns included in the same conductive layer (e.g., one of source-drain conductive layers included in a backplane layer BPL). In an embodiment, at least a portion of each of the first vertical power lines VL1 and the second vertical power lines VL2 may have a relatively larger width compared with that of signal lines and the like, and may overlap with at least one circuit element (e.g., a first transistor T1, a storage capacitor Cst, a third transistor T3, and a fourth transistor T4) included in each of the pixel circuits PXC. For example, the first vertical power lines VL1 and the second vertical power lines VL2 may be partially expanded or bent as needed or desired, and may cover a channel region of at least one pixel transistor PXT (e.g., the first transistor T1, the third transistor T3, and the fourth transistor T4) included in each of the pixel circuits PXC. Accordingly, it may be possible to block or reduce an incidence of light from above the backplane layer BPL onto the at least one pixel transistor PXT, and improve operating characteristics of the pixel circuits PXC.

In an embodiment, the first horizontal power lines HL1 and the second horizontal power lines HL2 may be patterns formed separately from each other among patterns included in the same conductive layer (e.g., one of gate conductive layers included in the backplane layer BPL). In an embodiment, the first horizontal power lines HL1 may be partially expanded in areas where the first contact holes CH1 are formed to connect the first vertical power lines VL1 and the first horizontal power lines HL1 to each other. Accordingly, the first vertical power lines VL1 and the first horizontal power lines HL1 may be stably and/or easily connected to each other. The second horizontal power lines HL2 may be partially expanded in areas where the first contact holes CH1 are formed to connect the second vertical power lines VL2 and the second horizontal power lines HL2 to each other. Accordingly, the second vertical power lines VL2 and the second horizontal power lines HL2 may be stably and/or easily connected to each other.

In an embodiment, as illustrated in FIG. 17, each of the first vertical power lines VL1 and each of the first horizontal power lines HL1 may be electrically connected to one another using the first connection pattern CNE1 located or formed in each of the first pixel circuits PXC1. In addition, each of the second vertical power lines VL2 and each of the second horizontal power lines HL2 may be electrically connected to one another using the first connection pattern CNE1 located or formed in each of the second pixel circuits PXC2 and the third pixel circuits PXC3. In an embodiment, the first connection patterns CNE1 may be formed as patterns of a conductive layer located between a conductive layer including the first vertical power lines VL1 and the second vertical power lines VL2 and a conductive layer including the first horizontal power lines HL1 and the second horizontal power lines HL2.

The first connection pattern CNE1 of each of the first pixel circuits PXC1 located at crossings or intersections of the first vertical power lines VL1 and the first horizontal power lines HL1 may electrically connect each first vertical power line VL1 and each first horizontal power line HL1 to one another. For example, the first connection pattern CNE1 of each of the first pixel circuits PXC1 located at the crossings or intersections of the first vertical power lines VL1 and the first horizontal power lines HL1 may be electrically connected to a first horizontal power line HL1, which is located below the first connection pattern CNE1, through a first contact hole CH1, and may be electrically connected to a first vertical power line VL1, which is located above the first connection pattern CNE1, through a first via hole VH1.

The first connection pattern CNE1 of each of the second pixel circuits PXC2 located at crossings or intersections of the second vertical power lines VL2 and the second horizontal power lines HL2 may electrically connect each second vertical power line VL2 and each second horizontal power line HL2 to one another. For example, the first connection pattern CNE1 of each of the second pixel circuits PXC2 located at the crossings or intersections of the second vertical power lines VL2 and the second horizontal power lines HL2 may be electrically connected to a second horizontal power line HL2, which is located below the first connection pattern CNE1, through a first contact hole CH1, and may be electrically connected to a second vertical power line VL2, which is located above the first connection pattern CNE1, through a first via hole VH1.

The first connection pattern CNE1 of each of the third pixel circuits PXC3 located at crossings or intersections of the second vertical power lines VL2 and the second horizontal power lines HL2 may electrically connect each second vertical power line VL2 and each second horizontal power line HL2 to one another. For example, the first connection pattern CNE1 of each of the third pixel circuits PXC3 located at the crossings or intersections of the second vertical power lines VL2 and the second horizontal power lines HL2 may be electrically connected to a second horizontal power line HL2, which is located below the first connection pattern CNE1, through a first contact hole CH1, and may be electrically connected to a second vertical power line VL2, which is located above the first connection pattern CNE1, through a first via hole VH1.

In an embodiment, the first via hole VH1 may be a kind of contact hole located in an upper part of the backplane layer BPL. For example, the first via hole VH1 may be an opening formed in an insulating layer on the first connection pattern CNE1 to expose the first connection pattern CNE1, or may be a contact hole formed in an insulating layer on the first connection pattern CNE1 (e.g., a contact hole formed in at least one organic insulating layer located in the upper part of the backplane layer BPL). The first vertical power lines VL1 and the second vertical power lines VL2 may partially or entirely fill their respective first via holes VH1.

In an embodiment, each first connection pattern CNE1 may be electrically connected to at least one circuit element and/or electrode included in each pixel circuit PXC. For example, each first connection pattern CNE1 may be electrically connected to one electrode (e.g., the second capacitor electrode SCE2 of FIGS. 14 and 15) of the storage capacitor Cst, which is included in each pixel circuit PXC, through at least one contact hole CH formed in an area overlapping with the storage capacitor Cst. In addition, each first connection pattern CNE1 may be electrically connected to a portion of a fifth transistor T5 (e.g., a source region of the fifth transistor T5, or a source electrode electrically connected to the source region), which is included in each pixel circuit PXC, through at least one other contact hole CH formed in an area overlapping with the fifth transistor T5.

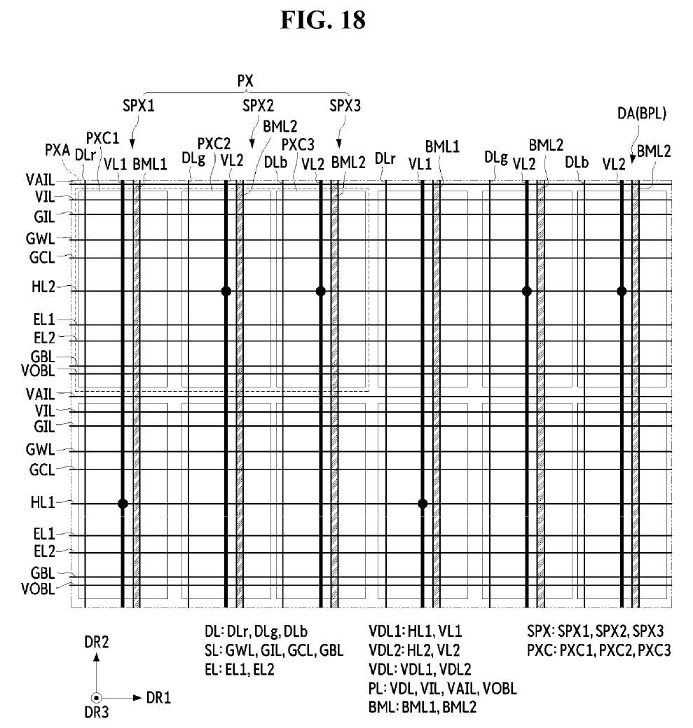

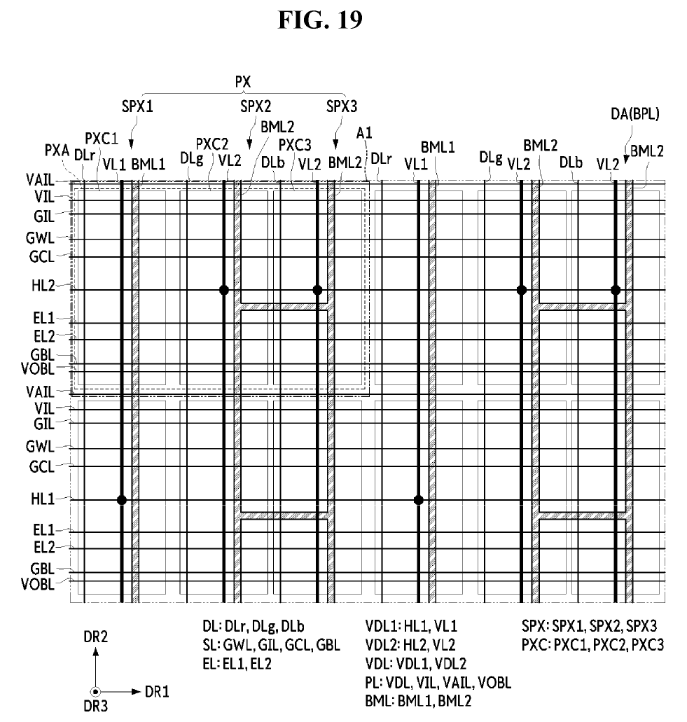

FIG. 18 is a plan view illustrating pixel circuits, signal lines, power lines, and bottom conductive patterns located in a backplane layer of a display panel according to an embodiment. FIG. 19 is a plan view illustrating pixel circuits, signal lines, power lines, and bottom conductive patterns located in a backplane layer of a display panel according to an embodiment. Compared with the embodiment illustrated in FIG. 13, FIGS. 18 and 19 show embodiments in which bottom conductive patterns BML are further located in a display area DA. FIGS. 18 and 19 schematically illustrate the positions and the arrangements of the bottom conductive patterns BML.

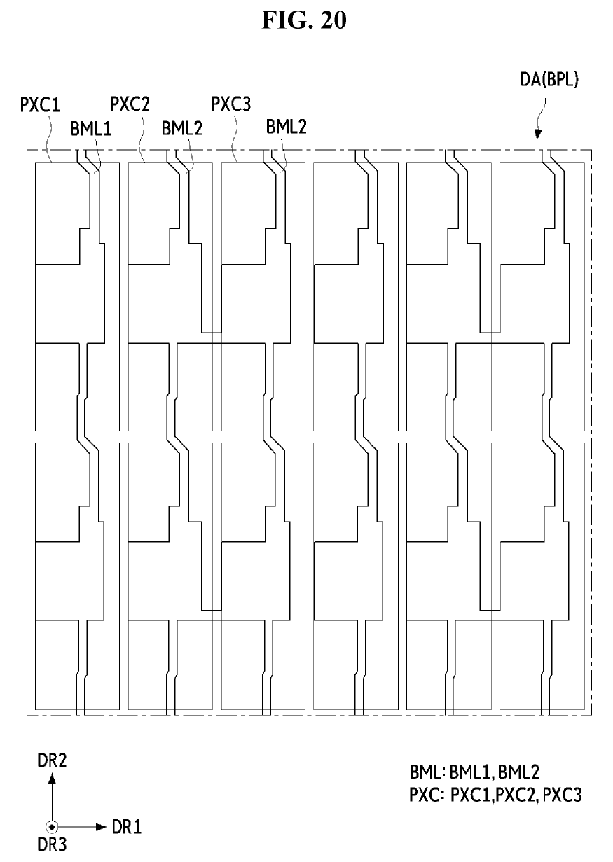

FIG. 20 is a plan view illustrating bottom conductive patterns according to an embodiment. For example, FIG. 20 shows the bottom conductive patterns BML according to the embodiment of FIG. 19.

Referring to FIGS. 18 through 20 in addition to FIGS. 9 through 17, the bottom conductive patterns BML including first bottom conductive patterns BML1 and second bottom conductive patterns BML2 may be further located in the display area DA. In an embodiment, the bottom conductive patterns BML may be located inside a backplane layer BPL. For example, the bottom conductive patterns BML may be formed as patterns of a bottom conductive layer located at a lowermost position among conductive layers included in the backplane layer BPL. However, the present disclosure is not limited thereto. For example, the bottom conductive patterns BML may also be located under the backplane layer BPL (e.g., between a substrate and the backplane layer BPL). The first bottom conductive patterns BML1 and the second bottom conductive patterns BML2 may be arranged in the first direction DR1, and may each extend in the second direction DR2.

The first bottom conductive patterns BML1 may overlap with the first pixel circuits PXC1. For example, the first bottom conductive patterns BML1 may be located under at least some circuit elements included in the first pixel circuits PXC1 (e.g., respective first transistors T1 and/or the like of the first pixel circuits PXC1).

The second bottom conductive patterns BML2 may overlap with the second pixel circuits PXC2 and the third pixel circuits PXC3. For example, the second bottom conductive patterns BML2 may be located under at least some circuit elements included in the second pixel circuits PXC2 and the third pixel circuits PXC3 (e.g., respective first transistors T1 and/or the like of the second pixel circuits PXC2 and the third pixel circuits PXC3).

In an embodiment, a first driving voltage VDD1 of a first level and a first driving voltage VDD2 of a second level may be applied to the first bottom conductive patterns BML1 and the second bottom conductive patterns BML2, respectively. The first bottom conductive patterns BML1 and the second bottom conductive patterns BML2 may be separated and/or spaced from each other, and may be electrically insulated from each other.

In an embodiment, as illustrated in FIG. 18, the second bottom conductive patterns BML2 may be separated and/or spaced from each other within the display area DA. The second bottom conductive patterns BML2 may be connected at the periphery of the display area DA and/or the like.

In an embodiment, at least two adjacent second bottom conductive patterns BML2 may be connected to each other within the display area DA. For example, as illustrated in FIGS. 19 and 20, a pair of second bottom conductive patterns BML2 adjacent to each other in the first direction DR1 (e.g., second bottom conductive patterns BML2 overlapping with the second and third pixel circuits PXC2 and PXC3 of each pixel column) may be connected to each other in each pixel area PXA. In an embodiment, the pair of second bottom conductive patterns BML2 may be integrally formed with each other, and may form or substantially form one second bottom conductive pattern BML2.

In an embodiment, at least a portion of each of the first bottom conductive patterns BML1 and the second bottom conductive patterns BML2 may have a relatively larger width compared with those of signal lines and/or the like, and may overlap with at least one circuit element (e.g., a first transistor T1 and a storage capacitor Cst) included in each of the pixel circuits PXC. For example, the first bottom conductive patterns BML1 and the second bottom conductive patterns BML2 may be partially expanded or bent as needed or desired, and may be located under a channel region of the first transistor T1 included in each of the pixel circuits PXC. Accordingly, charges that may gather around the first transistor T1 of each of the pixel circuits PXC may be dispersed, thereby improving the operating characteristics of the first transistor T1. In an embodiment, the first bottom conductive patterns BML1 and the second bottom conductive patterns BML2 may be formed as patterns having light-blocking and/or reflective properties, and may block or reduce an incidence of light from under the first transistors T1 onto the first transistors T1. Accordingly, the operating characteristics of the first transistors T1 may be further improved.

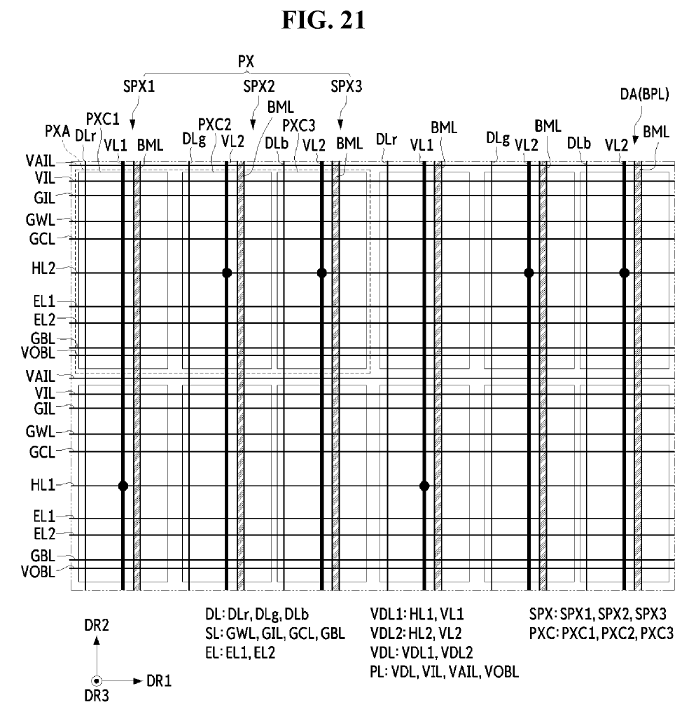

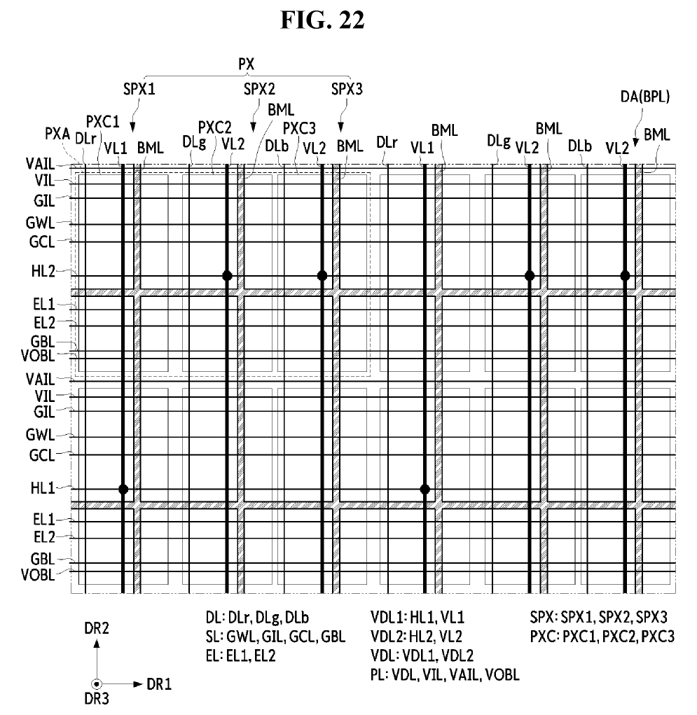

FIG. 21 is a plan view illustrating pixel circuits, signal lines, power lines, and bottom conductive patterns located in a backplane layer of a display panel according to an embodiment. FIG. 22 is a plan view illustrating pixel circuits, signal lines, power lines, and bottom conductive patterns located in a backplane layer of a display panel according to an embodiment.

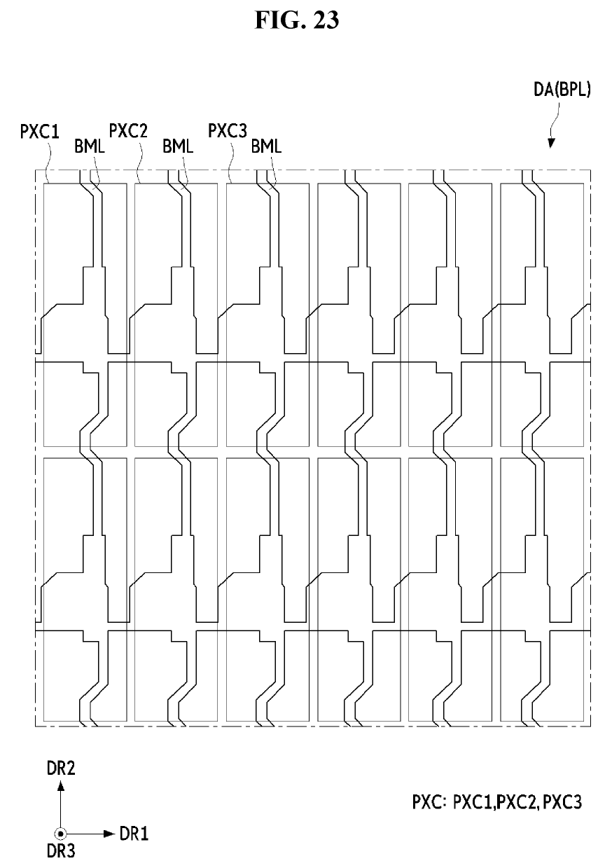

FIG. 23 is a plan view illustrating bottom conductive patterns according to an embodiment. For example, FIG. 23 shows bottom conductive patterns BML according to the embodiment of FIG. 22. Compared with the embodiments illustrated in FIGS. 18 through 20, FIGS. 21 through 23 show embodiments in which the bottom conductive patterns BML of a display area DA are patterns to which the same voltage is applied.

Referring to FIGS. 21 through 23 in addition to FIGS. 9 through 20, the bottom conductive pattern BML of a first subpixel SPX1 and the bottom conductive patterns BML of second and third subpixels SPX2 and SPX3 may be patterns to which the same voltage is applied. For example, the bottom conductive pattern BML of the first subpixel SPX1 and the bottom conductive patterns BML of the second and third subpixels SPX2 and SPX3 may be patterns to which a first driving voltage VDD1 of a first level or a first driving voltage VDD2 of a second level is applied.

In an embodiment, as illustrated in FIG. 21, the bottom conductive patterns BML may be separated and/or spaced from each other within the display area DA. The bottom conductive patterns BML may be connected at the periphery of the display area DA.

In an embodiment, the bottom conductive patterns BML may be connected to each other within the display area DA. For example, as illustrated in FIGS. 22 and 23, the bottom conductive patterns BML may be connected to each other in a mesh form within the display area DA. In an embodiment, the bottom conductive patterns BML may be integrally formed with each other, and may form or substantially form one bottom conductive pattern BML (e.g., a mesh-shaped bottom conductive pattern BML).

In an embodiment, at least a portion of each of the bottom conductive patterns BML may have a relatively larger width compared with those of signal lines and/or the like, and may overlap with at least one circuit element included in each of the pixel circuits PXC. For example, the bottom conductive patterns BML may be located under a channel region of a first transistor T1 included in each of the pixel circuits PXC. Accordingly, the operating characteristics of the first transistor T1 may be improved.

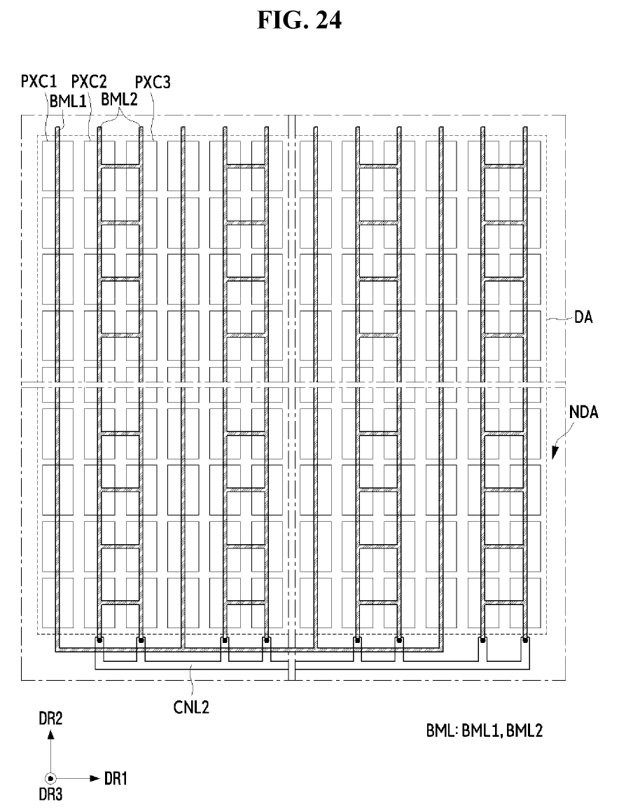

FIG. 24 is a plan view illustrating a connection structure of bottom conductive patterns according to an embodiment. For example, FIG. 24 shows the connection structure of the first bottom conductive patterns BML1 and the second bottom conductive patterns BML2 according to the embodiments of FIGS. 19 and 20.

Referring to FIG. 24, the first bottom conductive patterns BML1 may be connected to each other in a non-display area NDA, and the second bottom conductive patterns BML2 may be connected to each other in the non-display area NDA. The first bottom conductive patterns BML1 may be integrally formed with each other, or may be electrically connected to each other through at least one connection wiring. The second bottom conductive patterns BML2 may be integrally formed with each other, or may be electrically connected to each other through at least one connection wiring.

In an embodiment, the first bottom conductive patterns BML1 may be integrally connected to each other in the non-display area NDA, and the second bottom conductive patterns BML2 may be connected to each other through at least one second connection wiring CNL2 located in the non-display area NDA. In an embodiment, the first bottom conductive patterns BML1 may be connected to each other through at least one connection wiring located in the non-display area NDA, and the second bottom conductive patterns BML2 may be integrally connected to each other in the non-display area NDA.

For example, the first bottom conductive patterns BML1 and the second bottom conductive patterns BML2 may be arranged, such that patterns to which the same voltage (e.g., a first driving voltage VDD1 of a first level or a first driving voltage VDD2 of a second level) is applied are integrally formed with each other, or are non-integrally formed and connected to each other through at least one connection wiring. In an embodiment, when the first bottom conductive patterns BML1 and the second bottom conductive patterns BML2 (or power bus lines respectively connected to the first bottom conductive patterns BML1 and the second bottom conductive patterns BML2) cross or intersect each other in the non-display area NDA, the first bottom conductive patterns BML1 or the second bottom conductive patterns BML2 may be connected to each other using a connection wiring (e.g., the second connection wiring CNL2) located in a different conductive layer from those of the first bottom conductive patterns BML1 and the second bottom conductive patterns BML2. Therefore, electrical stability (e.g., insulation) between the first bottom conductive patterns BML1 and the second bottom conductive patterns BML2 may be secured. However, the connection structure of the first bottom conductive patterns BML1 and/or the connection structure of the second bottom conductive patterns BML2 may be variously modified as needed or desired.

The first bottom conductive patterns BML1 may be connected to the power supply unit 500 (e.g., see FIG. 3) through at least one wiring and/or pad located in the non-display area NDA. The second bottom conductive patterns BML2 may be connected to the power supply unit 500 through at least one wiring and/or pad located in the non-display area NDA. Accordingly, constant voltages (e.g., the first driving voltage VDD1 of the first level and the first driving voltage VDD2 of the second level) output from the power supply unit 500 may be applied to the first bottom conductive patterns BML1 and the second bottom conductive patterns BML2.

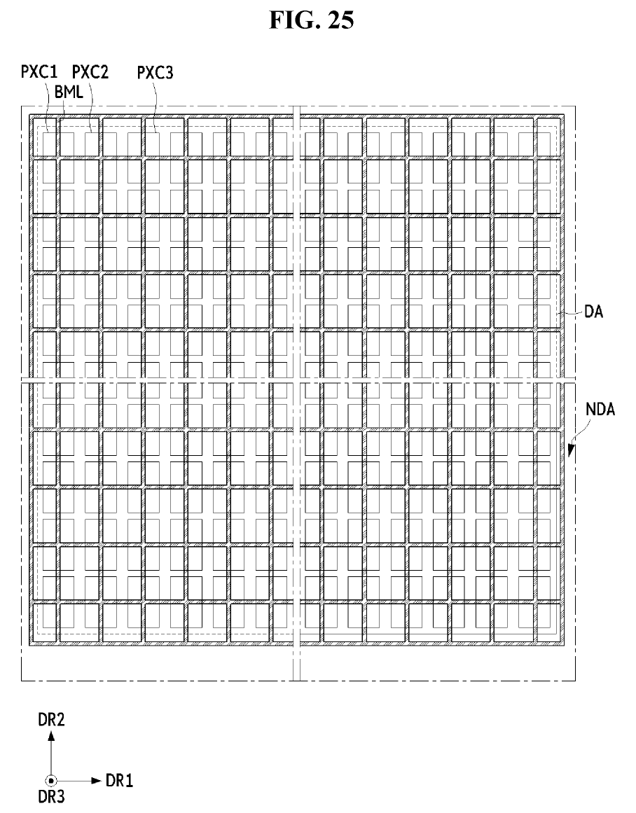

FIG. 25 is a plan view illustrating a connection structure of bottom conductive patterns according to an embodiment. For example, FIG. 25 shows the connection structure of the bottom conductive patterns BML according to the embodiments of FIG. 22 and FIG. 23.

Referring to FIG. 25, the bottom conductive patterns BML may be formed as one or substantially one mesh-shaped bottom conductive pattern BML. For example, the bottom conductive patterns BML may be connected to each other in a display area DA and a non-display area NDA around the display area DA to form one mesh-shaped pattern.

The bottom conductive patterns BML may be connected to the power supply unit 500 (e.g., see FIG. 3) through at least one wiring and/or pad located in the non-display area NDA. Accordingly, a constant voltage (e.g., a first driving voltage VDD1 of a first level or a first driving voltage VDD2 of a second level) output from the power supply unit 500 may be applied to the bottom conductive patterns BML.

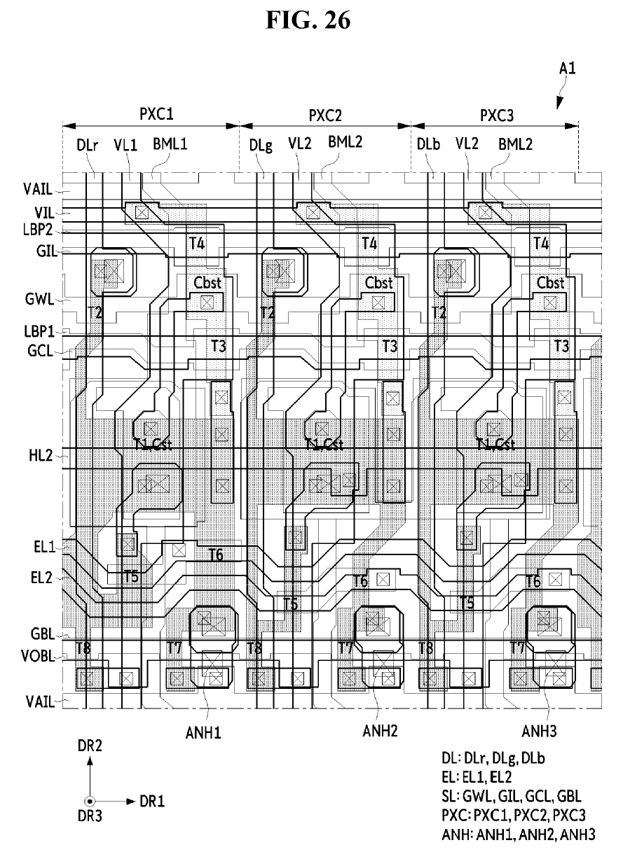

FIG. 26 is a layout view of a backplane layer of a display panel according to an embodiment. For example, FIG. 26 shows an embodiment of a layout of a backplane layer BPL in a portion of a display area DA corresponding to the area A1 of FIG. 19. The area A1 of FIGS. 19 and 26 may include one pixel area PXA, which includes a first pixel circuit PXC1, a second pixel circuit PXC2, and a third pixel circuit PXC3, and an area around the pixel area PXA.

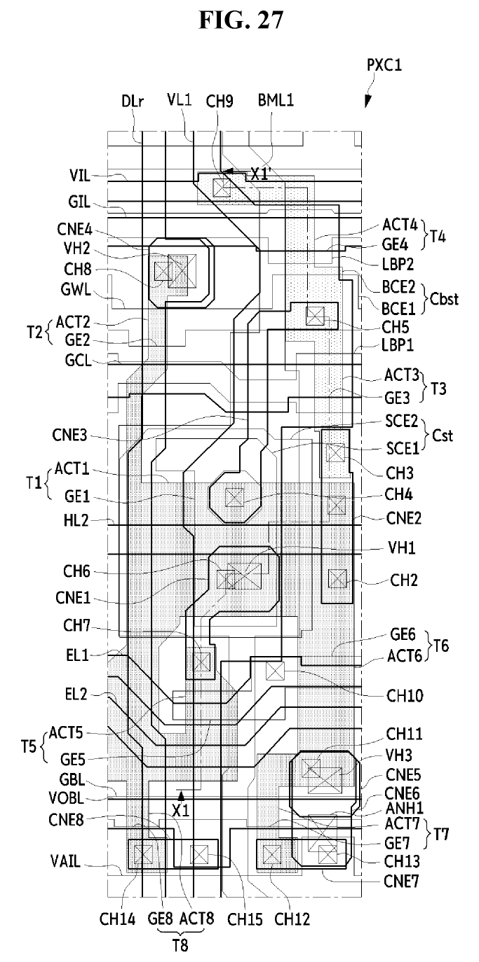

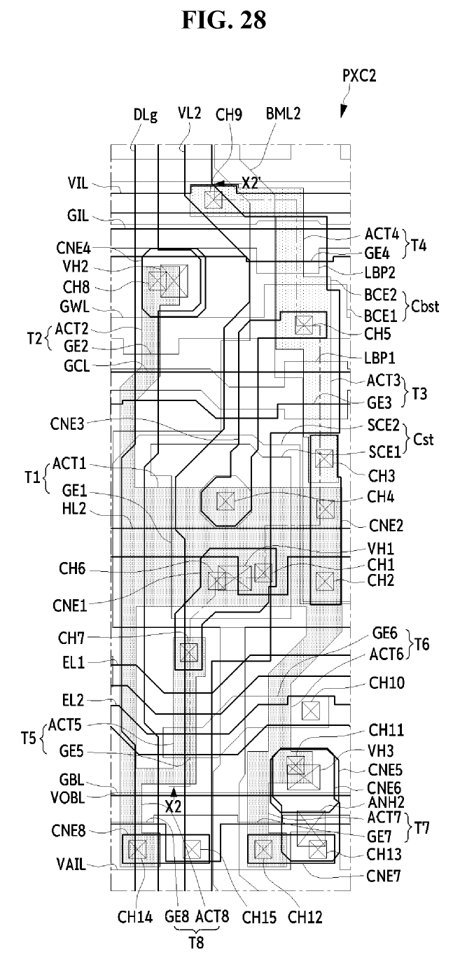

FIG. 27 is a more detailed layout view of the first pixel circuit PXC1 of FIG. 26. FIG. 28 is a more detailed layout view of the second pixel circuit PXC2 of FIG. 26.

The structures or the shapes of the second pixel circuit PXC2 and the third pixel circuit PXC3 of FIG. 26 may be the same or substantially the same as (or similar to) each other. For example, the layout structures or the shapes of the second pixel circuit PXC2 and the third pixel circuit PXC3 of FIG. 26 may be the same or substantially the same as each other, except that the second capacitor electrodes SCE2 of the second pixel circuit PXC2 and the third pixel circuit PXC3 may be connected to each other, and that second bottom conductive patterns BML2 of the second pixel circuit PXC2 and the third pixel circuit PXC3 (e.g., the second bottom conductive patterns BML2 overlapping with the second pixel circuit PXC2 and the third pixel circuit PXC3) are connected to each other.

Referring to FIGS. 26 through 28 in addition to FIGS. 7 through 25, each of the first pixel circuit PXC1, the second pixel circuit PXC2, and the third pixel circuit PXC3 may include first through eighth transistors T1 through T8, a storage capacitor Cst, and a boosting capacitor Cbst.

The first transistor T1 may include a first active layer ACT1 and a first gate electrode GE1. The first gate electrode GE1 may overlap with a portion of the first active layer ACT1.

The first active layer ACT1 may include a channel region overlapping with the first gate electrode GE1, and a source region and a drain region located on different sides of the channel region from each other. In FIGS. 26 through 28, the source region and the drain region included in the active layer of each of the transistors, as well as the first active layer ACT1, are not illustrated as being distinguished from each other. However, depending on the type (e.g., P-type or N-type) of each of the transistors and the voltage applied to opposite ends (e.g., both ends) of each of the transistors, a portion of the active layer included in each of the transistors may be a source region, and another portion of the active layer may be a drain region.

The source region of the first active layer ACT1 may be electrically connected to second, fifth, and eighth active layers ACT2, ACT5, and ACT8 included in the second, fifth, and eighth transistors T2, T5, and T8. For example, the first active layer ACT1, the second active layer ACT2, the fifth active layer ACT5, and the eighth active layer ACT8 may be integrally formed with each other, and the source region of the first active layer ACT1 may be electrically connected to a portion (e.g., a drain region) of each of the second, fifth, and eighth active layers ACT2, ACT5, and ACT8. The drain region of the first active layer ACT1 may be electrically connected to third and sixth active layers ACT3 and ACT6 included in the third and sixth transistors T3 and T6. For example, the drain region of the first active layer ACT1 may be electrically connected to a second connection pattern CNE2 through at least one second contact hole CH2, and may be electrically connected to a portion (e.g., a drain region) of the third active layer ACT3 through the second connection pattern CNE2. The first active layer ACT1 may also be integrally formed with sixth and seventh active layers ACT6 and ACT7. The drain region of the first active layer ACT1 may be electrically connected to a portion (e.g., a source region) of the sixth active layer ACT6.

The second connection pattern CNE2 may be electrically connected to a portion of the first active layer ACT1 through at least one second contact hole CH2. For example, the second connection pattern CNE2 may be electrically connected to the drain region of the first active layer ACT1 through a plurality of second contact holes CH2. The second connection pattern CNE2 may be electrically connected to the third transistor T3 through a third contact hole CH3. For example, the second connection pattern CNE2 may be electrically connected to a portion of the third active layer ACT3 (e.g., the drain region of the third active layer ACT3) through the third contact hole CH3.

The first gate electrode GE1 may be electrically connected to a first capacitor electrode SCE1 of the storage capacitor Cst. For example, the first gate electrode GE1 and the first capacitor electrode SCE1 may be integrally formed with each other, and may be formed as one or substantially one conductive pattern. The first gate electrode GE1 may be electrically connected to a third connection pattern CNE3 through a fourth contact hole CH4, and may be electrically connected to the third and fourth transistors T3 and T4 through the third connection pattern CNE3. The third connection pattern CNE3 may be electrically connected to a portion (e.g., a source or drain region) of each of the third and fourth active layers ACT3 and ACT4, which are included in the third and fourth transistors T3 and T4, through a fifth contact hole CH5.

The backplane layer BPL (or the display panel 100) may further include bottom conductive patterns BML located under the first active layer ACT1. For example, the backplane layer BPL may further include a bottom conductive layer (e.g., a bottom metal layer) located between a first semiconductor layer, in which the first active layer ACT1 is located, and a substrate, and the bottom conductive layer may include the bottom conductive patterns BML overlapping with the channel region of the first active layer ACT1. In an embodiment, the bottom conductive patterns BML may include a first bottom conductive pattern BML1 located under the first active layer ACT1 of the first pixel circuit PXC1, and second bottom conductive patterns BML2 located under the first active layers ACT1 of the second and third pixel circuits PXC2 and PXC3. In an embodiment, the second bottom conductive patterns BML2 located under the first active layers ACT1 of the second and third pixel circuits PXC2 and PXC3 included in each pixel PX may be integrally formed with each other to form one or substantially one pattern, but the present disclosure is not limited thereto.

The storage capacitor Cst may include the first capacitor electrode SCE1 and the second capacitor electrode SCE2, which overlap with each other. The first capacitor electrode SCE1 may be integrally formed with the first gate electrode GE1. The second capacitor electrode SCE2 may be electrically connected to a driving power line VDL. For example, the second capacitor electrode SCE2 may be electrically connected to a first connection pattern CNE1 through a sixth contact hole CH6, and may be electrically connected to a driving power line VDL (e.g., a first vertical power line VL1 of a first driving power line VDL1 or a second vertical power line VL2 of a second driving power line VDL2) through the first connection pattern CNE1. In an embodiment, the second capacitor electrode SCE2 may be opened at a portion (e.g., the fourth contact hole CH4 and its surroundings) where the first capacitor electrode SCE1 and the third connection pattern CNE3 are connected.

The first connection pattern CNE1 may be electrically connected to the driving power line VDL through a first via hole VH1 (e.g., a contact hole). For example, the first connection pattern CNE1 of the first pixel circuit PXC1 may be electrically connected to the first vertical power line VL1 of the first driving power line VDL1 through the first via hole VH1, and the first connection pattern CNE1 of each of the second pixel circuit PXC2 and the third pixel circuit PXC3 may be electrically connected to the second vertical power line VL2 of the second driving power line VDL2 through the first via hole VH1. In addition, the first connection pattern CNE1 may be electrically connected to a portion (e.g., a source region) of the fifth active layer ACT5, which is included in the fifth transistor T5, through a seventh contact hole CH7.

The first connection pattern CNE1 of the first pixel circuit PXC1 may overlap with a portion of a second horizontal power line HL2, but may not be connected to the second horizontal power line HL2. The first connection pattern CNE1 of each of the second pixel circuit PXC2 and the third pixel circuit PXC3 may overlap with a portion of the second horizontal power line HL2, and may be electrically connected to the second horizontal power line HL2 through a first contact hole CH1. Accordingly, in a pixel row in which the second horizontal power line HL2 is located (e.g., a horizontal line including the second horizontal power line HL2), the second horizontal power line HL2 and the second vertical power lines VL2 may be electrically connected to each other through the first connection patterns CNE1 of the second pixel circuit PXC2 and the third pixel circuit PXC3.

In another pixel row, for example, in a pixel row in which a first horizontal power line HL1 is located (e.g., a horizontal line including the first horizontal power line HL1), the first connection pattern CNE1 of the first pixel circuit PXC1 may be electrically connected to the first horizontal power line HL1 through a first contact hole CH1. Accordingly, in the pixel row in which the first horizontal power line HL1 is located, the first horizontal power line HL1 and the first vertical power line VL1 may be electrically connected to each other through the first connection pattern CNE1 of the first pixel circuit PXC1. In addition, in the pixel row in which the first horizontal power line HL1 is located, the first connection pattern CNE1 of each of the second pixel circuit PXC2 and the third pixel circuit PXC3 may not be connected to the first horizontal power line HL1.

The second transistor T2 may include the second active layer ACT2 and a second gate electrode GE2. The second gate electrode GE2 may overlap with a portion of the second active layer ACT2.

The second active layer ACT2 may include a channel region overlapping with the second gate electrode GE2, and a source region and a drain region located on different sides of the channel region from each other. The source region of the second active layer ACT2 may be electrically connected to a data line DL. For example, the source region of the second active layer ACT2 may be electrically connected to a fourth connection pattern CNE4 through an eighth contact hole CH8, and may be electrically connected to a data line DL (e.g., a first data line DLr, a second data line DLg, or a third data line DLb) of each subpixel SPX through the fourth connection pattern CNE4. The fourth connection pattern CNE4 may be electrically connected to the data line DL of each subpixel SPX through a second via hole VH2 (e.g., a contact hole). The drain region of the second active layer ACT2 may be electrically connected to the first, fifth, and eighth active layers ACT1, ACT5, and ACT8 included in the first, fifth, and eighth transistors T1, T5, and T8. For example, the drain region of the second active layer ACT2 may be electrically connected to the source region of the first active layer ACT1 and the drain region of each of the fifth and eighth active layers ACT5 and ACT8.

The second gate electrode GE2 may be electrically connected to a write scan line GWL. For example, the second gate electrode GE2 and the write scan line GWL may be integrally formed with each other, and may be formed as one or substantially one conductive pattern. In this case, a portion of the write scan line GWL, overlapping with the second active layer ACT2 may function as the second gate electrode GE2.

The third transistor T3 may include the third active layer ACT3 and a third gate electrode GE3. The third gate electrode GE3 may overlap with a portion of the third active layer ACT3.

The third active layer ACT3 may include a channel region overlapping with the third gate electrode GE3, and a source region and a drain region located on different sides of the channel region from each other. The source region of the third active layer ACT3 may be electrically connected to the first gate electrode GE1 of the first transistor T1 and the fourth active layer ACT4 of the fourth transistor T4. For example, the source region of the third active layer ACT3 may be electrically connected to the third connection pattern CNE3 through the fifth contact hole CH5, and may be electrically connected to the first gate electrode GE1 of the first transistor T1 through the third connection pattern CNE3. In addition, the third active layer ACT3 and the fourth active layer ACT4 may be integrally formed with each other, and the source region of the third active layer ACT3 may be electrically connected to the drain region of the fourth active layer ACT4. The drain region of the third active layer ACT3 may be electrically connected to the first active layer ACT1 of the first transistor T1. For example, the drain region of the third active layer ACT3 may be electrically connected to the second connection pattern CNE2 through the third contact hole CH3, and may be electrically connected to the drain region of the first active layer ACT1 through the second connection pattern CNE2.

The third gate electrode GE3 may be electrically connected to a control scan line GCL. For example, the third gate electrode GE3 and the control scan line GCL may be integrally formed with each other, and may be formed as one or substantially one conductive pattern. In this case, a portion of the control scan line GCL overlapping with the third active layer ACT3 may function as the third gate electrode GE3.

In an embodiment, the backplane layer BPL of the display panel 100 may further include a first light blocking pattern LBP1 located under the third active layer ACT3. The first light blocking pattern LBP1 may extend in the first direction DR1, and may overlap with the channel region of the third active layer ACT3 and the control scan line GCL. The first light blocking pattern LBP1 may block light incident from under the third active layer ACT3 toward the channel region of the third active layer ACT3. Accordingly, the operating characteristics of the third transistor T3 may be stabilized.

The fourth transistor T4 may include the fourth active layer ACT4 and a fourth gate electrode GE4. The fourth gate electrode GE4 may overlap with a portion of the fourth active layer ACT4.

The fourth active layer ACT4 may include a channel region overlapping with the fourth gate electrode GE4, and a source region and a drain region located on different sides of the channel region from each other. The source region of the fourth active layer ACT4 may be electrically connected to a first initialization power line VIL. For example, the source region of the fourth active layer ACT4 may be electrically connected to the first initialization power line VIL through a ninth contact hole CH9. In addition, the drain region of the fourth active layer ACT4 may be electrically connected to the first gate electrode GE1 of the first transistor T1 and the third active layer ACT3 of the third transistor T3. For example, the drain region of the third active layer ACT3 may be electrically connected to the first gate electrode GE1 of the first transistor T1 through the third connection pattern CNE3, and may be integrally formed with the source region of the third active layer ACT3. For example, the third active layer ACT3 and the fourth active layer ACT4 of each of the first pixel circuit PXC1, the second pixel circuit PXC2, and the third pixel circuit PXC3 may be integrated with each other to form one semiconductor pattern. In an embodiment, the third active layer ACT3 and the fourth active layer ACT4 may include an oxide semiconductor. Accordingly, a leakage current of the subpixels SPX may be reduced or prevented.

The fourth gate electrode GE4 may be electrically connected to an initialization scan line GIL. For example, the fourth gate electrode GE4 and the initialization scan line GIL may be integrally formed with each other, and may be formed as one or substantially one conductive pattern. In this case, a portion of the initialization scan line GIL overlapping with the fourth active layer ACT4 may function as the fourth gate electrode GE4.

In an embodiment, the backplane layer BPL of the display panel 100 may further include a second light blocking pattern LBP2 located under the fourth active layer ACT4. The second light blocking pattern LBP2 may extend in the first direction DR1, and may overlap with the channel region of the fourth active layer ACT4 and the initialization scan line GIL. The first light blocking pattern LBP1 and the second light blocking pattern LBP2 may be located in the same layer as each other within the backplane layer BPL, but the present disclosure is not limited thereto. The second light blocking pattern LBP2 may block light incident from under the fourth active layer ACT4 toward the channel region of the fourth active layer ACT4. Accordingly, the operating characteristics of the fourth transistor T4 may be stabilized.

In an embodiment, the third and fourth active layers ACT3 and ACT4 of the third and fourth transistors T3 and T4 may overlap with the write scan line GWL. The boosting capacitor Cbst may be formed between the third and fourth active layers ACT3 and ACT4 and the write scan line GWL.

The boosting capacitor Cbst may include a first electrode BCE1 and a second electrode BCE2 overlapping with each other. The first electrode BCE1 of the boosting capacitor Cbst may be integrally formed with the write scan line GWL. The second electrode BCE2 of the boosting capacitor Cbst may be integrally formed with a portion (e.g., the source or drain region) of each of the third and fourth active layers ACT3 and ACT4. In an embodiment, a capacitance of the boosting capacitor Cbst may be adjusted by controlling a size of an area where the third and fourth active layers ACT3 and ACT4 overlap with the write scan line GWL. For example, the capacitance of the boosting capacitor Cbst may be increased by increasing a width of the third and fourth active layers ACT3 and ACT4 and/or the write scan line GWL in a portion where the third and fourth active layers ACT3 and ACT4 cross or intersect the write scan line GWL.

The fifth transistor T5 may include the fifth active layer ACT5 and a fifth gate electrode GE5. The fifth gate electrode GE5 may overlap with a portion of the fifth active layer ACT5.

The fifth active layer ACT5 may include a channel region overlapping with the fifth gate electrode GE5, and a source region and a drain region located on different sides of the channel region from each other. The source region of the fifth active layer ACT5 may be electrically connected to the driving power line VDL (e.g., the first driving power line VDL1 including the first vertical power line VL1 or the second driving power line VDL2 including the second vertical power line VL2). For example, the source region of the fifth active layer ACT5 may be electrically connected to the first connection pattern CNE1 through the seventh contact hole CH7, and may be electrically connected to the first vertical power line VL1 or the second vertical power line VL2 through the first connection pattern CNE1. The drain region of the fifth active layer ACT5 may be electrically connected to the first, second, and eighth active layers ACT1, ACT2, and ACT8 included in the first, second, and eighth transistors T1, T2, and T8. For example, the drain region of the fifth active layer ACT5 may be electrically connected to the source region of the first active layer ACT1 and the drain region of each of the second and eighth active layers ACT2 and ACT8.

In an embodiment, the fifth active layer ACT5 may cross or intersect a first emission control line EL1 and a second emission control line EL2, which are electrically connected to the subpixels SPX of a corresponding pixel PX. For example, the fifth active layer ACT5 may have a roughly “U” or “Y” shape around the first emission control line EL1 and the second emission control line EL2, and may cross or intersect the first emission control line EL1 and the second emission control line EL2.

The fifth gate electrode GE5 may be electrically connected to any one emission control line EL. For example, the fifth gate electrode GE5 may be electrically connected to the first emission control line EL1 or the second emission control line EL2, which is located in a corresponding pixel row, through a tenth contact hole CH10. For example, the fifth gate electrode GE5 included in the first pixel circuit PXC1 may be electrically connected to the first emission control line EL1 through a tenth contact hole CH10 overlapping with the first emission control line EL1, and the fifth gate electrode GE5 included in each of the second and third pixel circuits PXC2 and PXC3 may be electrically connected to the second emission control line EL2 through a tenth contact hole CH10 overlapping with the second emission control line EL2.

The sixth transistor T6 may include the sixth active layer ACT6 and a sixth gate electrode GE6. The sixth gate electrode GE6 may overlap with a portion of the sixth active layer ACT6.

The sixth active layer ACT6 may include a channel region overlapping with the sixth gate electrode GE6, and a source region and a drain region located on different sides of the channel region from each other. The source region of the sixth active layer ACT6 may be electrically connected to the first and third active layers ACT1 and ACT3 included in the first and third transistors T1 and T3. For example, the source region of the sixth active layer ACT6 may be electrically connected to the drain region of each of the first and third active layers ACT1 and ACT3. The drain region of the sixth active layer ACT6 may be electrically connected to a light emitting element LE. For example, the drain region of the sixth active layer ACT6 may be electrically connected to a fifth connection pattern CNE5 through an eleventh contact hole CH11, and may be electrically connected to a pixel electrode of each subpixel SPX through fifth and sixth connection patterns CNE5 and CNE6. In an embodiment, the sixth active layer ACT6 may cross or intersect the first emission control line EL1 and the second emission control line EL2, which are electrically connected to a corresponding pixel PX.

The fifth connection pattern CNE5 may be electrically connected to the sixth connection pattern CNE6 through a third via hole VH3 (e.g., a contact hole). The sixth connection pattern CNE6 may be electrically connected to the pixel electrode of each subpixel SPX through an anode contact hole ANH of each subpixel SPX (or a cathode contact hole in the case of a display panel having a common-anode structure). For example, the sixth connection pattern CNE6 of the first pixel circuit PXC1 may be electrically connected to a first pixel electrode, which is connected to a light emitting element LE of a first subpixel SPX1, through a first anode contact hole ANH1 overlapping with the first pixel circuit PXC1. The sixth connection pattern CNE6 of the second pixel circuit PXC2 may be electrically connected to a second pixel electrode, which is connected to a light emitting element LE of a second subpixel SPX2, through a second anode contact hole ANH2 overlapping with the second pixel circuit PXC2. The sixth connection pattern CNE6 of the third pixel circuit PXC3 may be electrically connected to a third pixel electrode, which is connected to a light emitting element LE of a third subpixel SPX3, through a third anode contact hole ANH3 overlapping with the third pixel circuit PXC3.

The sixth gate electrode GE6 may be electrically connected to any one emission control line EL. For example, the sixth gate electrode GE6 may be electrically connected to the first emission control line EL1 or the second emission control line EL2, which is located in a corresponding pixel row (e.g., a horizontal line), through the tenth contact hole CH10. For example, the sixth gate electrode GE6 included in the first pixel circuit PXC1 may be electrically connected to the first emission control line EL1 through the tenth contact hole CH10 overlapping with the first emission control line EL1, and the sixth gate electrode GE6 included in each of the second and third pixel circuits PXC2 and PXC3 may be electrically connected to the second emission control line EL2 through the tenth contact hole CH10 overlapping with the second emission control line EL2.

In an embodiment, the fifth and sixth gate electrodes GE5 and GE6 of the first pixel circuit PXC1 may be formed as one conductive pattern overlapping with the first emission control line EL1, and may be electrically connected to the first emission control line EL1 through one tenth contact hole CH10 located between the fifth gate electrode GE5 and the sixth gate electrode GE6 of the first pixel circuit PXC1. In addition, the fifth and sixth gate electrodes GE5 and GE6 of each of the second and third pixel circuits PXC2 and PXC3 may be formed as one conductive pattern overlapping with the second emission control line EL2, and may be electrically connected to the second emission control line EL2 through one tenth contact hole CH10 located between the fifth gate electrode GE6 and the sixth gate electrode GE6 of each of the second and third pixel circuits PXC2 and PXC3. Accordingly, a design structure of the pixel circuits PXC may be simplified or optimized.

The seventh transistor T7 may include the seventh active layer ACT7 and a seventh gate electrode GE7. The seventh gate electrode GE7 may overlap with a portion of the seventh active layer ACT7.

The seventh active layer ACT7 may include a channel region overlapping with the seventh gate electrode GE7, and a source region and a drain region located on different sides of the channel region from each other. The source region of the seventh active layer ACT7 may be electrically connected to the sixth active layer ACT6 and the light emitting element LE. For example, the sixth and seventh active layers ACT6 and ACT7 may be integrally formed with each other, and the source region of the seventh active layer ACT7 may be electrically connected to the drain region of the sixth active layer ACT6. In addition, the source region of the seventh active layer ACT7 may be electrically connected to the fifth connection pattern CNE5 through the eleventh contact hole CH11, and may be electrically connected to the pixel electrode of each subpixel SPX through the fifth and sixth connection patterns CNE5 and CNE6. The drain region of the seventh active layer ACT7 may be electrically connected to a second initialization power line VAIL. For example, the drain region of the seventh active layer ACT7 may be electrically connected to a seventh connection pattern CNE7 through a twelfth contact hole CH12, and may be electrically connected to the second initialization power line VAIL through the seventh connection pattern CNE7. The seventh connection pattern CNE7 may be electrically connected to the second initialization power line VAIL through a thirteenth contact hole CH13.

The seventh gate electrode GE7 may be electrically connected to a bias scan line GBL. For example, the seventh gate electrode GE7 and the bias scan line GBL may be integrally formed with each other, and may be formed as one or substantially one conductive pattern. In this case, a portion of the bias scan line GBL overlapping with the seventh active layer ACT7 may function as the seventh gate electrode GE7.

The eighth transistor T8 may include the eighth active layer ACT8 and an eighth gate electrode GE8. The eighth gate electrode GE8 may overlap with a portion of the eighth active layer ACT8.

The eighth active layer ACT8 may include a channel region overlapping with the eighth gate electrode GE8, and a source region and a drain region located on different sides of the channel region from each other. The source region of the eighth active layer ACT8 may be electrically connected to a bias power line VOBL. For example, the source region of the eighth active layer ACT8 may be electrically connected to an eighth connection pattern CNE8 through a fourteenth contact hole CH14, and may be electrically connected to the bias power line VOBL through the eighth connection pattern CNE8. The eighth connection pattern CNE8 may be electrically connected to the bias power line VOBL through a fifteenth contact hole CH15. The drain region of the eighth active layer ACT8 may be electrically connected to the first, second, and fifth active layers ACT1, ACT2, and ACT5 included in the first, second, and fifth transistors T1, T2, and T5. For example, the drain region of the eighth active layer ACT8 may be electrically connected to the source region of the first active layer ACT1 and the drain region of each of the second and fifth active layers ACT2 and ACT5.

In an embodiment, the first active layer ACT1, the second active layer ACT2, the fifth active layer ACT5, the sixth active layer ACT6, the seventh active layer ACT7, and the eighth active layer ACT8 of each of the first pixel circuit PXC1, the second pixel circuit PXC2, and the third pixel circuit PXC3 may be integrally formed with each other, and may be formed as one or substantially one semiconductor pattern. The first active layer ACT1, the second active layer ACT2, the fifth active layer ACT5, the sixth active layer ACT6, the seventh active layer ACT7, and the eighth active layer ACT8 may include the same semiconductor material as each other, for example, such as polycrystalline silicon.

The eighth gate electrode GE8 may be electrically connected to the bias scan line GBL. For example, the eighth gate electrode GE8 and the bias scan line GBL may be integrally formed with each other, and may be formed as one or substantially one conductive pattern. In this case, a portion of the bias scan line GBL overlapping with the eighth active layer ACT8 may function as the eighth gate electrode GE8.

Signal lines and power lines PL of the backplane layer BPL may be located around the circuit elements to which the lines are connected. In an embodiment, each first vertical power line VL1 and each second vertical power line VL2 may have a relatively larger width at positions corresponding to the first transistor T1, the third transistor T3, and the fourth transistor T4 of each pixel circuit PXC, and may cover at least a portion of each of the first transistor T1, the third transistor T3, and the fourth transistor T4. For example, each first vertical power line VL1 and each second vertical power line VL2 may entirely or partially cover the channel region of each of the first transistor T1, the third transistor T3, and the fourth transistor T4 of each pixel circuit PXC. For example, the first vertical power line VL1 overlapping with the first pixel circuit PXC1 may cover the channel region of each of the first transistor T1, the third transistor T3, and the fourth transistor T4 of the first pixel circuit PXC1. The second vertical power lines VL2 overlapping with the second and third pixel circuits PXC2 and PXC3, respectively, may cover the respective channel regions of the first transistors T1, the third transistors T3, and the fourth transistors T4 of the second and third pixel circuits PXC2 and PXC3. Accordingly, light incident from above the backplane layer BPL toward the channel regions of the first transistors T1, the third transistors T3, and the fourth transistors T4 may be blocked or reduced without a light blocking pattern on the first transistors T1, the third transistors T3, and the fourth transistors T4. Accordingly, the operating characteristics of the first transistors T1, the third transistors T3, and the fourth transistors T4 may be stabilized, and a design structure of the backplane layer BPL may be further optimized.

In an embodiment, the subpixels SPX may be driven with driving currents Ids that are differentiated or optimized according to the optimal consumption efficiency of the light emitting elements LE. In addition, the pixel transistors PXT located in current paths through which the driving currents Ids flow in the subpixels SPX may have different sizes according to their respective driving currents Ids. For example, the first transistors T1 of at least two subpixels SPX among the first subpixel SPX1, the second subpixel SPX2, and the third subpixel SPX3 may have different sizes (e.g., ratios of a channel width to a channel length) from each other.

In an embodiment, the first subpixel SPX1 may be driven with a greater driving current Ids than those of the second subpixel SPX2 and the third subpixel SPX3, in response to a data voltage Vdata of each gray level. In this case, a size of the first transistor T1 of the first subpixel SPX1 may be larger than a size of the first transistor T1 of each of the second subpixel SPX2 and the third subpixel SPX3. For example, a ratio of a channel width to a channel length of the first transistor T1 of the first subpixel SPX1 may be greater than a ratio of a channel width to a channel length of the first transistor T1 of each of the second subpixel SPX2 and the third subpixel SPX3. Similarly, a size (e.g., a ratio of a channel width to a channel length) of the fifth transistor T5 of the first subpixel SPX1 may be larger than a size (e.g., a ratio of a channel width to a channel length) of the fifth transistor T5 of each of the second subpixel SPX2 and the third subpixel SPX3. A size of the sixth transistor T6 of the first subpixel SPX1 may be larger than a size of the sixth transistor T6 of each of the second subpixel SPX2 and the third subpixel SPX3. Accordingly, a current handling capability of the first transistor T1 included in the first subpixel SPX1 may be increased.

When the subpixels SPX are driven with the driving currents Ids optimized according to the optimal consumption efficiency of their respective light emitting elements LE, the consumption efficiency and lifespan of the light emitting elements LE may be improved. Accordingly, the power consumption and lifespan of the display device 1 may be improved.

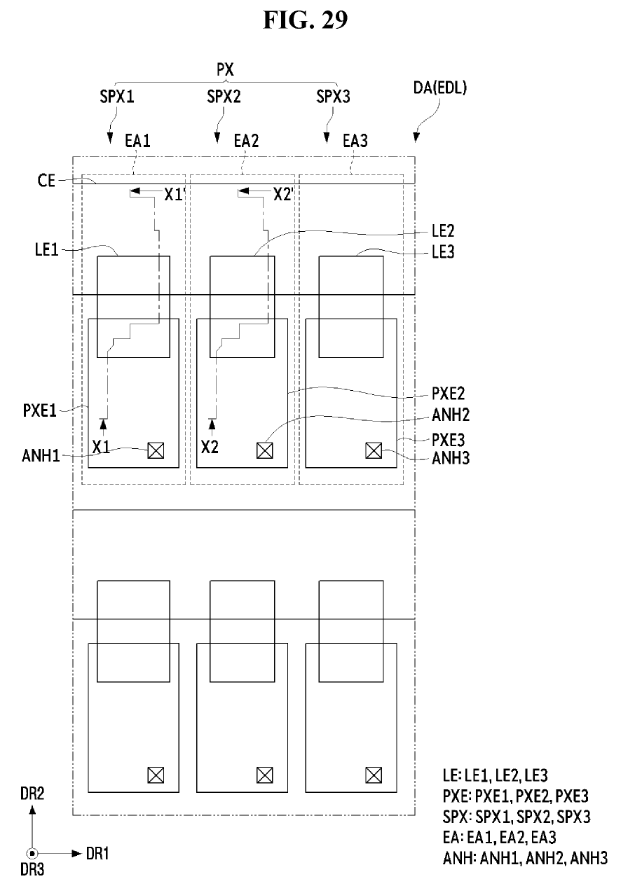

FIG. 29 is a layout view of a light emitting element layer of a display panel according to an embodiment. For example, FIG. 29 shows light emitting elements LE, pixel electrodes PXE, and a common electrode CE included in subpixels SPX of each pixel PX in a portion of a display area DA where two pixels PX that are adjacent to each other in the second direction DR2 are located.

Referring to FIG. 29 in addition to FIGS. 3 through 28, each of the subpixels SPX may include a pixel electrode PXE and a light emitting element LE located in an emission area EA. In an embodiment, when the light emitting element LE is a micro-LED of a flip-chip kind or a lateral kind, each of the subpixels SPX may further include a common electrode CE located on a surface (e.g., a lower surface or an upper surface) of the light emitting element LE together with the pixel electrode PXE. In an embodiment, when the light emitting element LE is a vertical kind of micro-LED, the light emitting element LE of each of the subpixels SPX may be located on the pixel electrode PXE, and the common electrode CE (e.g., a common electrode CE located in the entire display area DA in the form of a common layer) may be located on the light emitting elements LE of the subpixels SPX. FIG. 29 shows a light emitting element layer EDL of a display panel 100 including a flip-chip kind of light emitting elements LE according to an embodiment.

In addition, FIG. 29 shows the emission areas EA of the subpixels SPX having the same or substantially the same size as each other according to an embodiment. However, the present disclosure is not limited thereto. For example, the sizes of the emission areas EA of the subpixels SPX may also be differentiated or optimized according to the emission characteristics or the target luminances of the light emitting elements LE and/or the subpixels SPX.

Additionally, although the pixel electrodes PXE are located within (e.g., only within) their respective emission areas EA in FIG. 29, the present disclosure is not limited thereto. For example, a portion of at least one pixel electrode PXE may be located in a non-emission area around an emission area EA. For example, the size, the shape, and/or the arrangement direction of the pixel electrodes PXE may be variously modified as needed or desired.

In an embodiment, the subpixels SPX of each pixel PX may be arranged in the first direction DR1. In addition, the subpixels SPX of each pixel PX may share one common electrode CE. For example, the common electrode CE may extend in the first direction DR1 in each pixel row (e.g., in each horizontal line) of the display area DA, and the subpixels SPX of the pixels PX located in a corresponding pixel row may share one common electrode CE.

A first subpixel SPX1 may include a first pixel electrode PXE1, a first light emitting element LE1, and a common electrode CE (e.g., a portion of the common electrode CE) located in a first emission area EA1. The first emission area EA1 may refer to an emission area EA of the first subpixel SPX1. The first light emitting element LE1 may refer to a light emitting element LE of the first subpixel SPX1.

A second subpixel SPX2 may include a second pixel electrode PXE2, a second light emitting element LE2, and the common electrode CE located in a second emission area EA2. The second emission area EA2 may refer to an emission area EA of the second subpixel SPX2. The second light emitting element LE2 may refer to a light emitting element LE of the second subpixel SPX2.

The third subpixel SPX3 may include a third pixel electrode PXE3, a third light emitting element LE3, and the common electrode CE located in a third emission area EA3. The third emission area EA3 may refer to an emission area EA of the third subpixel SPX3. The third light emitting element LE3 may refer to a light emitting element LE of the third subpixel SPX3.

In each pixel PX, the first pixel electrode PXE1, the second pixel electrode PXE2, and the third pixel electrode PXE3 may be arranged in the first direction DR1. The first pixel electrode PXE1, the second pixel electrode PXE2, and the third pixel electrode PXE3 may be spaced apart from the common electrode CE in the second direction DR2. In an embodiment, when the subpixels SPX include vertical kind of micro-LEDs, the first pixel electrode PXE1, the second pixel electrode PXE2, and the third pixel electrode PXE3 may be spaced apart from the common electrode CE in the third direction DR3.

The pixel electrodes PXE may be electrically connected to pixel circuits PXC through anode contact holes ANH, respectively. For example, the first pixel electrode PXE1 may be electrically connected to a first pixel circuit PXC1 through a first anode contact hole ANH1. The second pixel electrode PXE2 may be electrically connected to a second pixel circuit PXC2 through a second anode contact hole ANH2. The third pixel electrode PXE3 may be electrically connected to a third pixel circuit PXC3 through a third anode contact hole ANH3.

The light emitting elements LE may be located between the pixel electrodes PXE and the common electrode CE, respectively. For example, the first light emitting element LE1 may be located on the first pixel electrode PXE1 and the common electrode CE. A portion of the first light emitting element LE1 may overlap with the first pixel electrode PXE1, and another portion of the first light emitting element LE1 may overlap with the common electrode CE. The first light emitting element LE1 may be electrically connected between the first pixel electrode PXE1 and the common electrode CE. The second light emitting element LE2 may be located on the second pixel electrode PXE2 and the common electrode CE. A portion of the second light emitting element LE2 may overlap with the second pixel electrode PXE2, and another portion of the second light emitting element LE2 may overlap with the common electrode CE. The second light emitting element LE2 may be electrically connected between the second pixel electrode PXE2 and the common electrode CE. The third light emitting element LE3 may be located on the third pixel electrode PXE3 and the common electrode CE. A portion of the third light emitting element LE3 may overlap with the third pixel electrode PXE3, and another portion of the third light emitting element LE3 may overlap with the common electrode CE. The third light emitting element LE3 may be electrically connected between the third pixel electrode PXE3 and the common electrode CE.

Each of the light emitting elements LE may emit light of a desired color (e.g., a red light, a green light, a blue light, or a white light). In an embodiment, the first light emitting element LE1, the second light emitting element LE2, and the third light emitting element LE3 may emit light of different colors from each other. For example, the first light emitting element LE1, the second light emitting element LE2, and the third light emitting element LE3 may emit light of a first color (e.g., a red light), light of a second color (e.g., a green light), and light of a third color (e.g., a blue light), respectively.

In an embodiment, the light emitting elements LE of at least two subpixels SPX may have different sizes from each other. For example, a size of the first light emitting element LE1 may be larger than a size of each of the second light emitting element LE2 and the third light emitting element LE3. The sizes of the second light emitting element LE2 and the third light emitting element LE3 may be the same or substantially the same as each other, or may be different from each other.

In an embodiment, the light emitting elements LE may have differentiated or optimized sizes according to the luminous efficiency of the light emitting elements LE. For example, at least two of the first light emitting element LE1, the second light emitting element LE2, and/or the third light emitting element LE3 may have different sizes from each other according to the luminous efficiency of each of the first light emitting element LE1, the second light emitting element LE2, and the third light emitting element LE3. For example, when the luminous efficiency of the first light emitting element LE1 is lower than the luminous efficiency of each of the second light emitting element LE2 and the third light emitting element LE3 based on the same size and shape, the size of the first light emitting element LE1 may be larger than the size of each of the second light emitting element LE2 and the third light emitting element LE3. Accordingly, the luminous efficiency of the first light emitting element LE1 may be improved, and a difference in a luminous efficiency between the first light emitting element LE1, the second light emitting element LE2, and the third light emitting element LE3 may be reduced or prevented.

In an embodiment, the first light emitting element LE1, the second light emitting element LE2, and the third light emitting element LE3 may emit light of the same color as each other. In this case, at least one of a light conversion layer (e.g., a light conversion layer including wavelength conversion particles, such as quantum dots) and/or a color filter may be located on the light emitting element LE of at least one of the first subpixel SPX1, the second subpixel SPX2, and/or the third subpixel SPX3 to convert light emitted from the light emitting element LE of the corresponding subpixel SPX into light corresponding to an emission color of the corresponding subpixel SPX. When the first light emitting element LE1, the second light emitting element LE2, and the third light emitting element LE3 emit light of the same color as each other, the sizes of the first light emitting element LE1, the second light emitting element LE2, and the third light emitting element LE3 may be the same or substantially the same as each other, or may be different from each other. For example, the sizes of the light emitting elements LE of the subpixels SPX and/or the areas of the emission areas EA of the subpixels SPX may be differentiated according to the light conversion efficiency by the light conversion layer and/or the like.

Although FIG. 29 illustrates an embodiment in which each of the first subpixel SPX1, the second subpixel SPX2, and the third subpixel SPX3 includes a single light emitting element LE, the present disclosure is not limited thereto. For example, at least one of the first subpixel SPX1, the second subpixel SPX2, and/or the third subpixel SPX3 may include a plurality of light emitting elements LE.

The common electrode CE may be electrically connected to a common power line VSL to which a second driving voltage VSS is applied. For example, the common electrode CE may extend to a non-display area NDA around the display area DA, and may be electrically connected to the common power line VSL (or a power bus line to which the second driving voltage VSS is applied) in the non-display area NDA. However, a connection structure between the common electrode CE and the second power line VSL may be variously modified as needed or desired. For example, in an embodiment, a common power line VSL extending in the first direction DR1 and/or the second direction DR2 may be located inside the display area DA, and the common electrode CE and the second power line VSL may be electrically connected to each other through at least one contact hole and/or connection pattern within the display area DA.

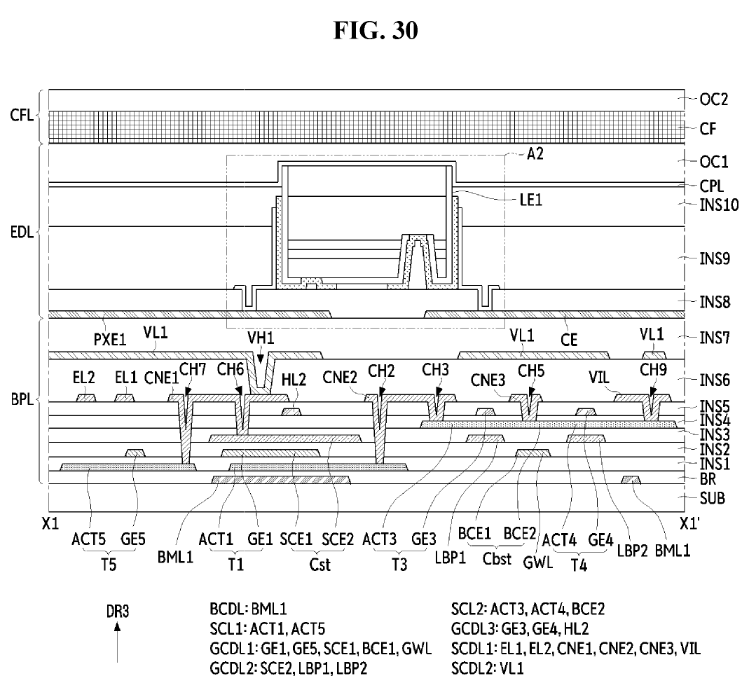

FIG. 30 is a cross-sectional view illustrating an example of a cross-section of a display panel corresponding to the line X1-X1’ of FIGS. 27 and 29. For example, FIG. 30 shows a cross-section of a display panel 100 corresponding to a portion of a first subpixel SPX1 according to an embodiment.

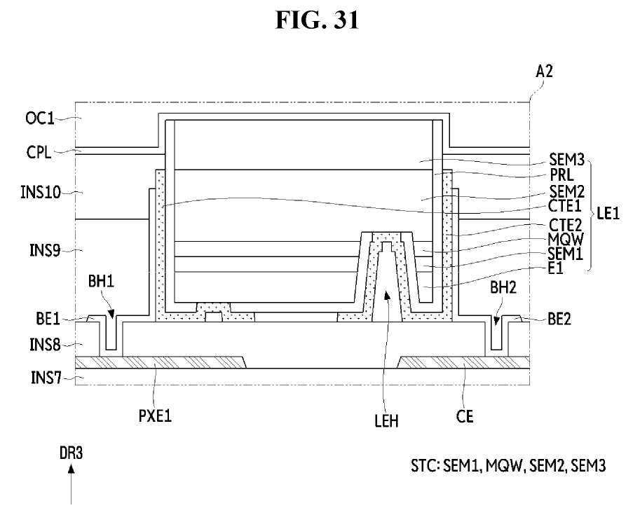

FIG. 31 is a more detailed cross-sectional view corresponding to the area A2 of FIG. 30. For example, FIG. 30 shows, in more detail, an example of a first light emitting element LE1 included in the first subpixel SPX1. In an embodiment, the first light emitting element LE1, a second light emitting element LE2, and a third light emitting element LE3 of the first subpixel SPX1, a second subpixel SPX2, and a third subpixel SPX3 may have the same or substantially the same (or similar) cross-sectional structures as each other.

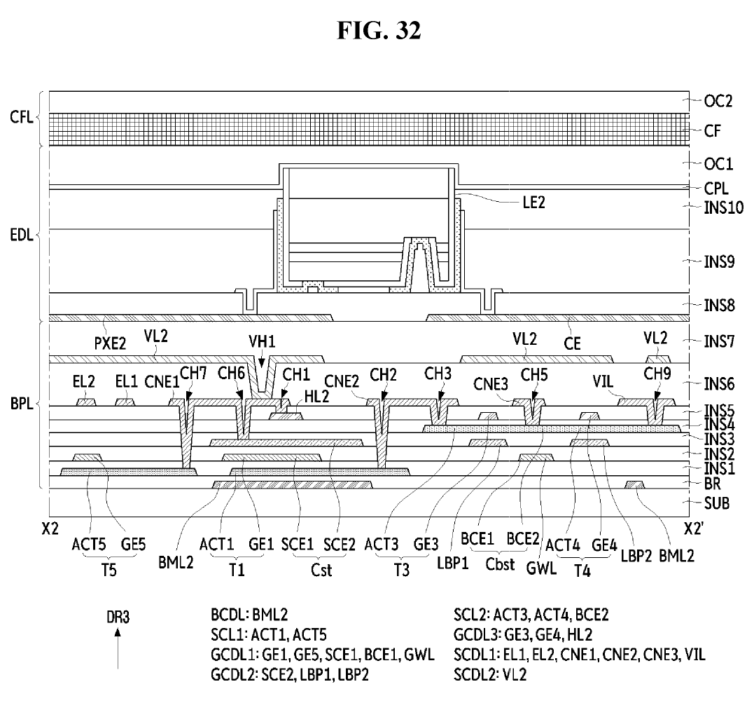

FIG. 32 is a cross-sectional view illustrating an example of a cross-section of a display panel corresponding to the line X2-X2’ of FIGS. 28 and 29. For example, FIG. 32 shows an embodiment of a cross-section of the display panel 100 corresponding to a portion of the second subpixel SPX2. In an embodiment, the second subpixel SPX2 and the third subpixel SPX3 may have the same or substantially the same (or similar) cross-sectional structures as each other.

Referring to FIGS. 30 through 32 in addition to FIGS. 1 through 29, the display panel 100 may include a substrate SUB, and a backplane layer BPL and a light emitting element layer EDL located on the substrate SUB. In an embodiment, the display panel 100 may further include a color filter layer CFL located on the light emitting element layer EDL. The backplane layer BPL, the light emitting element layer EDL, and the color filter layer CFL may be sequentially located on the substrate SUB along the third direction DR3.

The substrate SUB may include an insulating material, such as glass or a polymer resin. When the substrate SUB includes a polymer resin, it may be a flexible substrate that may be stretched. The polymer resin may be an acryl resin, an epoxy resin, a phenolic resin, a polyamide resin, or a polyimide resin.

The substrate SUB may include a display area DA and a non-display area NDA. The display area DA may include pixel areas PXA in which pixels PX are located. Each pixel area PXA may include emission areas EA of subpixels SPX.

The backplane layer BPL may include circuit elements included in pixel circuits PXC of the subpixels SPX, and wirings connected to the subpixels SPX. In an embodiment, the backplane layer BPL may be entirely formed on a surface of the substrate SUB.

The backplane layer BPL may include at least one semiconductor layer, conductive layers, and insulating layers. In an embodiment, when the pixel circuits PXC include at least two kinds of pixel transistors PXT including different materials from each other, the backplane layer BPL may include a plurality of semiconductor layers.

For example, the backplane layer BPL may include a bottom conductive layer BCDL, a barrier layer BR (or a buffer layer), a first semiconductor layer SCL1 (e.g., a polycrystalline silicon semiconductor layer), a first insulating layer INS1 (e.g., a first inorganic insulating layer), a first gate conductive layer GCDL1 (e.g., a first conductive layer), a second insulating layer INS2 (e.g., a second inorganic insulating layer), a second gate conductive layer GCDL2 (e.g., a second conductive layer), a third insulating layer INS3 (e.g., a third inorganic insulating layer), a second semiconductor layer SCL2 (e.g., an oxide semiconductor layer), a fourth insulating layer INS4 (e.g., a fourth inorganic insulating layer), a third gate conductive layer GCDL3 (e.g., a third conductive layer), a fifth insulating layer INS5 (e.g., a fifth inorganic insulating layer), a first source-drain conductive layer SCDL1 (e.g., a fourth conductive layer), a sixth insulating layer INS6 (e.g., a first organic insulating layer), a second source-drain conductive layer SCDL2 (e.g., a fifth conductive layer), and a seventh insulating layer INS7 (e.g., a second organic insulating layer), which are sequentially located on the substrate SUB along the third direction DR3.

The bottom conductive layer BCDL may include a bottom conductive pattern BML located under a first transistor T1. For example, the bottom conductive layer BCDL may include a first bottom conductive pattern BML1 located under the first transistor T1 included in a first pixel circuit PXC1, and a second bottom conductive pattern BML2 located under the first transistor T1 included in each of a second pixel circuit PXC2 and a third pixel circuit PXC3.

The bottom conductive pattern BML may entirely or partially cover a lower surface of a first active layer ACT1. For example, the bottom conductive pattern BML may be located under the first active layer ACT1 to overlap with a channel region of the first active layer ACT1 (e.g., a portion of the first active layer ACT1 overlapping with a first gate electrode GE1). In an embodiment, the bottom conductive layer BCDL may include a light blocking material. For example, the bottom conductive layer BCDL may include a metal, and the bottom conductive pattern BML may be formed as a bottom metal pattern.

The barrier layer BR may be located on the bottom conductive layer BCDL. The barrier layer BR may protect circuit elements of the backplane layer BPL and light emitting elements LE on the backplane layer BPL from moisture introduced through the substrate SUB, which is vulnerable to moisture penetration. In an embodiment, the barrier layer BR may include a plurality of inorganic insulating layers.

The circuit elements of the backplane layer BPL may be located on the barrier layer BR. For example, pixel transistors PXT, a storage capacitor Cst, and a boosting capacitor Cbst of each of the pixel circuits PXC included in a corresponding pixel PX may be located on the barrier layer BR in each pixel area PXA. In addition, wirings of the backplane layer BPL may be located on the barrier layer BR. For example, signal lines and power lines PL electrically connected to the subpixels SPX may be located on the barrier layer BR.

In an embodiment, each of the pixel circuits PXC may include first type transistors and second type transistors. The first type transistors and the second type transistors may be located in different layers from each other within the backplane layer BPL.

For example, each of the pixel circuits PXC may include first, second, fifth, sixth, seventh, and eighth transistors T1, T2, T5, T6, T7, and T8, which are P-type transistors, and third and fourth transistors T3 and T4, which are N-type transistors. First, second, fifth, sixth, seventh, and eighth active layers ACT1, ACT2, ACT5, ACT6, ACT7, and ACT8 included in the first, second, fifth, sixth, seventh, and eighth transistors T1, T2, T5, T6, T7, and T8, and third and fourth active layers ACT3 and ACT4 included in the third and fourth transistors T3 and T4 may be located in different semiconductor layers from each other included in the backplane layer BPL. In an embodiment, the first, second, fifth, sixth, seventh, and eighth active layers ACT1, ACT2, ACT5, ACT6, ACT7, and ACT8, and the third and fourth active layers ACT3 and ACT4 may include different semiconductor materials from each other, but the present disclosure is not limited thereto. In addition, first, second, fifth, sixth, seventh, and eighth gate electrodes GE1, GE2, GE5, GE6, GE7, and GE8 included in the first, second, fifth, sixth, seventh, and eighth transistors T1, T2, T5, T6, T7, and T8, and the third and fourth gate electrodes GE3 and GE4 included in the third and fourth transistors T3 and T4 may be located in different conductive layers from each other included in the backplane layer BPL.

The first semiconductor layer SCL1 may be located on the barrier layer BR. The first semiconductor layer SCL1 may include an active layer of each of the first type transistors. For example, the first semiconductor layer SCL1 may include the first, second, fifth, sixth, seventh, and eighth active layers ACT1, ACT2, ACT5, ACT6, ACT7, and ACT8. FIGS. 30 and 32 show only some of the pixel transistors PXT included in each pixel circuit PXC. In FIGS. 30 and 32, the first active layer ACT1 and the fifth active layer ACT5 among the active layers included in the first semiconductor layer SCL1 are illustrated. In an embodiment, the first, second, fifth, sixth, seventh, and eighth active layers ACT1, ACT2, ACT5, ACT6, ACT7, and ACT8 of each pixel circuit PXC may be integrally formed with each other using the same semiconductor material. For example, as illustrated in FIGS. 26 through 28, the first, second, fifth, sixth, seventh, and eighth active layers ACT1, ACT2, ACT5, ACT6, ACT7, and ACT8 of each of the first pixel circuit PXC1, the second pixel circuit PXC2, and the third pixel circuit PXC3 may be connected to each other to form one semiconductor pattern.

The patterns of the first semiconductor layer SCL1 (e.g., the first, second, fifth, sixth, seventh, and eighth active layers ACT1, ACT2, ACT5, ACT6, ACT7, and ACT8) may include a first semiconductor material. In an embodiment, the first semiconductor material may be, but is not limited to, polycrystalline silicon (e.g., a low-temperature polycrystalline silicon). For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or other suitable oxide semiconductors) or monocrystalline silicon.

The first insulating layer INS1 may be located on the first semiconductor layer SCL1. The first insulating layer INS1 may include at least one insulating material (e.g., silicon nitride (SiNₓ), silicon oxide (SiOₓ), silicon oxynitride (SiON), titanium oxide (TiOₓ), aluminum oxide (AlOₓ), or other suitable inorganic insulating materials), and may be formed as a single layer or multilayers.

The first gate conductive layer GCDL1 may be located on the first insulating layer INS1. The first gate conductive layer GCDL1 may include a gate electrode of each of the first type transistors. For example, the first gate conductive layer GCDL1 may include the first, second, fifth, sixth, seventh, and eighth gate electrodes GE1, GE2, GE5, GE6, GE7, and GE8. The first gate conductive layer GCDL1 may further include at least one conductive pattern and/or wiring. For example, the first gate conductive layer GCDL1 may further include a first capacitor electrode SCE1 of the storage capacitor Cst, a first electrode BCE1 of the boosting capacitor Cbst, a write scan line GWL, and a bias scan line GBL. In FIGS. 30 and 32, the first gate electrode GE1, the fifth gate electrode GE5, the first capacitor electrode SCE1 of the storage capacitor Cst, the first electrode BCE1 of the boosting capacitor Cbst, and the write scan line GWL among the patterns of the first gate conductive layer GCDL1 are illustrated.

In an embodiment, the first gate electrode GE1 of each pixel circuit PXC and the first capacitor electrode SCE1 of the storage capacitor Cst may be integrally formed with each other, and the second gate electrode GE2, the first electrode BCE1 of the boosting capacitor Cbst, and the write scan line GWL (e.g., the write scan line GWL connected to the subpixels SPX of each pixel row) may be integrally formed with each other. In addition, the seventh gate electrode GE7, the eighth gate electrode GE8, and the bias scan line GBL (e.g., the bias scan line GBL connected to the subpixels SPX of a corresponding horizontal line) may be integrally formed with each other.

The patterns of the first gate conductive layer GCDL1 (e.g., the first, second, fifth, sixth, seventh, and eighth gate electrodes GE1, GE2, GE5, GE6, GE7, and GE8, the first capacitor electrode SCE1 of the storage capacitor Cst, the first electrode BCE1 of the boosting capacitor Cbst, the write scan line GWL, and the bias scan line GBL) may include the same conductive material as each other.

The second insulating layer INS2 may be located on the first gate conductive layer GCDL1. The second insulating layer INS2 may include at least one insulating material (e.g., an inorganic insulating material), and may be formed as a single layer or multilayers.

The second gate conductive layer GCDL2 may be located on the second insulating layer INS2. The second gate conductive layer GCDL2 may include a second capacitor electrode SCE2 of the storage capacitor Cst. The first capacitor electrode SCE1 and the second capacitor electrode SCE2 of the storage capacitor Cst may overlap with each other with the second insulating layer INS2 therebetween. The second insulating layer INS2 may be located between the first capacitor electrode SCE1 and the second capacitor electrode SCE2. The second capacitor electrode SCE2 of the storage capacitor Cst may be opened at a portion (e.g., a fourth contact hole CH4 and its surroundings) where the first capacitor electrode SCE1 of the storage capacitor Cst is connected to a third connection pattern CNE3. The second gate conductive layer GCDL2 may further include at least one conductive pattern and/or wiring. For example, the second gate conductive layer GCDL2 may further include a first light blocking pattern LBP1, a second light blocking pattern LBP2, and a second initialization power line VAIL. In FIGS. 30 and 32, the second capacitor electrode SCE2 of the storage capacitor Cst, the first light blocking pattern LBP1, and the second light blocking pattern LBP2 among the patterns of the second gate conductive layer GCDL2 are illustrated.

In an embodiment, the first light blocking patterns LBP1 of the subpixels SPX located in each pixel row (e.g., the subpixels SPX arranged in the first direction DR1 in each horizontal line of the display area DA) may be integrally formed with each other, and the second light blocking patterns LBP2 of the subpixels SPX located in each pixel row may be integrally formed with each other.

The patterns of the second gate conductive layer GCDL2 (e.g., the second capacitor electrode SCE2 of the storage capacitor Cst, the first light blocking pattern LBP1, the second light blocking pattern LBP2, and the second initialization power line VAIL) may include the same conductive material as each other.

The third insulating layer INS3 may be located on the second gate conductive layer GCDL2. The third insulating layer INS3 may include at least one insulating material (e.g., an inorganic insulating material), and may be formed as a single layer or multilayers.

The second semiconductor layer SCL2 may be located on the third insulating layer INS3. The second semiconductor layer SCL2 may include an active layer of each of the second type transistors. For example, the second semiconductor layer SCL2 may include the third and fourth active layers ACT3 and ACT4. In an embodiment, the third and fourth active layers ACT3 and ACT4 of each pixel circuit PXC may be integrally formed with each other using the same semiconductor material. For example, as illustrated in FIGS. 26 through 28, the third and fourth active layers ACT3 and ACT4 of each of the first pixel circuit PXC1, the second pixel circuit PXC2, and the third pixel circuit PXC3 may be connected to each other to form one semiconductor pattern. In an embodiment, the second semiconductor layer SCL2 may further include a second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 (e.g., the third and fourth active layers ACT3 and ACT4 and the second electrode BCE2 of the boosting capacitor Cbst) may include a second semiconductor material. In an embodiment, the second semiconductor material may be an oxide semiconductor, but the present disclosure is not limited thereto. For example, the second semiconductor material may also be polycrystalline silicon or monocrystalline silicon.

The fourth insulating layer INS4 may be located on the second semiconductor layer SCL2. The fourth insulating layer INS4 may include at least one insulating material (e.g., an inorganic insulating material), and may be formed as a single layer or multilayers.

The third gate conductive layer GCDL3 may be located on the fourth insulating layer INS4. The third gate conductive layer GCDL3 may include a gate electrode of each of the second type transistors. For example, the third gate conductive layer GCDL3 may include the third and fourth gate electrodes GE3 and GE4. The third gate conductive layer GCDL3 may further include at least one conductive pattern and/or wiring. For example, the third gate conductive layer GCDL3 may further include an initialization scan line GIL, a control scan line GCL, a first horizontal power line HL1, a second horizontal power line HL2, and a bias power line VOBL. In FIGS. 30 and 32, the third gate electrode GE3, the fourth gate electrode GE4, and the second horizontal power line HL2 among the patterns of the third gate conductive layer GCDL3 are illustrated.

In an embodiment, the third gate electrode GE3 and the control scan line GCL (e.g., the control scan line GCL connected to the subpixels SPX of each pixel row) may be integrally formed with each other. In addition, the fourth gate electrode GE4 and the initialization scan line GIL (e.g., the initialization scan line GIL connected to the subpixels SPX of each pixel row) may be integrally formed with each other.

The patterns of the third gate conductive layer GCDL3 (e.g., the third and fourth gate electrodes GE3 and GE4, the initialization scan line GIL, the control scan line GCL, the first horizontal power line HL1, the second horizontal power line HL2, and the bias power line VOBL) may include the same conductive material as each other.

The fifth insulating layer INS5 may be located on the third gate conductive layer GCDL3. The fifth insulating layer INS5 may include at least one insulating material (e.g., an inorganic insulating material), and may be formed as a single layer or multilayers.

The first source-drain conductive layer SCDL1 may be located on the fifth insulating layer INS5. The first source-drain conductive layer SCDL1 may include at least one electrode, conductive pattern, and/or wiring. For example, the first source-drain conductive layer SCDL1 may include first, second, third, fourth, fifth, seventh, and eighth connection patterns CNE1, CNE2, CNE3, CNE4, CNE5, CNE7, and CNE8, first and second emission control lines EL1 and EL2, and a first initialization power line VIL. In FIGS. 30 and 32, the first, second, and third connection patterns CNE1, CNE2, and CNE3, the first and second emission control lines EL1 and EL2, and the first initialization power line VIL among the patterns of the first source-drain conductive layer SCDL1 are illustrated.

The patterns of the first source-drain conductive layer SCDL1 (e.g., the first, second, third, fourth, fifth, seventh, and eighth connection patterns CNE1, CNE2, CNE3, CNE4, CNE5, CNE7, and CNE8, the first and second emission control lines EL1 and EL2, and the first initialization power line VIL) may include the same conductive material as each other.

The sixth insulating layer INS6 may be located on the first source-drain conductive layer SCDL1. The sixth insulating layer INS6 may include at least one insulating material (e.g., an acryl resin, an epoxy resin, a phenolic resin, a polyamide resin, a polyimide resin, or other suitable organic insulating materials), and may be formed as a single layer or multilayers.

The second source-drain conductive layer SCDL2 may be located on the sixth insulating layer INS6. The second source-drain conductive layer SCDL2 may include at least one electrode, conductive pattern, and/or wiring. For example, the second source-drain conductive layer SCDL2 may include a sixth connection pattern CNE6, first, second, and third data lines DLr, DLg, and DLb, and first and second vertical power lines VL1 and VL2. In FIGS. 30 and 32, the first and second vertical power lines VL1 and VL2 among the patterns of the second source-drain conductive layer SCDL2 are illustrated.

The patterns of the second source-drain conductive layer SCDL2 (e.g., the sixth connection pattern CNE6, the first, second, and third data lines DLr, DLg, and DLb, and the first and second vertical power lines VL1 and VL2) may include the same conductive material as each other.

The seventh insulating layer INS7 may be located on the second source-drain conductive layer SCDL2. The seventh insulating layer INS7 may include at least one insulating material (e.g., an organic insulating material), and may be formed as a single layer or multilayers.

The patterns included in each of the conductive layers of the backplane layer BPL may include at least one conductive material. For example, the electrodes, conductive patterns, and/or wirings included in each of the first gate conductive layer GCDL1, the second gate conductive layer GCDL2, the third gate conductive layer GCDL3, the first source-drain conductive layer SCDL1, and the second source-drain conductive layer SCDL2 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), other suitable metals, an alloy thereof, or other suitable conductive materials. In an embodiment, the electrodes, conductive patterns, and/or wirings located in the same conductive layer as each other may be concurrently (e.g., simultaneously or substantially simultaneously) formed with each other using the same conductive material. At least two of the conductive layers of the backplane layer BPL may include the same conductive material as each other, or may include different conductive materials from each other.

In an embodiment, the patterns included in each of the conductive layers of the backplane layer BPL may have a single-layer or multilayered structure. For example, each of the electrodes, conductive patterns, and/or wirings included in each of the bottom conductive layer BCDL, the first gate conductive layer GCDL1, the second gate conductive layer GCDL2, the third gate conductive layer GCDL3, the first source-drain conductive layer SCDL1, and the second source-drain conductive layer SCDL2 may have a single-layer or multilayered structure. At least two of the conductive layers of the backplane layer BPL may have the same cross-sectional structure as each other, or may have different cross-sectional structures from each other.

In an embodiment, the patterns of the second source-drain conductive layer SCDL2 may include a metal (e.g., at least one of molybdenum (Mo), aluminum (Al), chromium (Cr), gold (Au), titanium (Ti), nickel (Ni), neodymium (Nd), copper (Cu), other suitable metals, or an alloy thereof), and may have a single-layer or multilayered structure. For example, the electrodes, conductive patterns, and/or wirings included in the second source-drain conductive layer SCDL2 may be low-resistance patterns formed in a three-layered structure of titanium/aluminum/titanium (Ti/Al/Ti). As another example, the patterns of the second source-drain conductive layer SCDL2 may include other low-resistance materials and/or structures. When the resistance of the patterns included in the second source-drain conductive layer SCDL2 is reduced or minimized, the resistance of driving power lines VDL (e.g., the first and second vertical power lines VL1 and VL2 included in first and second driving power lines VDL1 and VDL2), through which respective driving currents Ids of the subpixels SPX flow, may be reduced or minimized. Accordingly, the image quality of the display device 1 may be uniformized, and a power consumption may be improved.

The light emitting element layer EDL may be located on the seventh insulating layer INS7. The light emitting element layer EDL may include pixel electrodes PXE, light emitting elements LE, and a common electrode CE included in the subpixels SPX. In addition, the light emitting element layer EDL may further include insulating layers. In an embodiment, the insulating layers of the light emitting element layer EDL may include eighth, ninth, and tenth insulating layers INS8, INS9, and INS10, a capping layer CPL, and a first overcoat layer OC1.

A pixel electrode layer including the pixel electrodes PXE of the subpixels SPX may be located on the seventh insulating layer INS7. For example, the pixel electrode layer may include a first pixel electrode PXE1, a second pixel electrode PXE2, and a third pixel electrode PXE3. In an embodiment, each of the light emitting elements LE may be a flip-chip kind of micro-LED. The flip-chip kind of micro-LED refers to an LED in which first and second contact electrodes CTE1 and CTE2 are formed on a surface (e.g., a lower surface) of a light emitting element LE. When the light emitting elements LE are flip-chip kind of micro-LEDs, the pixel electrode layer may further include the common electrode CE. For example, the pixel electrodes PXE and the common electrode CE of the subpixels SPX may be located in the same layer as each other, and may be formed concurrently (e.g., simultaneously or substantially simultaneously) with each other using the same conductive material.

The first pixel electrode PXE1 of the first subpixel SPX1 may be electrically connected to the sixth connection pattern CNE6 of the first subpixel SPX1 through a first anode contact hole ANH1 (e.g., a contact hole which penetrates the seventh insulating layer INS7 to expose the sixth connection pattern CNE6 of the first subpixel SPX1) illustrated in FIGS. 26, 27, and 29. The second pixel electrode PXE2 of the second subpixel SPX2 may be electrically connected to the sixth connection pattern CNE6 of the second subpixel SPX2 through a second anode contact hole ANH2 (e.g., a contact hole which penetrates the seventh insulating layer INS7 to expose the sixth connection pattern CNE6 of the second subpixel SPX2) illustrated in FIGS. 26,28,and 29. The third pixel electrode PXE3 of the third subpixel SPX3 may be electrically connected to the sixth connection pattern CNE6 of the third subpixel SPX3 through a third anode contact hole ANH3 (e.g., a contact hole which penetrates the seventh insulating layer INS7 to expose the sixth connection pattern CNE6 of the third subpixel SPX3) illustrated in FIGS. 26 and 29. Accordingly, the first pixel electrode PXE1, the second pixel electrode PXE2, and the third pixel electrode PXE3 may be electrically connected to the first pixel circuit PXC1, the second pixel circuit PXC2, and the third pixel circuit PXC3, respectively. In addition, the first pixel circuit PXC1, the second pixel circuit PXC2, and the third pixel circuit PXC3 may control voltages applied to the first pixel electrode PXE1, the second pixel electrode PXE2, and the third pixel electrode PXE3.

The common electrode CE shared by the first, second, and third subpixels SPX1, SPX2, and SPX3 may be electrically connected to a common power line VSL within the display area DA and/or the non-display area NDA. Accordingly, a second driving voltage VSS applied to the common power line VSL may be transmitted to the common electrode CE.

In an embodiment, the patterns of the pixel electrode layer (e.g., the pixel electrodes PXE and the common electrode CE) may include the same conductive material as each other. In an embodiment, the patterns of the pixel electrode layer may include a metal (e.g., at least one of molybdenum (Mo), aluminum (Al), chromium (Cr), gold (Au), titanium (Ti), nickel (Ni), neodymium (Nd), copper (Cu), other suitable metals, or an alloy thereof) and may have a single-layer or multilayered structure. For example, the patterns of the pixel electrode layer may be low-resistance patterns formed in a three-layered structure of titanium/aluminum/titanium (Ti/Al/Ti). As another example, the patterns of the pixel electrode layer may include other low-resistance materials (e.g., copper (Cu)) and/or structures. When the resistance of the patterns included in the pixel electrode layer is reduced or minimized, a first driving voltage VDD (e.g., a first driving voltage VDD1 of a first level and a first driving voltage VDD2 of a second level) and the second driving voltage VSS may be stably transmitted to the light emitting elements LE of the subpixels SPX.

The eighth insulating layer INS8 may be located on the pixel electrodes PXE and the common electrode CE. The eighth insulating layer INS8 temporarily fixes or attaches the light emitting elements LE to prevent the light emitting elements LE from tilting or falling during a process of transferring the light emitting elements LE to the display panel 100. For example, the eighth insulating layer INS8 may be a layer for temporarily attaching the light emitting elements LE onto the pixel electrodes PXE and the common electrode CE. To facilitate the temporary attachment, a thickness of the eighth insulating layer INS8 may be greater than a thickness of each of the pixel electrodes PXE and the common electrode CE, and may be greater than a thickness of each of the first and second contact electrodes CTE1 and CTE2 of the light emitting elements LE.

Although the eighth insulating layer INS8 is located over the entire display area DA in FIGS. 30 through 32, the present disclosure is not limited thereto. For example, the eighth insulating layer INS8 may be located only on portions of the pixel electrodes PXE and the common electrode CE, which overlap with the light emitting elements LE, and may expose other portions of the pixel electrodes PXE and the common electrode CE.

The eighth insulating layer INS8 may include at least one insulating material, for example, such as an organic insulating material. For example, the eighth insulating layer INS8 may be a photosensitive organic layer, such as a photoresist. As another example, the eighth insulating layer INS8 may include an acryl resin, an epoxy resin, a phenolic resin, a polyamide resin, or a polyimide resin.

The light emitting elements LE may be located on the eighth insulating layer INS8. For example, the first light emitting element LE1 may be located on the first pixel electrode PXE1 and the common electrode CE of the first subpixel SPX1. The second light emitting element LE2 may be located on the second pixel electrode PXE2 and the common electrode CE of the second subpixel SPX2. The third light emitting element LE3 may be located on the third pixel electrode PXE3 and the common electrode CE of the third subpixel SPX3.

In an embodiment, each of the light emitting elements LE may be a micro-LED including an inorganic material. For example, each of the light emitting elements LE may include an inorganic material, such as gallium nitride (GaN). Each of the light emitting elements LE may have a length of several to hundreds of µm in each of the first direction DR1, the second direction DR2, and the third direction DR3. For example, each of the light emitting elements LE may have a length of about 100 µm or less in each of the first direction DR1, the second direction DR2, and the third direction DR3.

The light emitting elements LE may be grown on a semiconductor substrate, such as a silicon substrate or a sapphire substrate. The light emitting elements LE may be directly transferred from the semiconductor substrate onto the pixel electrodes PXE and the common electrode CE of the display panel 100. As another example, the light emitting elements LE may be transferred onto the pixel electrodes PXE and the common electrode CE of the display panel 100 through an electrostatic method using an electrostatic head, or a stamp method using an elastic polymer material, such as PDMS or silicon, as a transfer substrate.

Each of the light emitting elements LE may include a conductive layer E1, a semiconductor stack STC, contact electrodes CTE1 and CTE2, and a protective layer PRL. The semiconductor stack STC may include a first semiconductor layer SEM1, an active layer MQW (e.g., a light emitting layer), and a second semiconductor layer SEM2 sequentially located in the third direction DR3. In an embodiment, the semiconductor stack STC may further include a third semiconductor layer SEM3 on the second semiconductor layer SEM2.

The conductive layer E1 may be located on a lower surface of the first semiconductor layer SEM1. Although the conductive layer E1 covers the entire lower surface of the first semiconductor layer SEM1 in FIG. 31, the present disclosure is not limited thereto. For example, the conductive layer E1 may also be located on a portion of the lower surface of the first semiconductor layer SEM1. The conductive layer E1 may include any one of molybdenum (Mo), aluminum (Al), chromium (Cr), gold (Au), titanium (Ti), nickel (Ni), neodymium (Nd), and/or copper (Cu), or may include a transparent conductive material, such as a metal oxide.

The first semiconductor layer SEM1 may be located on the conductive layer E1. The first semiconductor layer SEM1 may include a semiconductor material layer, for example, such as gallium nitride (GaN), doped with a first conductivity kind of dopant, such as magnesium (Mg), zinc (Zn), calcium (Ca), strontium (Sr), or barium (Ba).

The active layer MQW may be located on the first semiconductor layer SEM1. The active layer MQW may include the same semiconductor material as those of the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least any one of gallium nitride (GaN), indium gallium nitride (InGaN), and/or aluminum gallium nitride (AlGaN). The active layer MQW may emit light through the recombination of electron-hole pairs in response to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. The well layers may include InGaN, and the barrier layers may include GaN or AlGaN, but the present disclosure is not limited thereto. As another example, the active layer MQW may be a structure in which semiconductor materials having a large band gap energy and semiconductor materials having a small band gap energy are alternately stacked, or may include group 3 to 5 semiconductor materials depending on the wavelength band of light to be emitted by the active layer MQW.

When the active layer MQW includes indium gallium nitride (InGaN), the color of light emitted by the active layer MQW may vary depending on the indium content. For example, as the indium content increases, the wavelength band of light emitted by the active layer MQW may move to a red wavelength band, and as the indium content decreases, the wavelength band of light emitted by the active layer MQW may move to a blue wavelength band. For example, the indium content of the active layer MQW of a light emitting element LE, which emits light of a third color (e.g., a blue light), may be about 10 to 20 wt%.

The second semiconductor layer SEM2 may be located on the active layer MQW. The second semiconductor layer SEM2 may be a semiconductor material layer, for example, such as gallium nitride (GaN), doped with a second conductivity kind of dopant, such as silicon (Si), germanium (Ge), or tin (Sn).

The third semiconductor layer SEM3 may be located on the second semiconductor layer SEM2. The third semiconductor layer SEM3 may be a semiconductor material layer having an n-type dopant, which is lower than a selected threshold value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN) having an n-type dopant, which is lower than a selected threshold value.

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with a p-type Mg. The electron blocking layer may be omitted as needed or desired.

A superlattice layer may be located between the active layer MQW and the second semiconductor layer SEM2. The superlattice layer may be a layer for alleviating a stress between the second semiconductor layer SEM2 and the active layer MQW. For example, the superlattice layer may include InGaN or GaN. The superlattice layer may be omitted as needed or desired.

The protective layer PRL may be located on side surfaces of the first semiconductor layer SEM1, side surfaces of the active layer MQW, and side surfaces of the second semiconductor layer SEM2. The protective layer PRL may be a layer for protecting side surfaces of each light emitting element LE. The protective layer PRL may include an inorganic material, for example, such as silicon nitride (SiNₓ), silicon oxide (SiOₓ), silicon oxynitride (SiON), titanium oxide (TiOₓ), aluminum oxide (AlOₓ), or other suitable inorganic insulating materials.

In FIG. 31, the protective layer PRL is located on the side surfaces of the first semiconductor layer SEM1, the side surfaces of the active layer MQW, and the side surfaces of the second semiconductor layer SEM2 of the semiconductor stack STC, but is not located on side surfaces of the third semiconductor layer SEM3. However, the present disclosure is not limited thereto. For example, the protective layer PRL may be located on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH may be formed to penetrate the conductive layer E1, the first semiconductor layer SEM1, and the active layer MQW of each light emitting element LE, and expose the second semiconductor layer SEM2. The hole LEH may have a circular planar shape, but the present disclosure is not limited thereto. For example, the hole LEH may also have an elliptical planar shape or a polygonal planar shape, such as a quadrangle.

The protective layer PRL may be located on sidewalls of the conductive layer E1, sidewalls of the first semiconductor layer SEM1, and sidewalls of the active layer MQW exposed in the hole LEH. The protective layer PRL may not cover the second semiconductor layer SEM2 in the hole LEH. Accordingly, the second semiconductor layer SEM2 may be exposed without being covered by the protective layer PRL.

The first contact electrode CTE1 may be located on at least one side surface of the semiconductor stack STC and at least one side surface and a lower surface of the conductive layer E1. The first contact electrode CTE1 may be located on the lower surface of the conductive layer E1 exposed without being covered by the protective layer PRL. Therefore, the first contact electrode CTE1 may be electrically connected to the conductive layer E1.

The second contact electrode CTE2 may be located on at least one side surface of the semiconductor stack STC and at least one side surface and the lower surface of the conductive layer E1. The first contact electrode CTE1 may be located on a first side surface of the semiconductor stack STC and a first side surface of the conductive layer E1, but the second contact electrode CTE2 may be located on a second side surface of the semiconductor stack STC and a second side surface of the conductive layer E1.

The second contact electrode CTE2 may be located on the protective layer PRL, which is located in the hole LEH, and the second semiconductor layer SEM2, which is exposed without being covered by the protective layer PRL in the hole LEH. Therefore, the second contact electrode CTE2 may be electrically connected to the second semiconductor layer SEM2 in the hole LEH.

Although the first contact electrode CTE1 and the second contact electrode CTE2 of each of the light emitting elements LE are located on the eighth insulating layer INS8 in FIGS. 30 through 32, the present disclosure is not limited thereto. For example, the eighth insulating layer INS8 may be located on a lower surface and a portion of a side surface of the first contact electrode CTE1 and a lower surface and a portion of a side surface of the second contact electrode CTE2 of each of the light emitting elements LE. As another example, the eighth insulating layer INS8 may be located on the side surfaces of the conductive layer E1 of each of the light emitting elements LE. As another example, the eighth insulating layer INS8 may be located on the side surfaces of the first semiconductor layer SEM1, the side surfaces of the active layer MQW, and the side surfaces of the second semiconductor layer SEM2 of each of the light emitting elements LE. In this case, the eighth insulating layer INS8 may be located on a portion of each of the side surfaces of the second semiconductor layer SEM2.

Each of the first contact electrode CTE1 and the second contact electrode CTE2 may be located on three side surfaces of the semiconductor stack STC. For example, when the semiconductor stack STC includes first through fourth side surfaces, the first contact electrode CTE1 may be located on the first side surface, the second side surface, and the third side surface, and the second contact electrode CTE2 may be located on the second side surface, the third side surface, and the fourth side surface.

Each of the first contact electrode CTE1 and the second contact electrode CTE2 may include at least one conductive material, for example, such as any one of molybdenum (Mo), aluminum (Al), chromium (Cr), gold (Au), titanium (Ti), nickel (Ni), neodymium (Nd), and/or copper (Cu). In an embodiment, to increase a reflectivity, the first contact electrode CTE1 and the second contact electrode CTE2 may have a two-layered structure of chromium (Cr) and gold (Au), a three-layered structure of titanium (Ti), aluminum (Al), and titanium (Ti), or a three-layered structure of indium tin oxide (ITO), silver (Ag), and indium tin oxide (ITO).

When each of the first contact electrode CTE1 and the second contact electrode CTE2 includes a metal with a high reflectivity, light travelling toward the side of a light emitting element LE among the light emitted from the active layer MQW of the light emitting element LE may be reflected by the first contact electrode CTE1 and the second contact electrode CTE2 to an upper surface of the light emitting element LE. Accordingly, a loss of light of the light emitting element LE may be reduced, which in turn, increases the light efficiency of the light emitting element LE. Therefore, in order to increase the light efficiency of the light emitting element LE, the first contact electrode CTE1 and the second contact electrode CTE2 may cover most of the side surfaces of the semiconductor stack STC.

A first bridge electrode BE1 (e.g., a first connection electrode) connects the first contact electrode CTE1 of a light emitting element LE and each pixel electrode PXE to each other. For example, the first bridge electrode BE1 of the first subpixel SPX1 may connect the first contact electrode CTE1 of the first light emitting element LE1 and the first pixel electrode PXE1 to each other. Similarly, the first bridge electrode BE1 of the second subpixel SPX2 may connect the first contact electrode CTE1 of the second light emitting element LE2 and the second pixel electrode PXE2 with each other, and the first bridge electrode BE1 of the third subpixel SPX3 may connect the first contact electrode CTE1 of the third light emitting element LE3 and the third pixel electrode PXE3 with each other.

The first bridge electrode BE1 may be connected to each pixel electrode PXE, which is exposed through a first connection hole BH1 penetrating the eighth insulating layer INS8. In addition, the first bridge electrode BE1 may be located on an upper surface of the eighth insulating layer INS8 and the first contact electrode CTE1 of each light emitting element LE. In an embodiment, if (e.g., when) the eighth insulating layer INS8 is located only on a portion of a pixel electrode PXE overlapping with a light emitting element LE, the first connection hole BH1 may be unnecessary. For example, the first bridge electrode BE1 may be located directly on the pixel electrode PXE, which is exposed around the light emitting element LE.

A second bridge electrode BE2 (e.g., a second connection electrode) connects the second contact electrode CTE2 of each light emitting element LE and the common electrode CE with each other. For example, the second bridge electrode BE2 of the first subpixel SPX1 may connect the second contact electrode CTE2 of the first light emitting element LE1 and the common electrode CE with each other. Similarly, the second bridge electrode BE2 of the second subpixel SPX2 may connect the second contact electrode CTE2 of the second light emitting element LE2 and the common electrode CE with each other, and the second bridge electrode BE2 of the third subpixel SPX3 may connect the second contact electrode CTE2 of the third light emitting element LE3 and the common electrode CE with each other. In an embodiment, if (e.g., when) the eighth insulating layer INS8 is located only on a portion of the common electrode CE overlapping with a light emitting element LE, a second connection hole BH2 may be unnecessary. For example, the second bridge electrode BE2 may be located directly on the common electrode CE, which is exposed around the light emitting element LE.

The second bridge electrode BE2 may be connected to the common electrode CE, which is exposed through the second connection hole BH2 penetrating the eighth insulating layer INS8. In addition, the second bridge electrode BE2 may be located on the upper surface of the eighth insulating layer INS8 and the second contact electrode CTE2.

Each of the first bridge electrode BE1 and the second bridge electrode BE2 may include at least one conductive material, for example, such as any one of molybdenum (Mo), aluminum (Al), chromium (Cr), gold (Au), titanium (Ti), nickel (Ni), neodymium (Nd), and/or copper (Cu). As another example, each of the first bridge electrode BE1 and the second bridge electrode BE2 may include a transparent conductive material (e.g., a transparent conductive oxide (TCO)), such as indium tin oxide (ITO) or indium zinc oxide (IZO).

When each of the first bridge electrode BE1 and the second bridge electrode BE2 includes a metal material with a high reflectivity, such as aluminum (Al), light travelling toward the side of a light emitting element LE among the light emitted from the active layer MQW of the light emitting element LE may be reflected by the connection electrodes BE toward the top of the light emitting element LE. Accordingly, a loss of light of the light emitting element LE may be reduced, which in turn, increases the light efficiency of the light emitting element LE.

As illustrated in FIGS. 30 through 32, the conductive layer E1 of a light emitting element LE may be electrically connected to each pixel electrode PXE through the first contact electrode CTE1 and the first bridge electrode BE1. In addition, the second semiconductor layer SEM2 of the light emitting element LE may be electrically connected to the common electrode CE through the second contact electrode CTE2, which is formed in the hole LEH, and the second bridge electrode BE2. The pixel electrodes PXE may be referred to as anodes or first electrodes, and the common electrode CE may be referred to as a cathode or a second electrode.

The ninth insulating layer INS9 may be located on the eighth insulating layer INS8. The ninth insulating layer INS9 may partially cover the side surfaces of the light emitting elements LE. In addition, the ninth insulating layer INS9 may cover the first and second bridge electrodes BE1 and BE2, but at least a portion of each of the first and second bridge electrodes BE1 and BE2 may be exposed without being covered by the ninth insulating layer INS9.

The tenth insulating layer INS10 may be located on the ninth insulating layer INS9. The tenth insulating layer INS10 may partially cover the side surfaces of each of the light emitting elements LE. The tenth insulating layer INS10 may be located on at least a portion of each of the first and second bridge electrodes BE1 and BE2, which is exposed without being covered by the ninth insulating layer INS9. The upper surface of each of the light emitting elements LE may be exposed without being covered by the tenth insulating layer INS10.

The ninth insulating layer INS9 and the tenth insulating layer INS10 may include at least one insulating material, for example, such as an organic insulating material. For example, each of the ninth insulating layer INS9 and the tenth insulating layer INS10 may include an organic insulating layer, such as an acryl resin, an epoxy resin, a phenolic resin, a polyamide resin, or a polyimide resin.

The ninth insulating layer INS9 and the tenth insulating layer INS10 may flatten steps caused by the light emitting elements LE. If (e.g., when) the ninth insulating layer INS9 is high enough to cover most of the side surfaces of each of the light emitting elements LE, the tenth insulating layer INS10 may be omitted.

The capping layer CPL may be located on the light emitting elements LE, the ninth insulating layer INS9, and the tenth insulating layer INS10. The capping layer CPL may include at least one insulating material, for example, such as an inorganic insulating material.

In an embodiment, if (e.g., when) the light emitting element LE of each of the subpixels SPX emits light of a color corresponding to (e.g., matching) an emission color (e.g., an emission wavelength) of the corresponding subpixel SPX, the display panel 100 may not include a light conversion layer. For example, the first overcoat layer OC1 may be located directly on the capping layer CPL.

When the subpixels SPX include light emitting elements LE that emit light corresponding to their respective emission colors, light emitted from the light emitting elements LE may be utilized more efficiently. For example, a decrease in the light efficiency of the subpixels SPX due to a light conversion may be prevented. In addition, the color purity of light emitted from the subpixels SPX may be increased, and the color gamut of the subpixels SPX may be increased.

In an embodiment, when the light emitting element LE of at least one subpixel SPX emits light of a color different from an emission color (e.g., an emission wavelength) of the corresponding subpixel SPX, a light conversion layer may be further located on the light emitting element LE. For example, when the first light emitting element LE1 emits blue light, and when the first subpixel SPX1 is a red subpixel that emits red light, a light conversion layer, which covers the first light emitting element LE1, may be placed on the capping layer CPL. The light conversion layer may include light conversion particles (e.g., red quantum dots and/or the like), which convert blue light incident from the first light emitting element LE1 into red light. When the subpixels SPX include light emitting elements LE that emit light of the same color as each other, the manufacturing efficiency of the light emitting element layer EDL and the display panel 100 including the light emitting element layer EDL may be increased, and manufacturing costs may be reduced.

The first overcoat layer OC1 may be located on the capping layer CPL (or the light conversion layer). The first overcoat layer OC1 may be an organic insulating layer including an organic insulating material (e.g., an acryl resin, an epoxy resin, a phenolic resin, a polyamide resin, or a polyimide resin), and an upper surface of the first overcoat layer OC1 may be flat or substantially flat. However, the present disclosure is not limited thereto. For example, the first overcoat layer OC1 may be an inorganic insulating layer including an inorganic insulating material. The first overcoat layer OC1 may be formed to a sufficient thickness to include a flat or substantially flat upper surface, or may be planarized through a separate planarization process. Accordingly, the upper surface of the first overcoat layer OC1 may be flat or substantially flat.

The color filter layer CFL may be located on the first overcoat layer OC1. The color filter layer CFL may further include color filters CF located in the emission areas EA of the subpixels SPX, and a second overcoat layer OC2 that covers the color filters CF.

The color filter layer CFL may include the color filters CF, which selectively transmit light corresponding to respective emission colors (e.g., emission wavelengths) of the subpixels SPX. For example, if (e.g., when) the first subpixel SPX1, the second subpixel SPX2, and the third subpixel SPX3 are subpixels SPX that emit a red light, a green light, and a blue light, respectively, a red color filter, a green color filter, and a blue color filter may be located in a first emission area EA1 of the first subpixel SPX1, a second emission area EA2 of the second subpixel SPX2, and a third emission area EA3 of the third subpixel SPX3, respectively. In an embodiment, the color filters CF of the subpixels SPX may overlap with each other in a non-emission area, which surrounds (e.g., around peripheries of) the emission areas EA of the subpixels SPX, to form a light blocking pattern.

The second overcoat layer OC2 may be located on the color filters CF. The second overcoat layer OC2 may be an organic insulating layer including an organic insulating material, and an upper surface of the second overcoat layer OC2 may be flat substantially flat. However, the present disclosure is not limited thereto. For example, the second overcoat layer OC2 may be an inorganic insulating layer including an inorganic insulating material. The second overcoat layer OC2 may be formed to a sufficient thickness to include a flat or substantially flat upper surface, or may be planarized through a separate planarization process. Accordingly, the upper surface of the second overcoat layer OC2 may be flat or substantially flat.

As described above, according to some embodiments, at least two of a plurality of subpixels SPX included in a pixel PX may be electrically connected to separate driving power lines VDL, respectively. Accordingly, first driving voltages VDD respectively applied to the at least two subpixels SPX may be individually and/or independently controlled. For example, a first driving voltage VDD1 of a first level or a first driving voltage VDD2 of a second level may be applied to each subpixel SPX depending on the characteristics of light emitting elements LE included in the subpixels SPX.

In some embodiments, a first subpixel SPX1 of each pixel PX may be electrically connected to a first driving power line VDL1, and second and third subpixels SPX2 and SPX3 of each pixel PX may be electrically connected to a second driving power line VDL2. Accordingly, the first driving voltages VDD applied to at least two of the subpixels SPX included in each pixel PX may be individually and/or independently controlled. For example, the first driving voltage VDD1 of the first level, which is adjusted or optimized according to a first driving current Ids to efficiently drive first light emitting elements LE1, may be applied to the first driving power line VDL1 connected to the first subpixels SPX1. In addition, the first driving voltage VDD2 of the second level, which is adjusted or optimized according to a second driving current Ids to efficiently drive second light emitting elements LE2 and third light emitting elements LE3, may be applied to the second driving power line VDL2 connected to the second subpixels SPX2 and the third subpixels SPX3. In an embodiment, the second subpixels SPX2 and the third subpixels SPX3 may also be connected to different driving power lines, so that the driving currents Ids and the first driving voltages VDD of the first subpixels SPX1, the second subpixels SPX2, and the third subpixels SPX3 may be individually and/or independently controlled. According to some embodiments, the driving currents Ids of the subpixels SPX may be appropriately adjusted according to the characteristics of the light emitting elements LE and the subpixels SPX including the light emitting elements LE, and the first driving voltages VDD applied to the subpixels SPX may be appropriately differentiated and/or optimized according to the driving currents Ids of the subpixels SPX. Accordingly, the consumption efficiency of the light emitting elements LE may be increased, and the power consumption of a display device 1 and an electronic device 10 may be improved.

In some embodiments, each driving power line VDL may be formed as a mesh-shaped wiring. For example, the first driving power line VDL1 may include first vertical power lines VL1 and first horizontal power lines HL1, which cross or intersect each other and are electrically connected to each other within a display area DA. In addition, the second driving power line VDL2 may include second vertical power lines VL2 and second horizontal power lines HL2, which cross or intersect each other and are electrically connected to each other within the display area DA. Accordingly, a drop of the first driving voltages VDD may be reduced, and the subpixels SPX may be stably supplied with their respective first driving voltages VDD.

In some embodiments, a display panel 100 may further include bottom conductive patterns BML located under first transistors T1 of the subpixels SPX, and one of panel driving voltages applied to the subpixels SPX (e.g., the first driving voltage VDD1 of the first level or the first driving voltage VDD2 of the second level) may be applied to each of the bottom conductive patterns BML. Accordingly, the operating characteristics of the subpixels SPX may be improved without adding a panel driving voltage.

The display device 1 according to at least one of the embodiments described above may be applied to various suitable electronic devices. An electronic device according to an embodiment includes the above-described display device 1 (or a display module including a display panel 100 according to at least one embodiment), and may further include various suitable modules or devices having other additional functions, in addition to the display device 1.

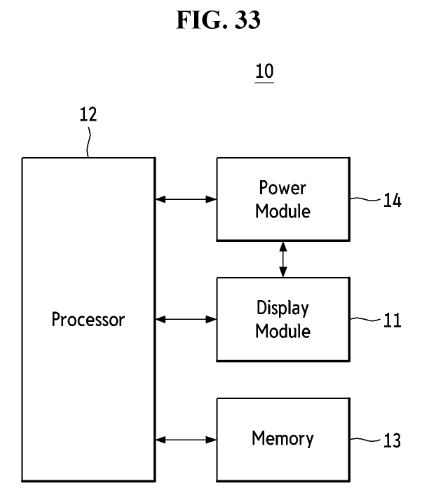

FIG. 33 is a block diagram of an electronic device 10 according to an embodiment. Referring to FIG. 33, the electronic device 10 according to the embodiment may include a display module 11, a processor 12, a memory 13, and a power module 14.

The electronic device 10 may output various information in the form of images through the display module 11. When the processor 12 executes an application stored in the memory 13, image information provided by the application may be provided to a user through the display module 11.

The display module 11 may include a display panel 100 for displaying an image. For example, the display module 11 may include a display panel 100 according to at least one of the embodiments described above.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. For example, the memory 13 may store an image data signal and/or an input control signal.

The processor 12 may control the display module 11 using information stored in the memory 13. The processor 12 may transmit an image data signal and/or an input control signal stored in the memory 13 to the display module 11. For example, when the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module, which generates power necessary for the operation of the electronic device 10 by converting power supplied by the power supply module.

At least one of the elements of the electronic device 10 described above may be included in the display device 1 according to the above-described embodiments. In addition, some of individual modules functionally included in one module may be included in the display device 1, and other modules may be provided separately from the display device 1. For example, the display device 1 may include the display module 11, and the processor 12, the memory 13 and the power module 14 may be provided not in the display device 1, but in the form of other devices within the electronic device 10.

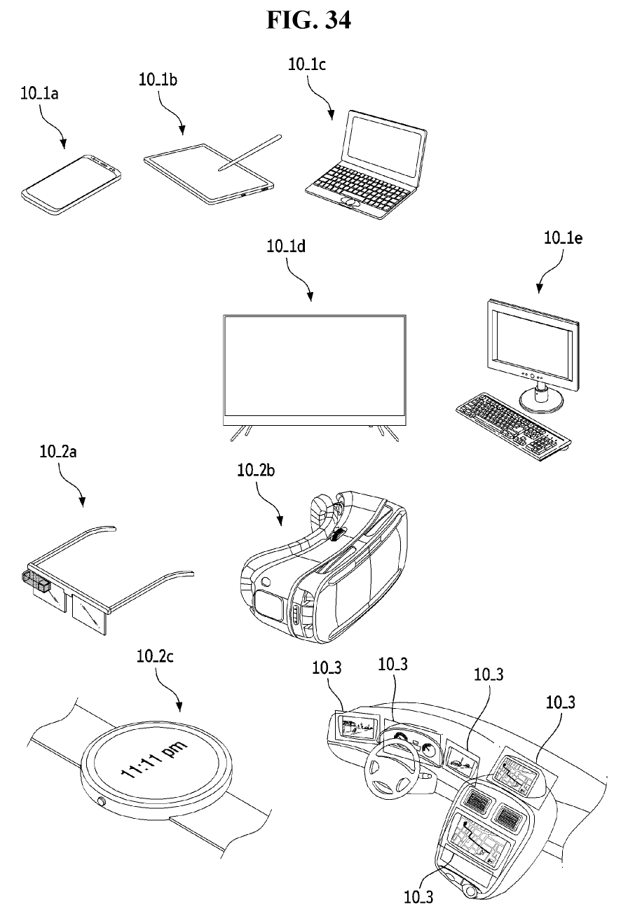

FIG. 34 is a schematic diagram of some electronic devices according to some embodiments.

Referring to FIG. 34, various electronic devices to which a display device 1 according to embodiments is applied may include not only image display electronic devices, such as a smartphone 10_1a, a tablet PC 10_1b, a laptop 10_1c, a television 10_1d and a desk monitor 10_1e, but also wearable electronic devices including display modules, such as smart glasses 10_2a, a head-mounted display 10_2b and a smart watch 10_2c, and vehicle electronic devices 10_3 including display modules, such as a center information display (CID) and a room mirror display placed on an instrument panel, center fascia and dashboard of a vehicle.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
pixels in a display area, each of the pixels comprising a first subpixel, a second subpixel, and a third subpixel;
a first driving power line electrically connected to the first subpixels of the pixels; and
a second driving power line electrically connected to at least one of the second subpixels or the third subpixels of the pixels,
wherein the first driving power line and the second driving power line are configured to be applied with driving voltages of different levels from each other.

2. The display device of claim 1, wherein the first driving power line comprises first vertical power lines and first horizontal power lines crossing each other and electrically connected to each other in the display area, and the second driving power line comprises second vertical power lines and second horizontal power lines crossing each other in the display area.

3. The display device of claim 2, wherein the pixels comprise pixels of a first pixel row along a first direction of the display area, and pixels of a second pixel row along the first direction of the display area, and
wherein the pixels of the first pixel row overlap with one first horizontal power line among the first horizontal power lines, and the pixels of the second pixel row overlap with one second horizontal power line among the second horizontal power lines.

4. The display device of claim 3, wherein the first vertical power lines and the second vertical power lines are located along the first direction, and each of the first vertical power lines and the second vertical power lines extend in a second direction.

5. The display device of claim 4, wherein the one first horizontal power line is electrically connected to the first vertical power lines through connection patterns included in the pixels of the first pixel row, and
wherein the one second horizontal power line is electrically connected to the second vertical power lines through connection patterns included in the pixels of the second pixel row.

6. The display device of claim 2, wherein each of the first subpixels, the second subpixels, and the third subpixels of the pixels comprises:
a pixel circuit comprising a first transistor; and
a light emitting element electrically connected to the pixel circuit.

7. The display device of claim 6, wherein the first vertical power lines overlap with the pixel circuits of the first subpixels of the pixels, and are electrically connected to the pixel circuits of the first subpixels, and
wherein the second vertical power lines overlap with the pixel circuits of the second subpixels and the third subpixels of the pixels, and are electrically connected to the pixel circuits of the second subpixels and the third subpixels.

8. The display device of claim 7, wherein each of the first subpixels of the pixels comprises a first light emitting element configured to emit light of a first color,
wherein each of the second subpixels of the pixels comprises a second light emitting element configured to emit light of a second color, and
wherein each of the third subpixels of the pixels comprises a third light emitting element configured to emit light of a third color.

9. The display device of claim 1, wherein each of the first subpixels, the second subpixels, and the third subpixels of the pixels comprises a first transistor electrically connected to the first driving power line or the second driving power line, and configured to control a driving current.

10. The display device of claim 9, wherein each of the first subpixels, the second subpixels, and the third subpixels of the pixels further comprises a capacitor electrically connected between the first driving power line and a gate electrode of the first transistor, or electrically connected between the second driving power line and the gate electrode of the first transistor.

11. The display device of claim 10, wherein the capacitor of the first subpixel is electrically insulated from the capacitors of the second subpixel and the third subpixel, and the capacitor of the first subpixel comprises a capacitor electrode spaced from capacitor electrodes of the capacitors of the second subpixel and the third subpixel.

12. The display device of claim 9, further comprising bottom conductive patterns located under the first transistors of each of the first subpixels, the second subpixels, and the third subpixels of the pixels.

13. The display device of claim 12, wherein each of the bottom conductive patterns is configured to be applied with a driving voltage of a first level of the first driving power line, or a driving voltage of a second level of the second driving power line.

14. The display device of claim 12, wherein the bottom conductive patterns comprise:
a first bottom conductive pattern located under the first transistor of the first subpixel; and
second bottom conductive patterns spaced from the first bottom conductive pattern, and located under the first transistors of the second and third subpixels,
wherein the first bottom conductive pattern and the second bottom conductive patterns are configured to be applied with driving voltages of different levels from each other.

15. The display device of claim 12, wherein the bottom conductive patterns are connected to each other in the display area, and are configured to be applied with a driving voltage of a first level of the first driving power line, or a driving voltage of a second level of the second driving power line.

16. An electronic device comprising:
a display module comprising a display panel;
memory configured to store an image data signal or an input control signal; and
a processor configured to transmit the image data signal or the input control signal stored in the memory to the display module,
wherein the display panel comprises:
pixels in a display area, each of the pixels comprising a first subpixel, a second subpixel, and a third subpixel;
a first driving power line electrically connected to the first subpixels of the pixels; and
a second driving power line electrically connected to at least one of the second subpixels or the third subpixels of the pixels, and
wherein the first driving power line and the second driving power line are configured to be applied with driving voltages of different levels from each other.

17. The electronic device of claim 16, wherein the first driving power line comprises first vertical power lines and first horizontal power lines crossing each other and electrically connected to each other in the display area, and
the second driving power line comprises second vertical power lines and second horizontal power lines crossing each other and electrically connected to each other in the display area.

18. The electronic device of claim 16, wherein each of the first subpixels, the second subpixels, and the third subpixels of the pixels comprises a first transistor electrically connected to the first driving power line or the second driving power line, and configured to control a driving current, and
wherein the display panel further comprises bottom conductive patterns located under the first transistors of the first subpixels, the second subpixels, and the third subpixels of the pixels.

19. The electronic device of claim 18, wherein the bottom conductive patterns comprise:
a first bottom conductive pattern located under the first transistor of each of the first subpixels of the pixels; and
second bottom conductive patterns spaced from the first bottom conductive pattern, and located under the first transistors of the second and third subpixels of the pixels, and
wherein the first bottom conductive pattern and the second bottom conductive patterns are configured to be applied with driving voltages of different levels from each other.

20. The electronic device of claim 18, wherein the bottom conductive patterns are connected to each other in the display area, and are configured to be applied with a driving voltage of a first level of the first driving power line, or a driving voltage of a second level of the second driving power line.
